(19) United States
(12) Patent Application Publication
(10) Pub. No.: US 2022/0383081 A1
(43) Pub. Date: Dec. 1, 2022

(54) BANDWIDTH-AWARE FLEXIBLE-SCHEDULING MACHINE LEARNING ACCELERATOR

(71) Applicant: Meta Platforms Technologies, LLC, Menlo Park, CA (US)

(72) Inventors: Huichu LIU, Santa Clara, CA (US); Fan WU, Redwood City, CA (US); Edith DALLARD, San Mateo, CA (US); Linyan MEI, Heverlee (BE); Huseyin Ekin SUMBUL, San Francisco, CA (US)

(21) Appl. No.: 17/553,726

(22) Filed: Dec. 16, 2021

Related U.S. Application Data
(60) Provisional application No. 63/194,715, filed on May 28, 2021.

(51) Int. Cl. G06N 3/063; G06N 3/04; G06N 3/08

(52) U.S. Cl. CPC G06N 3/063; G06N 3/04; G06N 3/08

(57) ABSTRACT

A neural network accelerator includes a first memory device, a controller connected to the first memory device through a high-bandwidth (e.g., three-dimensional) interconnect, a configurable processing element (PE) array connected to the first memory device through a first data bus and including a two-dimensional (2D) array of PEs, a local memory connected to the controller and connected, through a second data bus, to the configurable PE array. The controller is configured to, during execution of a neural network (NN), dynamically configure the neural network accelerator for executing each NN layer of a plurality of NN layers of the neural network by selecting either weights of a weight tensor or input data of an input tensor of a tensor operation of the NN layer to store into the local memory, and configuring input and output connections of PEs in the 2D array of PEs for performing the tensor operation.

### CROSS-REFERENCE TO RELATED APPLICATIONS

This application claims the benefit of and priority to U.S. Provisional Application No. 63/194,715, filed May 28, 2021, entitled “BANDWIDTH-AWARE FLEXIBLE-SCHEDULING MACHINE LEARNING ACCELERATOR FOR 3D-DIE STACKING ARCHITECTURE,” which is herein incorporated by reference in its entirety for all purposes.

### BACKGROUND

Three-dimensional (3D) integrated circuits (ICs) employing die-stacking technology and/or monolithic 3D processing technology, such as through-silicon-vias (TSVs), advanced micro-bumps (μBumps), and/or hybrid-bonding between two or more dies or wafers, can offer high-bandwidth, low-latency communications and energy-efficient performance. With new developments in TSV size reduction (e.g., less than about 5 μm) and fine-pitch (e.g., less than about 10 μm) integration for chip-on-wafer and wafer-on-wafer stacking, design trade-offs associated with two-dimensional (2D) wire interconnect congestion and low on-chip memory capacity have been changed. For example, by stacking one die including static random-access memory (SRAM) with another die including logic circuits, high-bandwidth, low-latency, and energy-efficient SRAM-logic communication can be achieved, which can be beneficial for applications such as high performance computing (HPC) and neural network accelerators, where the processing engines may need higher bandwidth and low latency for memory access (e.g., to fetch input data and/or weights and save output data) and larger local memory for caching data (e.g., input activations, weights, and intermediate results).

### SUMMARY

This disclosure relates generally to neural network accelerators. More specifically, techniques disclosed herein relate to bandwidth-aware, flexible-scheduling neural network accelerators implemented using three-dimensional (3D) integrated circuits that include high-bandwidth and low-latency 3D interconnects, configurable processing elements, configurable local memory, and/or bandwidth-configurable data buses. Various inventive embodiments are described herein, including devices, systems, circuits, packages, die stacks, processes, methods, and the like.

According to certain embodiments, a neural network accelerator may include a first memory device, a controller connected to the first memory device through a high-bandwidth interconnect, a configurable processing element (PE) array connected to the first memory device through a first data bus and including a two-dimensional (2D) array of PEs, a local memory connected to the controller and connected, through a second data bus, to the configurable PE array. The controller is configured to, during execution of a neural network (NN), dynamically configure the neural network accelerator for executing each NN layer of a plurality of NN layers of the neural network by selecting either weights of a weight tensor or input data of an input tensor of a tensor operation of the NN layer to store into the local memory, and configuring input and output connections of PEs in the 2D array of PEs for performing the tensor operation.

In some embodiments of the neural network accelerator, the controller may include a set of configuration registers configured to store respective configuration parameters for each NN layer of the plurality of NN layers, and the controller may be configured to dynamically configure the neural network accelerator for executing each NN layer of the plurality of NN layers based on the respective configuration parameters. In some embodiments, the controller may be configured to dynamically control a first bandwidth of the first data bus, a second bandwidth of the second data bus, or both, for performing the tensor operation, and the controller may be configured to configure the input and output connections of the PEs in the 2D array of PEs based on the first bandwidth, the second bandwidth, or both. In some embodiments, the controller may include an array of bus arbiters configured to control the first bandwidth of the first data bus. In some embodiments, the controller may be configured to control the second bandwidth of the second data bus by sending a local memory control signal to the local memory.

In some embodiments, each PE of the 2D array of PEs may include a multiply-accumulate (MAC) unit, a first register configured to receive data from the first memory device, a second register configured to receive data from the local memory, a third register coupled to MAC unit and configured to store an output of the MAC unit. The configurable PE array may include a plurality of multiplexers. Each multiplexer of the plurality of multiplexers may be configured to connect an output of a PE to an input of another PE in the 2D array of PEs, connect the first register of a PE in the 2D array of PEs to the first data bus, or connect the second register of a PE in the 2D array of PEs to the second data bus. In some embodiments, the controller may be configured to configure the input and output connections of the PEs in the 2D array of PEs by controlling the plurality of multiplexers using a set of control signals, and at least two multiplexers of the plurality of multiplexers may be controlled by a same control signal of the set of control signals. In some embodiments, the plurality of multiplexers may include a first set of multiplexers configured to connect PEs in the 2D array of PEs, a second set of multiplexers configured to connect first registers of PEs in the 2D array of PEs to the first data bus, and a third set of multiplexers configured to connect second registers of PEs in the 2D array of PEs to the second data bus. In some embodiments, the first memory device may include a static random access memory (SRAM) device and is larger than the local memory, and the first register may be larger than the second register and is smaller than the third register.

In some embodiments, the first memory device may be on a first die; the controller, the configurable PE array, and the local memory may be on a second die; the high-bandwidth interconnect may include three-dimensional (3D) interconnects; and the first die and the second die may be arranged in a die stack and may be connected by the 3D interconnects. In some embodiments, the 3D interconnects may include through-silicon-vias (TSVs), micro-bumps, or both. In some embodiments, the first data bus may be characterized by a configurable bandwidth equal to or greater than 512 bits per clock cycle. In some embodiments, the input tensor may include input data for one or more input channels and a plurality of batches, and the weight tensor may include weights for generating a plurality of output channels from the input tensor.

According to certain embodiments, an integrated circuit device may include a configurable processing element (PE) array that includes a two-dimensional (2D) array of PEs and a plurality of multiplexers connected to PEs in the 2D array of PEs; a controller connected to the configurable PE array through a first data bus and configured to control the plurality of multiplexers; and a local memory connected to the controller and connected, through a second data bus, to the configurable PE array. Each PE of the 2D array of PEs may include a multiply-accumulate (MAC) unit, a first register connected to the first data bus directly or through a multiplexer of the plurality of multiplexer and configured to store data from the first data bus, a second register connected to the second data bus directly or through a multiplexer of the plurality of multiplexer and configured to store data from the local memory, and a third registers coupled to MAC unit and configured to store an output of the MAC unit.

In some embodiments of the integrated circuit device, the MAC unit of a first PE in a first column of the 2D array of PEs may be connected, through a multiplexer of the plurality of multiplexers, to the MAC unit of an adjacent second PE in the first column of the 2D array of PEs. In some embodiments, the configurable PE array may include a plurality of accumulators outside of PEs of the 2D array of PEs, and each accumulator of the plurality of accumulators may be connected to at least two PEs in a same column of the 2D array of PEs directly or through a multiplexer of the plurality of multiplexers. In some embodiments, a first PE in a first column of the 2D array of PEs may be connected to a second PE in an adjacent column of the 2D array of PEs through a multiplexer of the plurality of multiplexers and an accumulator of the plurality of accumulators.

In some embodiments of the integrated circuit device, the controller may include a set of configuration registers configured to store respective configuration parameters for each neural network (NN) layer of a plurality of NN layers of a neural network, and the controller may be configured to, during execution of the neural network by the integrated circuit device and based on the respective configuration parameters for each NN layer of the plurality of NN layers, control the plurality of multiplexers to dynamically configure the configurable PE array for executing each NN layer of the plurality of NN layers. In some embodiments, the controller may be configured to, based on the respective configuration parameters for each NN layer of the plurality of NN layers, dynamically control a first bandwidth of the first data bus, a second bandwidth of the second data bus, or both, for executing the NN layer of the plurality of NN layers; and select either weights of a weight tensor or input data of an input tensor of a tensor operation of the NN layer to store into the local memory. In some embodiments, the controller, the configurable PE array, and the local memory may be on a first die, and the integrated circuit device may include a second die bonded to the first die and electrically connected to the first die through three-dimensional (3D) interconnects, where the second die may include a memory device that has a larger capacity than the local memory and is configured to store tensors used by a neural network.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 illustrates an example of a convolutional neural network (CNN).

FIG. 3 illustrates an example of a tensor operation on a convolution layer of a CNN.

FIG. 4 illustrates an example of an operation of a neural network (NN) layer performed by a NN accelerator according to certain embodiments.

FIG. 5 illustrates an example of a processing element (PE) array of a NN accelerator according to certain embodiments.

FIG. 6A illustrates an example of a two-dimensional (2D) processing engine that may be used to implement a neural network.

FIG. 6B illustrates an example of a three-dimensional (3D) processing engine with die-to-die stacking through 3D interconnects according to certain embodiments.

FIG. 6C illustrates an example of a 3D integrated circuit device formed by face-to-back bonding of multiple dies according to certain embodiments.

FIG. 6D illustrates another example of a 3D integrated circuit device formed by face-to-face bonding of two dies according to certain embodiments.

FIG. 7 includes a simplified block diagram of an example of a 2D NN accelerator implemented using a 2D integrated circuit.

FIG. 8 includes a simplified block diagram of an example of a 3D NN accelerator including a memory die and a logic die electrically connected through 3D interconnects.

FIG. 9 includes a simplified block diagram of another example of a 3D NN accelerator including a memory die electrically connected to a logic die with local memory through 3D interconnects.

FIGS. 10A-10C illustrate energy consumption and latency of examples of NN accelerators with different data communication bandwidths for executing different augmented reality (AR) NN layers of an edge inference NN.

FIGS. 11A-11C illustrate energy consumption and latency of examples of NN accelerators with different data communication bandwidths and PE array sizes for executing an AR NN layer.

FIGS. 12A-12C illustrate energy consumption and latency of examples of NN accelerators with different data communication bandwidths and PE array sizes for executing an AR NN layer.

FIG. 13 illustrates various parameters of some NN layers of an example of an edge inference AR neural network according to certain embodiments.

FIG. 14 is a simplified block diagram of an example of a bandwidth-aware, layer-aware 3D NN accelerator according to certain embodiments.

FIG. 15 illustrates an example of a PE array for supporting flexible spatial mapping according to certain embodiments.

FIGS. 16A-16F illustrate 12 different configurations of an example of a bandwidth-aware, flexible-scheduling NN accelerator according to certain embodiments.

FIGS. 17A-17C illustrate examples of configurating the configurable PE array to support spatial mapping of 1, 2, and 4 input channels, respectively, according to certain embodiments.

FIG. 18 illustrates an example of configuring a configurable PE array to support spatial mapping of tensor operations including 8 input channels in two steps according to certain embodiments.

FIGS. 19A and 19B illustrate an example of a configurable column data casting design with full flexibility for supporting global buffer bandwidths of 512 and 1024 bits/cycle, respectively, according to certain embodiments.

FIGS. 20A and 20B illustrate an examples of a light-weight configurable column data casting designs with low control overhead for supporting global buffer bandwidths of 512 and 1024 bits/cycle, respectively, according to certain embodiments.

FIGS. 21A-21C illustrate an example of a configurable row data casting design with full flexibility for supporting local buffer bandwidths of 128, 256, and 512 bits/cycle, respectively, according to certain embodiments.

FIGS. 22A-22C illustrate an example of a light-weight configurable row data casting designs with low control overhead for supporting local buffer bandwidths of 128, 256, and 512 bits/cycle, respectively, according to certain embodiments.

FIG. 23 illustrates an example of spatial unrolling according to a configuration of a 3D NN accelerator disclosed herein to implement a depth-wise convolution layer of an edge inference AR NN according to certain embodiments.

FIGS. 24A-24D illustrate latency and energy efficiency comparisons of baseline architectures and various configurations of a 3D NN accelerator according to certain embodiments disclosed herein for implementing a depth-wise convolution layer of an edge inference AR NN.

FIG. 25 illustrates an example of spatial unrolling according to a configuration of a 3D NN accelerator disclosed herein to implement a convolution layer of an AR NN according to certain embodiments.

FIGS. 26A-26D illustrate latency and energy efficiency comparisons of baseline architectures and various configurations of a 3D NN accelerator according to certain embodiments disclosed herein for implementing a convolution layer of an AR NN.

FIG. 27 is a table including experiment results showing the most energy-efficient operation modes of a bandwidth-aware, flexible-scheduling 3D NN accelerator according to certain embodiments for implementing different NN layers of an AR NN.

FIG. 28 is a table including experiment results showing memory energy reduction by the bandwidth-aware, flexible-scheduling 3D NN accelerator disclosed herein according to certain embodiments over baseline NN accelerator architectures for implementing different NN layers of an AR NN.

FIG. 29 is a table including experiment results showing data communication latency reduction by a bandwidth-aware, flexible-scheduling 3D NN accelerator disclosed herein according to certain embodiments over baseline NN accelerator architectures for implementing different NN layers of an AR NN.

FIG. 30 is a table including experiment results showing energy delay product improvement of a bandwidth-aware, flexible-scheduling 3D NN accelerator according to certain embodiments over baseline NN accelerator architectures for implementing different NN layers of an AR NN.

FIG. 31 is a perspective view of an example of a near-eye display in the form of a head-mounted display (HMD) device for implementing some of the examples disclosed herein.

FIG. 32 is a perspective view of an example of a near-eye display in the form of a pair of glasses for implementing some of the examples disclosed herein.

FIG. 33 is a simplified block diagram of an electronic system of an example of a near-eye display for implementing some of the examples disclosed herein.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to neural network (NN) accelerators. More specifically, techniques disclosed herein relate to bandwidth-aware, flexible-scheduling neural network accelerators implemented using three-dimensional (3D) integrated circuits (ICs) that include high-bandwidth and low-latency 3D interconnects, configurable processing elements, configurable local memory, and/or bandwidth-configurable data buses. Various inventive embodiments are described herein, including devices, systems, circuits, packages, die stacks, processes, methods, and the like.

As Moore's law gradually approaches an end because of the difficulties and challenges in making chips with even smaller devices (e.g., transistors) in newer semiconductor manufacturing technology nodes, 3D ICs have gain popularity in recent years due to their capability of reducing form factors, shortening interconnection wires, offering high-bandwidth data communication, supporting heterogeneous integration, and the like. For example, 3D interconnects with sub-10 μm pitches have been implemented using micro-bumps (μBumps) and/or through-silicon-vias (TSVs) in advanced silicon processing technology to achieve over 10,000/mm² die-to-die interconnect density with about 0.1 pJ/bit or lower energy consumption. 3D ICs may overcome the scaling and yield challenges of two-dimensional (2D) ICs by improving functionality and performance per unit area through vertical integration of smaller dies, and reducing cost through design block reuse. 3D fabrication processes also enable heterogeneous integration of dies made of different processes and/or different materials, thereby offering more freedom in choosing the processing technology and material system for each die based on the application and cost requirements, and providing new capabilities such as near-sensor intelligence (e.g. sensor on logic) and nonvolatile processing (e.g. nonvolatile memory (NVM) on logic). For example, in applications such as server and high performance computing (HPC) applications, SRAM-on-logic stacking can significantly increase local static random access memory (SRAM) capacity (e.g., about tens of gigabytes or more) with higher memory bandwidth (about tens or hundreds of gigabytes per second) and lower access latency compared with off-chip dynamic random access memory (DRAM) access. This can alleviate data movement bottleneck and cost in computing systems, such that massively parallelized processing units can be more fully utilized for higher performance computing.

For some specialized neural network accelerators built for compute-intensive deep neural network (DNN) workloads, the overall system performance and energy efficiency are often bounded by data movements between processing element (PE) arrays and memory systems. For example, the memory bandwidth of a system may limit the system throughput, and the memory capacity may limit energy efficiency. Emerging applications such as augmented reality (AR) and virtual reality (VR) applications may need moderate performance in machine learning tasks but a more stringent power efficiency performance. Unlike some other central processing unit (CPU) or graphic processing unit (GPU workloads, AR/VR neural networks may be compressed and quantized for running on devices with power and thermal constraints. To achieve low latency and high energy efficiency for always-accessible user experiences, AR/VR hardware needs to reduce data movement cost between different modules, and needs to have a small form factor due to area and size constraints in wearable or portable devices. Therefore, 3D ICs may be suitable and beneficial for AR/VR applications.

However, conventional NN accelerator architectures may not take full advantage of the high bandwidth offered by 3D die-to-die stacking in advanced processing technology. For example, as described in detail below, the high bandwidth offered by splitting SRAMs and logic circuits in two dies may not improve the energy efficiency in 3D stacked AR/VR DNN accelerators. In addition, different AR/VR DNN layers may have different configurations for optimal energy efficiency in terms of bandwidth requirement, data reuse opportunity, temporal mapping, and spatial mapping, due to, for example, different sizes of parameters (e.g., input data, weights, and output data) in different AR/VR DNN layers. Therefore, the overall energy efficiency of a DNN accelerator implementing the AR/VR DNN may be suboptimal when the DNN accelerator has a fixed architecture for different layers of the DNN. Furthermore, to fully utilize the 3D interconnect bandwidth, more computing units may be needed to process the data, and thus larger PE arrays may be needed. However, many AR/VR NNs have been pruned and quantized with limited parameter sizes for fitting on-device, larger PE arrays (e.g., 64×64 or larger) may not be needed and may result in low hardware utilization, which is neither energy nor area efficient. Therefore, conventional 3D die-stacking architectures that may work well for reducing memory access latency and energy in general-purpose CPUs and GPUs may not be directly applicable to AR/VR applications.

According to certain embodiments, to fully utilize the high bandwidth offered by 3D die-stacking and further improve the energy efficiency for implementing on-device AR/VR NNs beyond what 2D designs may be able to offer, a bandwidth-aware, flexible-scheduling NN accelerator implemented by 3D stacking of a global buffer (GB) die and another die including logic circuits and a local buffer (LB) is disclosed herein. The NN accelerator can, based on properties of AR/VR NN layers, dynamically configure hardware resources, such as the local buffer, the PE array, and the data bus bandwidth, to implement different respective layers of an AR/VR NN more efficiently. For example, based on the tensor operation (e.g., sizes of the tensors) of a NN layer, the NN accelerator disclosed herein may utilize the high bandwidth offered by 3D interconnects for transferring large and/or less frequently used (or reused) data (either weights or input activations) to reduce energy and latency. The NN accelerator may configure a local buffer that may have limited size and bandwidth to store small and/or more frequently used (or reused) data (either weights or input activations). The NN accelerator may dynamically configure the connections of PEs in the PE array with other PEs, with the local buffer, and with the global buffer, to support flexible spatial unrolling of tensor operations that use tensors having various dimensions and sizes, such as various numbers of input channels, input batches, filters, and output channels.

In some embodiments, the NN accelerator includes a bandwidth-aware, NN layer-aware controller that may include a set of configuration registers for storing configuration parameters of respective NN layers, and an array of arbiters to allocate data traffic to the local buffer and the PE array on a die. For example, configuration parameters of the preferred configurations for respective AR/VR NN layers may be pre-determined and loaded into the configuration registers for respective NN layers. The controller may, based on the spatial mapping preference of an AR/VR NN layer for maximal layer-wise energy efficiency and/or the configuration parameters for the AR/VR NN layer, configure the local buffer to store either weights or input data for the AR/VR NN layer using LB configuration control signals. The controller may also, based on the spatial scheduling preference of the AR/VR NN layer (e.g., the configuration parameters stored in the configuration registers), dynamically control the allocation of data traffic for each AR/VR NN layer by allocating suitable data transfer bandwidth between the GB and the PE array and data transfer bandwidth between the LB and PE array. The controller may further generate and send PE configuration control signals to the PE array to configure the PE array for supporting flexible spatial unrolling (also referred to as unfolding or mapping) of convolution operations (e.g., including DNN loops) that matches the allocated 3D bandwidth.

In some embodiments, the NN accelerator may include a configurable PE array with novel register partition to support flexible spatial mapping. In existing PE array designs, each PE may have a dedicated register for input data (I-REG), a dedicated register for weights (W-REGs), and a dedicated register for output data (O-REG). In the configurable PE array disclosed herein, the registers in each PE may not be assigned based on the different data types but may instead be assigned based on the different data sources, such as the LB or GB. For example, the PE disclosed herein may include a local buffer register (LB-REG) that receives data from the LB on the same die, and a global buffer register (GB-REG) that receives data from the GB on another die. The PE may also include an output register (O-REG) for storing intermediate results. The sizes of the LB-REG, GB-REG, and O-REG may be different. For example, the size of the GB-REG may be four times to eight times or more of the size of the LB-REG, while the size of the O-REG may be three times to eight times or more of the size of the GB-REG. The PE array may also include a set of multiplexers or arbiters for configuring the input and output connections of the PEs with other PEs, the local buffer, the global buffer, and other circuits (e.g., additional accumulators) in the PE array.

In some embodiments, the NN accelerator includes a flexible spatial mapping PE array that can be dynamically configured to support different mapping schemes at run-time, such as different configurations for different combinations of bandwidth allocation and LB assignment. For example, the different spatial mapping schemes may correspond to different allocated bandwidth for data communication between the LB and the PE array (LB-PE) and data communication between the GB and the PE array (GB-PE), and the LB data type (e.g., input data or weights). The controller may generate configuration signals to control the set of multiplexers or arbiters to alter the row, column, and/or output connections in the PE array to match the allocated bandwidth and support different spatial mappings for tensor operations with different numbers of input channels and corresponding filters, different numbers of output channels, and different batch sizes.

The NN accelerator disclosed herein can fully utilize the high 3D SRAM bandwidth (e.g., at or greater than 512 bits/cycle), and can dynamically alter the dataflow and scheduling during run-time based on the properties of each AR NN layer. The NN accelerator can support different architectures by changing operating modes (e.g. allocating the bandwidth and data types in the local buffer) to reduce energy consumption and latency thereby improving energy efficiency, with minimal or low hardware overhead. Experimental results show that, due to the 3D bandwidth-aware configurability and flexibility, the 3D NN accelerator disclosed herein can reduce the energy-delay product (EDP) in the layer level by up to 93% or more compared with the best case 2D NN accelerator design, and by up to 67% or 75% or more compared with existing 3D NN accelerator designs. As such, the 3D NN accelerator disclosed herein can improve energy efficiency by up to 13.5 times or more over the 2D NN accelerator design, and by up to 3.04 times or 4.12 times or more over existing 3D NN accelerator designs. In the application level (across all layers of the NN), the 3D NN accelerator disclosed herein can provide an overall energy efficiency improvement about 2.19 times or more over the 2D NN accelerator design, and about 2.32 times or 1.35 times or more over the existing 3D NN accelerator designs.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including a head-mounted device (HMD) connected to a host computer system, a standalone HMD, a mobile device or computing system, or any other hardware platform capable of providing artificial reality content to one or more viewers.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

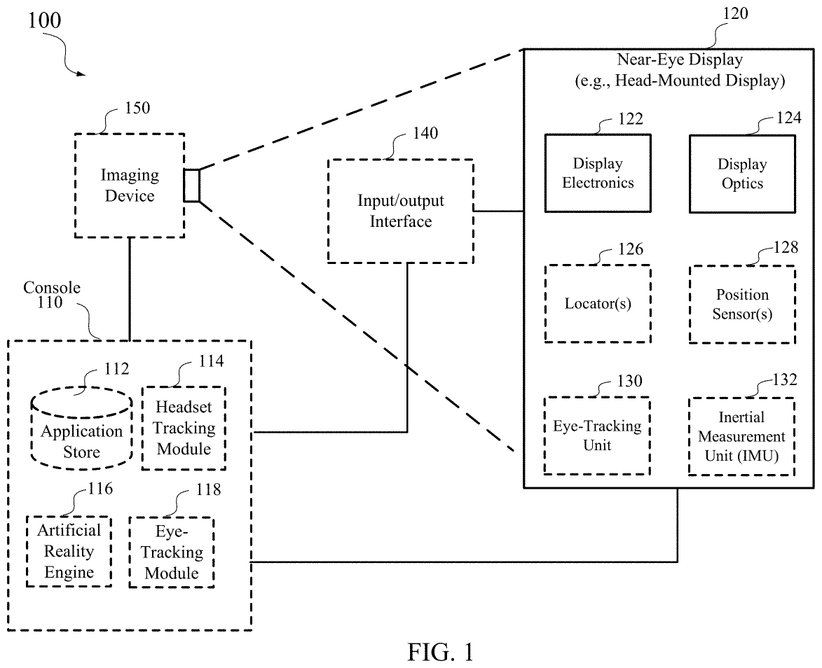

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. For example, in some embodiments, functions and modules of console 110, input/output interface 140, and/or imaging device 150 may be implemented in near-eye display 120. In alternative configurations, different or additional components may be included in artificial reality system environment 100.

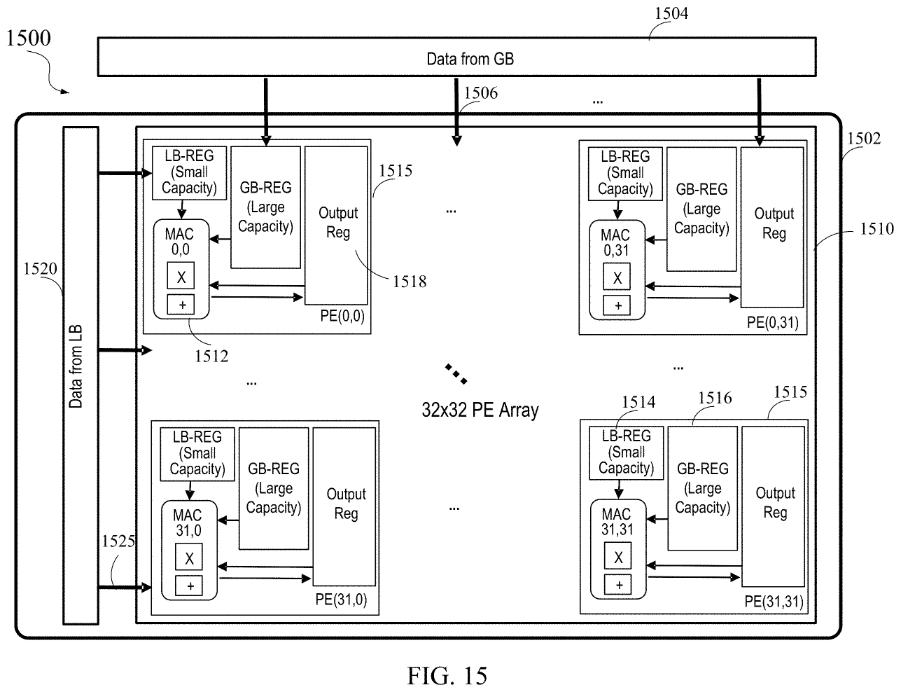

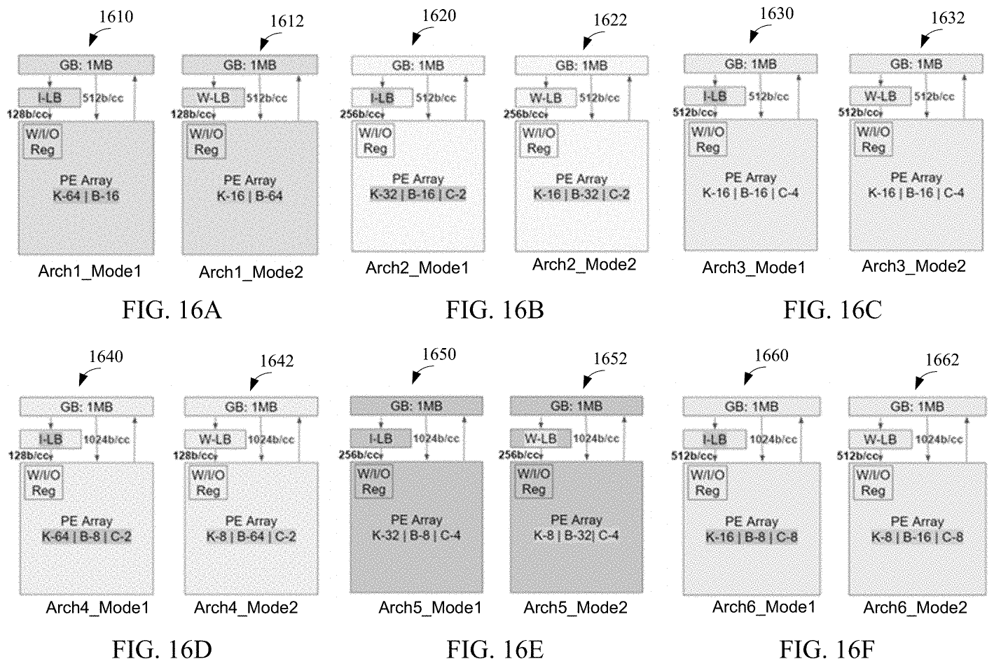

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 15 and 16. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be a light emitting diode (LED), a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, a camera, an infrared detector, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, input/output interface 140 may be configured to remotely receive inputs from the user, such as based on gestures and/or positions of user's body parts, such as user's hands or arms.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.). In some embodiments, external imaging device 150 may be used to track input/output interface 140, such as tracking the location or position of a controller (which may include, for example, an IR light source) or a hand (or another body part) of the user to determine the motion, gesture, and/or position of the user. In some embodiments, near-eye display 120 may include one or more imaging devices to track input/output interface 140, such as tracking the location or position of a controller or a hand (or another body part) of the user to determine the motion, gesture, and/or position of the user.

In some embodiments, console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to determine the eye's orientation more accurately.

In some implementations, the tracking of the hand, eye, or arm of the user or the controller described above may be implemented using a deep neural network (DNN) and, for example, one or more monochrome cameras. In one example, a deep neural network may be used to predict the location of a user's hands and features (e.g., joints) of the hand, which may be used to reconstruct a multiple (e.g., 10 or more, such as 26) degree-of-freedom pose of the user's hands and fingers. A 3D model that includes the configuration and surface geometry of a hand may thus be created and used for immersive user interaction, for example, through direct manipulation, hand rays, gesture recognition, and the like. It is desirable that the deep neural network can provide accurate, low-jitter estimates of hand pose robustly across a wide range of environments, and has a small footprint and a low power consumption to enable real-time hand-tracking on a mobile device, without compromising other user applications.

Artificial neural networks (also referred to as “neural networks”) have been used in machine learning research and industrial applications and have achieved many breakthrough results in, for example, image recognition, speech recognition, computer vision, natural language processing, and the like. An artificial neural network may include multiple processing nodes arranged on two or more layers, where processing nodes on one layer may connect to processing nodes on another layer. The processing nodes can be divided into layers including, for example, an input layer, a number of intermediate layers (also known as hidden layers), and an output layer. Each processing node on a layer (e.g., an input layer, an intermediate layer, etc.) may receive a sequential stream of input data elements, multiply each input data element with a weight, compute a weighted sum of the input data elements, and forward the weighted sum to the next layer. The processing node may also apply a function (e.g., a nonlinear function) to the weighted sum of its inputs.

A feedforward neural network is a type of artificial neural network that includes multiple nodes arranged in multiple layers. Nodes from adjacent layers may have connections or edges between them. These connections may have corresponding weights associated with them. Information may flow from the input nodes, through the hidden nodes (if any), and to the output nodes. In many situations, using the feedforward neural network for real-world application, such as image classification, may be impractical. For example, for a two-dimensional (2D) image with 200×200 pixels, 40,000 input nodes may be used in the neural network. If a hidden layer has 20,000 nodes, the size of the matrix for the weights would be 40,000×20,000 (or 800 million elements). If each weight is a 32-bit (i.e., 4-byte) floating point value, the total memory used for the weights would be 3.2 GB. This is just for a single layer. As the number of layers increases, the size of the weights may increase as well. In addition, vectorizing an image using individual pixels may ignore the complex multi-dimensional spatial structure of the image.

One way to overcome these issues is to use convolutional neural networks that perform convolutions using smaller convolutional filters rather than the large matrix multiplications as described above. Learning a set of convolutional filters (e.g., 2×2, 2×3, . . . , or 11×11 matrices) may be much easier and faster than learning a large matrix (e.g., 40,000×20,000). Multi-dimensional convolutions or other tensor operations can also naturally take the multi-dimensional structure of images into account. Convolutional neural networks can be considered as feedforward neural networks with local connectivity and weight sharing. The local connectivity refers to the fact that a convolutional filter may have much smaller dimensions than the image it operates on. The weight sharing is due to the fact that a same filter may be used across the image when performing the convolution, which means that a same local filter is used on many locations in the image. In other words, the weights between all filtering for different locations in the image are shared. A convolutional neural network may perform operations including, for example, convolution, non-linearity (or activation) function (e.g., ReLU), pooling or sub-sampling; and classification (e.g., Softmax). Different CNNs may have different combinations of these four operations, as well as other additional operations. For example, a ResNet-50 network may include network layers that include mostly convolution layers and a few pooling layers, and may also perform residue-add operations for residue learning.

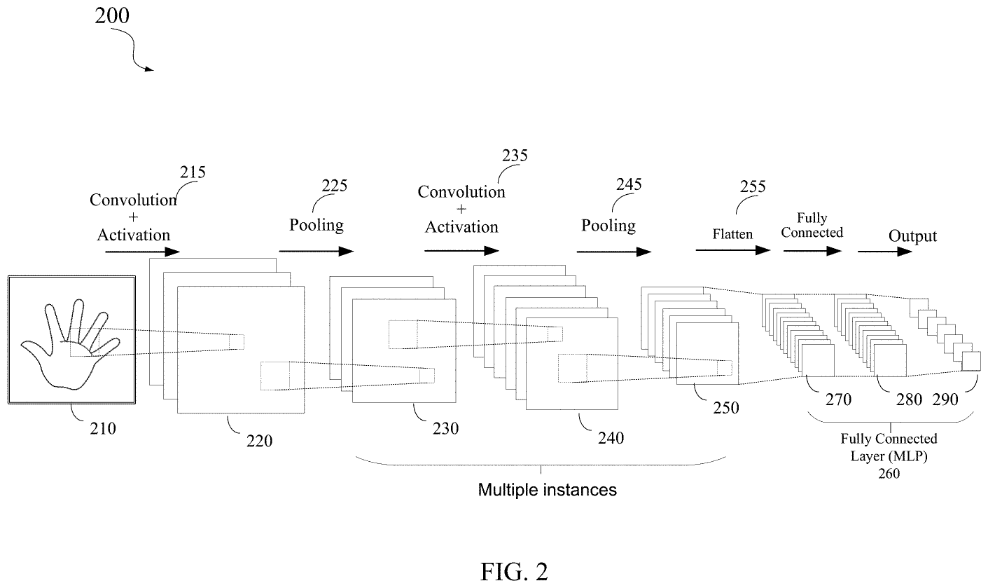

FIG. 2 illustrates an example of a convolutional neural network (CNN) 200 for object recognition, classifications, or tracking. CNN 200 may perform the four types of operations described above, including convolution, non-linearity (or activation) function (e.g., ReLU), pooling or sub-sampling, and classification (fully-connected layer). An object 210 (e.g., a user's hand) to be recognized, classified, or tracked may be represented by data matrices or tensors (e.g., one or more input images, reshaped images, or other input datasets, also referred to as input feature maps or input tensors). For example, object 210 may be represented by multiple channels (e.g., multiple input feature maps), each channel representing a certain component of object 210. For example, an image from a color camera may have a red channel, a green channel, and a blue channel, where each channel may be represented by a 2D matrix of pixels having pixel values in the range of, for example, 0 to 255 (i.e., 8-bit). In another example, object 210 may be captured by multiple monochromatic cameras from different perspectives and thus may be represented by multiple monochromatic (e.g., gray-scale) images. In the following description, the processing of a single image channel using CNN 200 is described. Other channels may be processed similarly.

As shown in FIG. 2, input data representing object 210 (e.g., input images) may first be processed by a first convolution layer 215 using a first set of filters, where first convolution layer 215 may perform a convolution between a matrix representing the input image and a matrix representing each filter in the first set of filters. The convolution may include multiple matrix multiplication. First convolution layer 215 may also perform a non-linear activation function (e.g., ReLU). ReLU is an element-wise operation that replaces all negative pixel values in the feature map by zero. The purpose of the ReLU operation is to introduce non-linearity in the CNN. Other non-linear functions, such as tan h or sigmoid function, can also be used. An output matrix 220 from first convolution layer 215 may have smaller dimensions than the input image. First convolution layer 215 may perform convolutions on the input image using the first set of filters to generate multiple output matrices 220, which may be referred to as output feature maps of first convolution layer 215. The number of filters used may be referred to as the depth of the convolution layer. In the example shown in FIG. 2, first convolution layer 215 may have a depth of three.

Each output matrix 220 (e.g., an output feature map) may be passed to a pooling layer 225, where each output matrix 220 may be subsampled or down-sampled to generate a matrix 230. Spatial pooling may reduce the dimensions of each feature map, while retaining the most important information. In particular, pooling may make the feature dimensions smaller and more manageable, and reduce the number of parameters and computations in the network. Spatial pooling may be performed in different ways, such as max pooling, average pooling, sum pooling, etc. In max pooling, the largest element in each spatial neighborhood (e.g., a 2×2 window) may be used to represent the spatial neighborhood. Instead of taking the largest element, the average (for average pooling) or sum (for sum pooling) of all elements in each window may be used to represent the spatial neighborhood.

Each matrix 230 may be processed by a second convolution layer 235 using a second set of filters. A non-linear activation function (e.g., ReLU) may also be performed by the second convolution layer 235 as described above. An output matrix 240 (e.g., an output feature map) from second convolution layer 235 may have smaller dimensions than matrix 230. Second convolution layer 235 may perform convolutions on matrix 230 using the second set of filters to generate multiple output matrices 240. In the example shown in FIG. 2, second convolution layer 235 may have a depth of six. Each output matrix 240 may be passed to a pooling layer 245, where each output matrix 240 may be subsampled or down-sampled to generate an output matrix 250. There may be multiple instances of second convolution layer 235 and pooling layer 245 in a deep neural network. In some embodiments, a pooling layer may not be used after every convolution layer. For example, in some implementations, a CNN may perform multiple convolution and ReLU operations before performing a pooling operation. Thus, there may be fewer pooling layers 245 than second convolution layers 235.

The sizes of the output feature maps may be determined based on parameters such as the depth, stride, and zero-padding. For example, in CNN 200 shown in FIG. 2, three distinct filters are used in first convolution layer 215 to perform convolution operations on the input image, thus producing three different output matrices 220 (or feature maps). Stride is the number of pixels by which the filter matrix is slid over the input pixel array. For example, when the stride is one, the filter matrix is moved by one pixel at a time. When the stride is two, the filter matrix is moved by two pixels at a time. Having a larger stride may produce smaller feature maps. In some implementations, the input matrix may be padded with zeros around the border so that the filter matrix may be applied to bordering elements of the input pixel array. Zero-padding may allow control of the size of the feature maps.

The output matrices 250 from pooling layer 245 may be flattened to vectors by a flatten layer 255, and passed through a fully-connected layer 260 (e.g., a multi-layer perceptron (MLP)). Fully-connected layer 260 may include an input layer 270 that takes the 2D output vector from flatten layer 255. Fully-connected layer 260 may also include a hidden layer and an output layer 290. Fully-connected layer 260 may recognize or classify the object (or features of the object, such as joints on a hand) in the input image using feature maps or output matrix 250 and, for example, a Softmax function. The operation of the fully-connected layer may be represented by matrix multiplications. For example, if there are M nodes on input layer 270 and N nodes on hidden layer 280, and the weights of the connections between the M nodes on input layer 270 and the N nodes on hidden layer 280 can be represented by a matrix W that includes M×N elements, the output Y of hidden layer 280 may be determined by Y=x×w.

The convolution operations in a CNN may be used to extract features (e.g., edges and/or joints of user's hand) from the input data. The convolution operations may preserve the spatial relationship between pixels by extracting image features using small regions of the input image. In a convolution, a matrix (referred to as a filter, a kernel, or a feature detector) may slide over the input image (or a feature map) at a certain step size (referred to as the stride). For every position (or step), element-wise multiplications between the filter matrix and the overlapped matrix in the input image may be calculated and summed to generate a final value that represents a single element of an output matrix (e.g., a feature map). A filter may act to detect certain features from the original input image. The convolution using one filter (or one filter set) over an input pixel array may be used to produce one feature map, and the convolution using another filter (or another filter set) over the same input pixel array may generate a different feature map. A CNN may learn the weights of the filters on its own during the training process based on some user specified parameters (which may be referred to as hyperparameters), such as the number of filters, the filter size, the architecture of the network, etc. A CNN may be trained using, for example, the back propagation method and appropriate training data.

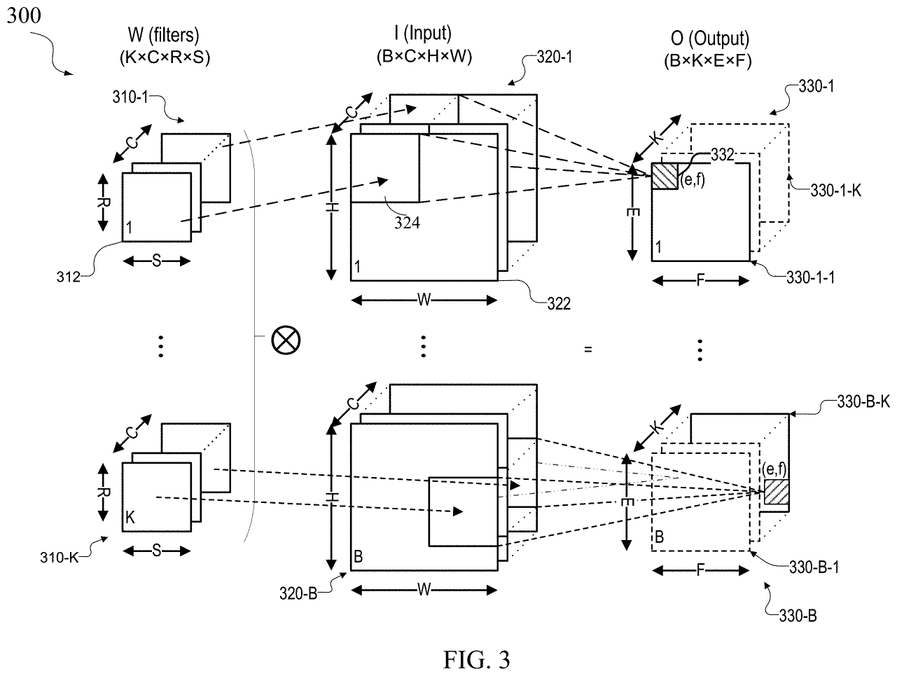

FIG. 3 illustrates an example of a tensor operation 300 on a convolution layer of a convolutional neural network used in, for example, image processing. As illustrated in the example, there may be multiple (e.g., B) batches of 3D inputs 320-1, . . . , and 320-B to the convolution layer. Each 3D input may include C channels of 2D input feature maps (with dimensions H×W). For the first convolution layer in a CNN, such as a ResNet-50, a 3D input may include, for example, three channels of 2D images (e.g., the red, green, and blue color channels) or a single channel of 2D image (a monochromatic channel). Multiple (e.g., K) 3D filters 310-1, . . . , and 310-K, each having C 2D filters of dimensions R×S, may be convolved with the B 3D inputs 320-1, . . . , and 320-B (e.g., B batches of C input feature maps of dimensions H×W) to generate multiple (e.g., B) 3D outputs 330-1, . . . , and 330-B, where each of the 3D outputs 330-1, . . . , and 330-B may include K output feature maps (also referred to as output channels). Each 3D filter 310-1, . . . , or 310-K (with dimensions C×R×S) may be applied to a 3D input 320-1, . . . , or 320-B (with dimensions C×H×W) to generate an output feature map (with dimensions E×F) in a 3D output 330-1, . . . , or 330-B that includes K output feature maps. Therefore, K 3D filters may be used to generate the K output feature maps in a 3D output 330-1, . . . , or 330-B for a 3D input 320-1, . . . , or 320-B. For example, 3D filter 310-1 may be applied to 3D input 320-1 to generate an output feature map 330-1-1, . . . and 3D filter 310-K may be applied to 3D input 320-1 to generate an output feature map 330-1-K. The same K 3D filters 310-1, . . . , and 310-K can be applied to each 3D input 320-1, . . . , or 320-B to generate each respective 3D output 330-1, . . . , or 330-B that includes K output feature maps. For example, 3D filter 310-1 may be applied to 3D input 320-B to generate an output feature map 330-B−1, and 3D filter 310-K may be applied to 3D input 320-B to generate an output feature map 330-B-K. Thus, there are B 3D inputs and B 3D outputs, where each 3D output includes K output feature maps.

More specifically, as shown in FIG. 3, for a 3D input 320-1, . . . , or 320-B and a 3D filter 310-1, . . . , or 310-K, the C 2D filters (each with dimensions R×S) in a 3D filter 310-K may correspond to the C channels of 2D input feature maps (each with dimensions H×W) in the 3D input, and the convolution operation between each 2D filter of the C 2D filters and the corresponding channel of the C channels of 2D input feature maps may be performed. The convolution results for C pairs of 2D filter and corresponding 2D input feature map can be summed to generate a convolution output (e.g., a pixel) O[b][k][e][f] on an output feature map of index kin the K output feature maps in a batch b of 3D output 330-1, . . . , or 330-B as follows:

O[b][k][e][f]=Σ_{c=0}^{c-1}Σᵣ₌₀^{R-1}Σₛ₌₀^{S-1}I[b][c][eD+r][fD+s]×W[k][c][r][s], (1)

where b∈[1, B], k corresponds to the index of the output feature map and the index of the 3D filter in the K 3D filters. D is the sliding-window stride distance. e and f are the coordinates of the output pixel in the corresponding output feature map of the K output feature maps and may correspond to a particular sliding window. Each output feature map may have E×F elements, where E=(H−R+D)/D and F=(W−S+D)/D. r and s correspond to a particular location (e.g., pixel or element) within a sliding window or a 2D filter. I[b][c][eD+r][fD+s] is the value of a pixel with a horizontal pixel coordinate of eD+r and a vertical pixel coordinate of fD+s in an input feature map of index C in the C channels of 2D input feature maps in a 3D input. W[k][c][r][s] is a weight corresponding to a pixel at a location (r, s) of a 2D filter of index C in the 3D filter of index k. Equation (1) indicates that, to compute each convolution output (e.g., pixel) O[b][k][e[f] at a location (e, f) on an output feature map k, each pixel I[b][c][eD+r][fD+s] within a sliding window in an input feature map of index C may be multiplied with a corresponding weight W[k][c][r][s] to generate a product, the partial sum of the products for the pixels within each sliding window in the input feature map of index C can be computed, and then a sum of the partial sums for all C input feature maps can be computed to determine the value of the pixel O[b][k][e[f] at a location (e, f) in the corresponding output feature map of index k in the K output feature maps.

In one example, for 3D filter 310-1 and 3D input 320-1, each 2D filter 312 in the C 2D filters in 3D filter 310-1 may correspond to a respective input feature map 322 in 3D input 320-1 and may be used to convolve with (e.g., filter) the corresponding input feature map 322, where each pixel in a sliding window 324 in input feature map 322 may be multiplied with a corresponding pixel in 2D filter 312 to generate a product, and the products for all pixels in sliding window 324 may be summed to generate a partial sum. The partial sums for the C 2D filters 312 (and corresponding input feature map 322) may be added together to generate an output pixel 332 at a location (e, f) on output feature map 330-1-1 in 3D output 330-1. Sliding window 324 may be shifted on all C input feature maps 322 in 3D input 320-1 based on the strides D in the two dimensions to generate another output pixel 332 at a different location on output feature map 330-1-1 in 3D output 330-1. Sliding window 324 may be repeatedly shifted together on all C input feature maps 322 until all output pixels 332 on output feature map 330-1-1 in 3D output 330-1 are generated.

Each 3D filter 310-2, . . . , or 310-K may be used to convolve with 3D input 320-1 as described above with respect to 3D filter 310-1 to generate each respective output feature map 330-1-2, . . . , or 330-1-K in 3D output 330-1. Similarly, each 3D filter 310-1, . . . , or 310-K may be used to convolve with 3D input 320-B as described above with respect to 3D filter 310-1 and 3D input 320-1 to generate each respective output feature map 330-B−1, . . . , or 330-B-K in 3D output 330-B.

Operation of a neural network (e.g., conducting an inference), as illustrated by the examples discussed above, generally involves fetching input data (e.g., input activations) and filter data (e.g., weights), executing multiply-accumulate (MAC) operations on the input data and the filter data in parallel for each node in a layer, and providing output activations. The performance of a neural network, for example, the response time of the neural network, can be improved when a hardware architecture is capable of highly parallelized computations. Special-purpose or domain-specific neural network processors can achieve better performance than both general-purpose CPUs and GPUs when executing a neural network. Neural network processors can employ a spatial architecture including a PE array (e.g., a systolic array), in which the processing elements may form processing chains and can pass data directly from one processing element to another. This can significantly reduce the number of memory transactions.

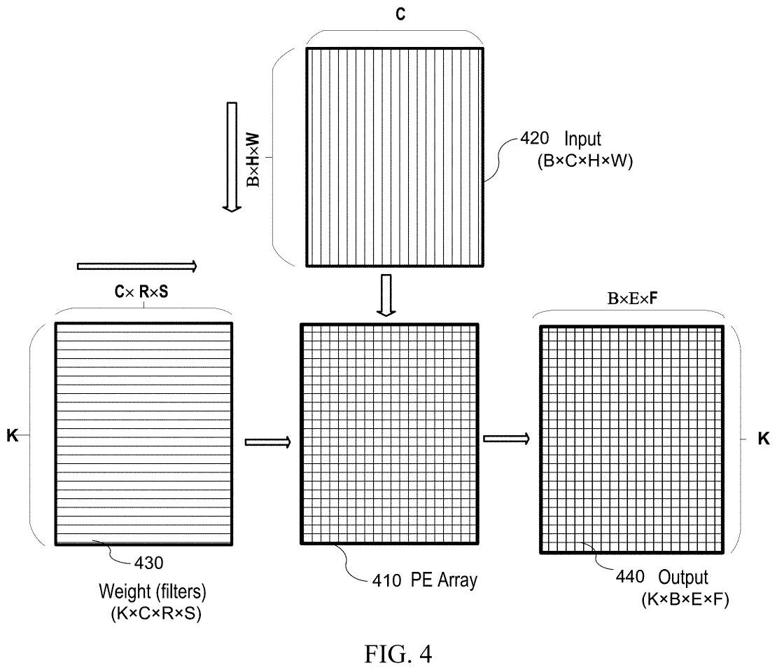

FIG. 4 illustrates an example of an operation of a neural network layer performed by a NN accelerator according to certain embodiments. The neural network layer may be a convolutional layer that includes operations described above, for example, with respect to FIG. 3. As illustrated, the convolution operation to be performed by a processing element (PE) array 410 may include a tensor operation that uses B bathes of 3D inputs 420 each including C channels of 2D input feature maps (each with dimensions H×W) and 3D filters 430 that include K 3D filters each including C channels of 2D filters (each with dimensions R×S) to generate output feature maps 440 that include K output channels of output feature maps. Each output channel may include B output feature maps that each include E×F pixels. 3D inputs 420 may be flattened to C input channels each including B×H×W pixel values, where each input channel may be mapped to a column (or row) of PE array 410 such that input data of the input channel may be shifted or otherwise loaded into PEs in the corresponding column (or row) of PE array 410. 3D filters 430 may be flattened to K channels each including C×R×S weight values, where each of the K channels may be mapped to a row (or column) in PE array 410 such that the weights for the channel may be shifted or otherwise loaded into PEs in the corresponding row (or column) of PE array 410.

The convolutions described above with respect to FIGS. 3 and 4 may be normal convolutions, where the depth of a filter may be the same as the number of input channels (input feature maps) of the input tensor for each batch and the weighted sums of the input channels may be summed, and thus the number of the output feature maps may be different from the number of input channels. For example, as shown in FIG. 3, the normal convolution of 3D filter 310-1 (including C 2D filters 312) and 3D input 320-1 (including C input feature maps 322) may yield one output feature map 330-1-1. In some neural networks, such as some neural networks for mobile and embedded applications, some convolution operations may be depth-wise convolutions, where the depth of a filter may be the same as the number of input channels (input feature maps) of the input tensor in each batch but the weighted sums of the input channels may be stacked or concatenated (instead of summed), and thus the number of the output feature maps may be the same as the number of input channels.

FIG. 5. illustrates an example of a PE array 500 of a NN accelerator according to certain embodiments. PE array 500 may be an example of PE array 410. PE array 500 can, for example, execute parallel integration, convolution, correlation, and/or matrix multiplication, among other things. Processing element array 500 may include multiple processing elements 502, arranged in rows and columns (e.g., M rows and N columns in an M×N array), such that results output by one processing element 502 can be input into another processing element 502. In some PE arrays, processing elements 502 that are not on the outside edges of PE array 500 may receive data from other processing elements 502, rather than from a memory subsystem of the NN accelerator.

In some embodiments, PE array 500 may use systolic execution, where data may arrive at each processing element 502 from different directions at regular intervals. In some examples, input data can flow into processing element array 500 from the left and weight values can be loaded at the top. In some examples, weights and input data can flow from the left and partial sums can flow from top to bottom. In some examples, input data can flow into processing element array 500 from the left and weight values and partial sums can flow from top to bottom. The numbers of columns and rows in PE array 500 may determine the computational capacity of processing element array 500. In one example as shown in FIG. 5, the number of rows in processing element array 500 may determine the number of input feature maps that can be processed in parallel, and the number of columns in processing element array 500 may determine the number of filter sets that can be applied in parallel to input data. The number of rows and/or the number of columns may also determine the memory bandwidth requirement for achieving the maximum utilization of processing element array 500. Processing element array 500 can have, for example, 64 columns and 64 rows, 32 columns and 32 rows, or some other numbers of columns and rows.

In the illustrated example, each row of PE array 500 may process one input channel comprising multiple input data elements, such as a one-dimensional vector (e.g., with H×W×B elements) representing a flattened multi-dimensional matrix (e.g., H×W×B). For example, when PE array 500 is to process C input channels (520, 522, 524, . . . , and 526), a first row (510) of PE array 500 may receive input data elements of input channel 1 (520), a second row (512) may receive input data elements of input channel 2 (522), a third row (514) may receive input data elements of input channel 3 (524), . . . , and an Mth row (516) may receive input data elements of input channel c (526). Each column of PE array 500 may receive weights for a filter, such as a one-dimensional vector (e.g., with C×R×S elements) representing a flattened multi-channel filter. For example, a first column (511) of PE array 500 may receive weights of filter 1 (530), a second column (513) may receive weights of filter 2 (532)), a third column (515) may receive weights of filter 3 (534), . . . , and an Nth column (517) may receive weights of filter k (536). Each column of PE array 500 may generate weighted sums of input data elements from different input channels as output data of an output channel (also referred to as an output feature map (OFMAP)), such as OFMAP 1 (540), OFMAP 2 (542), OFMAP 3 (544), . . . , or OFMAP k (546).

An example of a processing element 502 is illustrated in an inset diagram in FIG. 5. As illustrated, processing element 502 may include a multiply-accumulate (MAC) circuit. Inputs to processing element 502 can include, for example, input data I and a weight value W, where input data I may be a value taken from either a set of input data or a set of intermediate results, and weight value W may be from a set of weight values. In some implementations, a PE 502 may receive input data I from a preceding PE 502 (e.g., on the left) in the same row (or from external circuitry) via a row input bus. In some implementations, a PE 502 may also receive inputs (e.g., weight value W or partial sum (PSUM)) from a preceding PE 502 (e.g., on top) in the same column (or from external circuitry) via a column input bus. A PE 502 may perform floating point or integer arithmetic operations (e.g., multiplication) on input data I and weight value W, add the weighted input data to the PSUM, and pass the updated PSUM to the PE below in the same column (e.g., through the column output bus). The partial sum represents the weighted sum of input data elements of input data sets. In some implementations, a PE 502 may also forward the inputs to a subsequent PE 502 (e.g., to the right) in the same row, via a row output bus. The PE 502 at the bottom row of each column may generate a weighted sum of input data elements received by all PEs in the column.

In some embodiments, the operations of each PE 502 of PE array 500 may be synchronized to a clock signal to improve the interoperability between PE array 500 and other components of the neural network processor. In some embodiments, each PE 502 may also include sequential logic circuitries (e.g., registers, latches, flip-flops, state machines, etc.) to store input data, weights, and partial sums, and to synchronize the flow of the data into and out of the circuitry. The sequential logic circuitry of each PE can be clocked by either the same clock signal or a replica of the clock signal, such that data may be synchronously shifted into and/or out of the PE sequentially during the clock cycles.

The size of the data used in each layer, such as the dimensions of input data for each channel, the number of channels, the number of weights (e.g., filters) to be applied to the input data, the dimension of each filter, and the like, can be very large. For example, a convolutional neural network (ConvNet or CNN) may include thousands or more of processing nodes and millions or more of weights and input data elements. Some applications (e.g., natural language processing, autonomous navigation, and hand/eye tracking described above) may need almost instantaneous inference results with minimal latency and high throughput, and/or may have large feature maps and/or weight matrices for large tensor operations (e.g., matrix multiplications for convolution operations). Therefore, neural network models developed to perform complex tasks may have high demand on computational power and local memory space.

In some implementations, the weights or inputs can be pre-loaded into the processing element array. In some implementations, neural network accelerators can include an on-chip buffer (referred to as a local memory or a state buffer) that can store values read from external memory (e.g., an SRAM or a DRAM). In some implementations, each PE may include small, local register files for storing input activations, weights, and intermediate results (e.g., PSUMs). Having an on-chip memory hierarchy can improve the efficiency of the operation of a neural network by reducing the number of memory accesses and memory access latencies. Movement of data, such as input activations, weights, and partial sums to be accumulated, between PEs can also reduce the number of access to the local buffers or off-chip memory. In some embodiments, the input activations may be stationary and the weights may be shifted, which may be referred to as an “input-stationary” model. In some embodiments, a “weight-stationary” model may be used, where the weights may be stationary (preloaded into the registers in the PE array) and the input may be loaded and moving during computation.

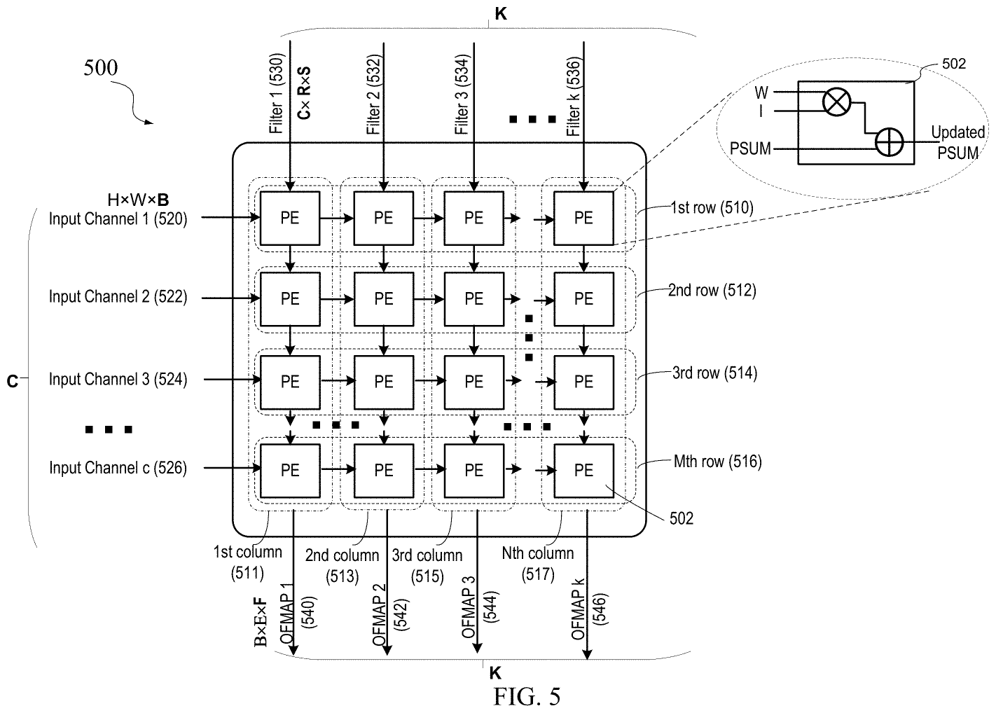

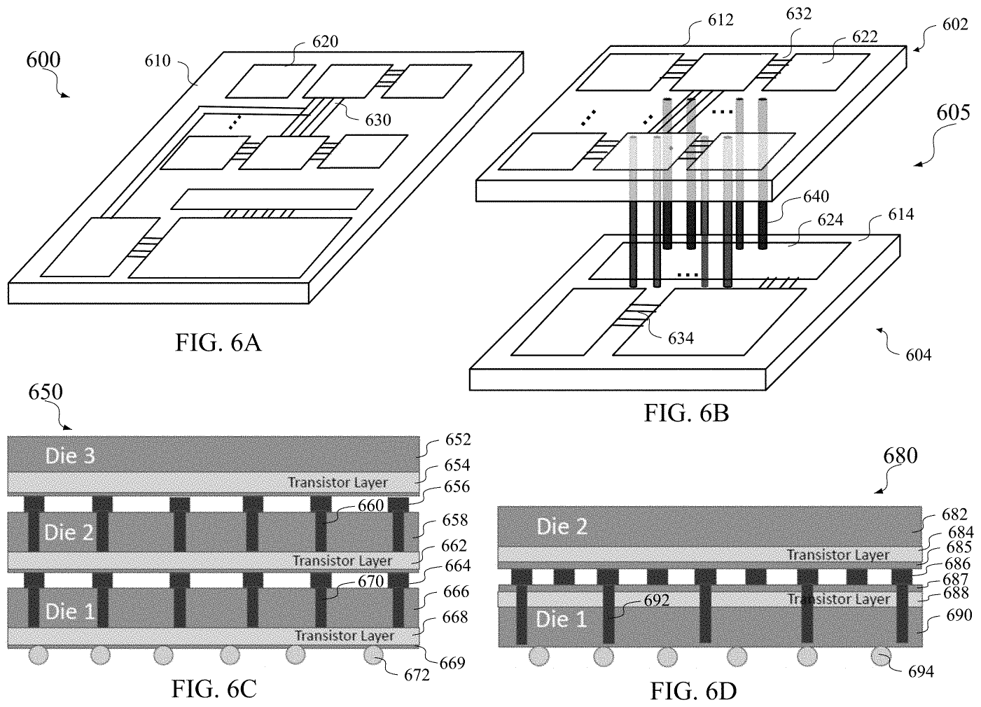

FIG. 6A illustrates an example of a two-dimensional (2D) processing engine 600 that may be used to implement a neural network. 2D processing engine 600 may be on a die 610 and may include functional blocks 620 interconnected by 2D wires 630. 2D wires 630 may be routed between functional blocks 620 and/or may be routed on additional metal layers. Due to the limited size of die 610, 2D wires 630 may need to be narrow and long in order to connect different functional blocks 620 and fit on the die. The narrow and long 2D wires 630 may have long delays and high losses, and thus may not operate at high frequencies, for example, due to signal integrity and/or power consumption issues. In addition, there may not be sufficient real estate on die 610 to fit many 2D wires 630, and thus the width of a data bus on die 610 may not be high. As such, the overall data communication bandwidth of the data bus may not be as high as desired. Furthermore, it can be difficult to monolithically integrate functional blocks 620 that may need to be fabricated using different processes/materials and/or may have different design rules onto a same die. For example, high-speed digital logic, high-density SRAM, non-volatile memory, and DRAM may need to be fabricated using different processes in order to achieve better performance. Even if memory devices such as SRAM devices can be integrated with digital logic circuits on a same die, the size of the SRAM devices may be limited, such as less than a few megabytes, less than about one megabytes, or less than about 100 kilobytes.

3D integrated circuits (ICs) may include many short interconnects to provide high bandwidth communication (e.g., >500 bits/cycle). 3D ICs may also offer reduced form factors and heterogeneous integration. For example, as described above, 3D interconnects with sub-10 μm pitches has been implemented using micro-bumps (μBumps) and/or small through-silicon-vias (TSVs) (e.g., <5 um) in advanced silicon processing technology to achieve over 10,000/mm′ die-to-die interconnect density at about 0.1 pJ/bit or lower energy consumption. 3D fabrication processes also enables heterogeneous integration of dies made of different processes/materials, thereby offering more freedom in choosing the processing technology and material system for each die based on the application and cost requirements. For example, SRAM-on-logic stacking can significantly increase local SRAM capacity (e.g., about tens of gigabytes or more) with higher memory bandwidth (about tens or hundreds of gigabytes per second) and lower access latency compared with off-chip DRAM access. This can alleviate data movement bottleneck and cost in computing systems for high performance computing applications where CPUs/GPUs may need large-capacity, on-chip memory for caching data and higher bandwidth for low latency SRAM access.

FIG. 6B illustrates an example of a 3D processing engine 605 with die-to-die stacking through 3D interconnects 640 according to certain embodiments. In the illustrated example, 3D processing engine 605 may include two dies 602 and 604 arranged in a vertical stack. Die 602 may include a silicon substrate 612 that includes multiple functional blocks 622 (e.g., SRAM blocks or banks) fabricated thereon. The SRAM on die 602 may have a high capacity, such as more than a few megabytes or a few gigabytes. Functional blocks 622 may be interconnected through 2D wires 632. Die 604 may include a silicon substrate 614 that includes functional blocks 624 (e.g., a PE array and peripheral circuits) fabricated thereon. Functional blocks 624 may be interconnected through 2D wires 634. Die 602 and Die 604 are connected through 3D interconnects 640 that includes TSVs in silicon substrate 612. 3D interconnects 640 may have a high density and short lengths, and thus may be able to provide high bandwidth for data communication, such as reading from or writing to the SRAM blocks on die 602. In various embodiments, two or more dies may be vertically stacked to form a 3D IC, and the dies may be stacked face-to-face, fact-to-back, or a combination thereof.

FIG. 6C illustrates an example of a 3D IC device 650 formed by face-to-back bonding of multiple dies according to certain embodiments. In the illustrated example, 3D IC device 650 may include a first die (die 1), a second die (die 2), and a third die (die 3) arranged in a vertical stack and interconnected through TSVs and bonding bumps (or pads). The first die may include a substrate 666 and circuits formed in transistor layer(s) 668 and metal layers 669. The first die may also include bonding bumps 672 formed thereon and electrically connected to metal layers 669 and transistor layer(s) 668. Bonding bumps 672 may be used to bond 3D IC device 650 to a printed circuit board or an interposer in a package. The first die may also include TSVs 670 and backside ponding pads (or bumps) that may be parts of bonding pads 664. The second die may include a substrate 658, circuits formed in transistor layer(s) 662 and metal layers, and frontside bonding pads that are bonded to the backside bonding pads on the first die to form bonding pads 664. The second die may also include TSVs 660 and backside ponding pads (or bumps) that may be parts of bonding pads 656. The third die may include a substrate 652, circuits formed in transistor layer(s) 654 and metal layers, and frontside bonding pads that are bonded to the backside bonding pads on the second die to form bonding pads 656.

FIG. 6D illustrates another example of a 3D IC device 680 formed by face-to-face bonding of two dies according to certain embodiments. In the illustrated example, 3D IC device 680 may include a first die (die 1) and a second die (die 2) bonded face-to-face to formed a vertical stack. The first die may include a substrate 690, circuits formed in transistor layer(s) 688 and metal layers 687, and bonding pads electrically connected to metal layers 687 and transistor layer(s) 688. Similarly, the second die may include a substrate 682, circuits formed in transistor layer(s) 684 and metal layers 685, and bonding pads electrically connected to metal layers 685 and transistor layer(s) 684. The bonding pads on the first die may be bonded to the bonding pads on the second die, for example, using metal-to-metal bonding or hybrid bonding, to form bonding pads 686. The first die may include TSVs 692, an optional redistribution layer (not shown), and bonding bumps 694 on the back side of substrate 690. Bonding bumps 694 may be used to bond 3D IC device 680 to a printed circuit board or an interposer in a package.

As described above, for specialized neural network accelerators built for compute-intensive deep neural network workloads, the overall system performance and energy efficiency are often bounded by data movements between PE arrays and memory systems. For example, the memory bandwidth may limit the system throughput, and the memory capacity may limit the throughput and energy efficiency. Thus, it can be difficult to achieve high performance and energy efficient DNN accelerators using 2D ICs described above with respect to FIG. 6A.

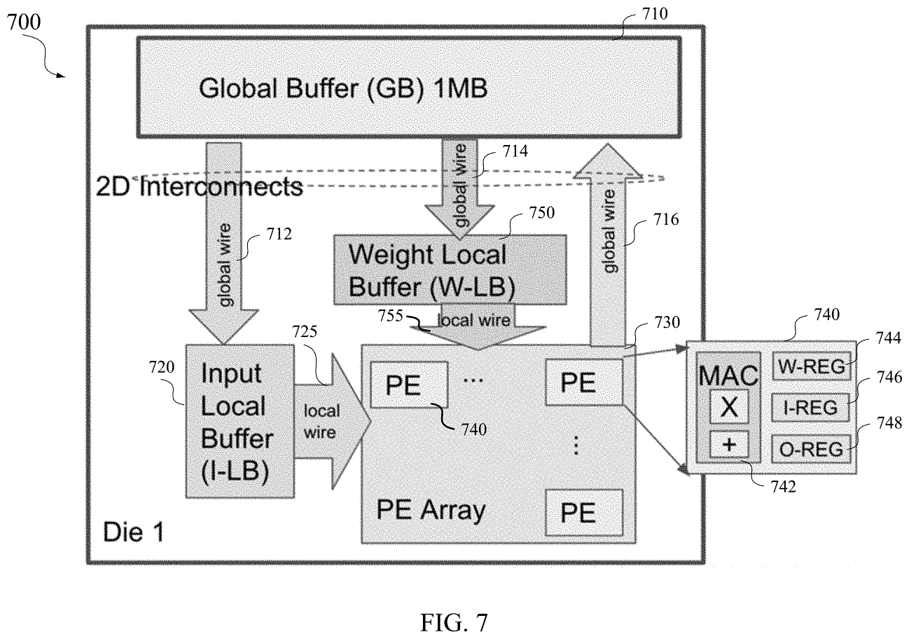

FIG. 7 includes a simplified block diagram of an example of a 2D NN accelerator 700 implemented using a 2D IC as described above with respect to FIG. 6A. 2D NN accelerator 700 may also be referred to as “Baseline 1” design in the following description. 2D NN accelerator 700 may include a global buffer (GB) 710, which may have a size about one megabytes or larger and may be used to store input activations, weights, and/or output activations. 2D NN accelerator 700 may also include a PE array 730, an input local buffer (I-LB) 720, and a weight local buffer (W-LB) 750. GB 710 may be connected to I-LB 720 through 2D interconnects 712 to load input activations into I-LB 720. GB 710 may be connected to W-LB 750 through 2D interconnects 714 to load weights into W-LB 750. GB 710 may also be connected to PE array 730 through 2D interconnects 716 to receive output data (e.g., weighted sums) from PE array 730. 2D interconnects 712, 714, and 716 may be global interconnects and may have long lengths and/or narrow bus widths, and thus may have low bandwidths. I-LB 720 and W-LB 750 may have small sizes and may be close to PE array 730. I-LB 720 may be connected to PE array 730 through 2D interconnects 725, and W-LB 750 may be connected to PE array 730 through 2D interconnects 755. Both 2D interconnects 725 and 2D interconnects 755 may be local interconnects and may have short lengths and/or wide bus widths. Each PE 740 in PE array 730 may include a MAC unit 742, a weight register (W-REG) 744 for storing weights, an input register (I-REG) 746 for storing input activations, and an output register (O-REG) 748 (also referred to as PSUM register). Even though not shown in FIG. 7, 2D NN accelerator 700 may include some other circuits, such as a light-weight CPU or microcontroller unit (MCU) for controlling the operations of 2D NN accelerator 700, or a direct memory access (DMA) controller or a double data rate (DDR) interface for data communication between the global buffer and a large office-chip memory, such as system DRAM. As described above, the on-chip memory hierarchy that includes the global buffer, the local buffers, and the in-PE registers can improve the efficiency of the operation of a neural network by reducing memory accesses and memory latencies. However, the bandwidths of the on-die global interconnects may be low and the capacity of the on-die global buffer may be low.

3D ICs described above, for example, with respect to FIGS. 6B-6D, may include many short 3D interconnects to provide high-bandwidth communication (e.g., >500 bits/cock cycle) between global buffers and local buffers and between the global buffers and the PE array, and thus may be suitable for implementing DNN accelerators. For example, advanced 3D die-stacking techniques may achieve 3D interconnects with pitches at or below 10 μm or densities about or over 1×10⁴ interconnects per mm². Therefore, for an edge inference accelerator having a die size of about 0.5 mm² to about 1 mm² at advanced nodes (e.g., about 7 nm and below) and moderate frequencies (e.g., about 500 MHz), the die-to-die 3D interconnection can support a bandwidth of 1024 bits/cycle or higher for either read or write. As also described above, 3D ICs may also offer reduced form factors and heterogeneous integration, and thus may be suitable for use in mobile devices, such AR/VR HMDs.

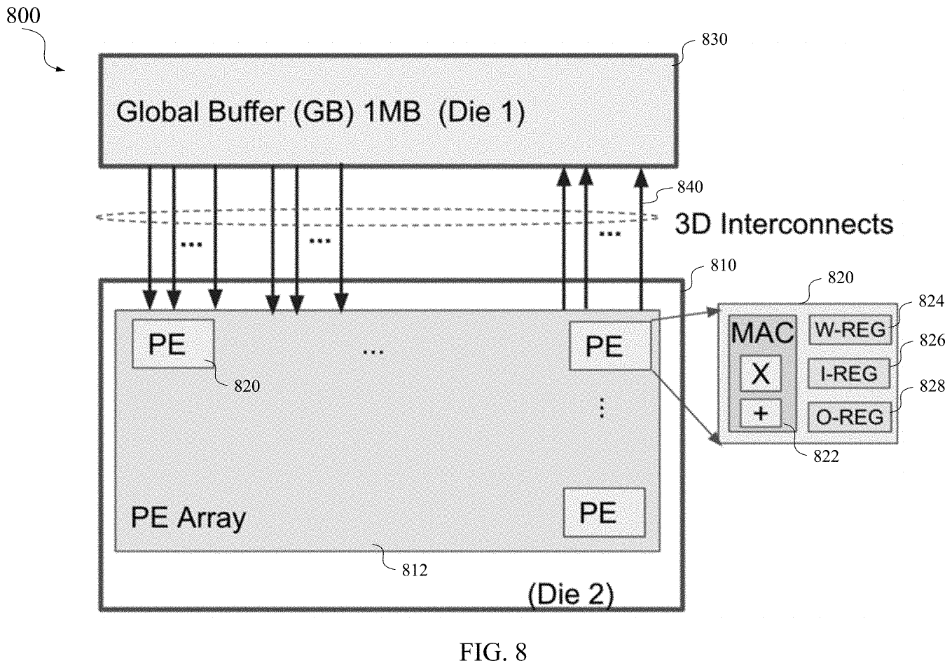

FIG. 8 includes a simplified block diagram of an example of a 3D NN accelerator 800 including a memory die 830 and a logic die 810 electrically connected through 3D interconnects 840. 3D NN accelerator 800 may also be referred to as “Baseline 2” design in the following description. In the illustrated example, memory die 830 may include a global buffer that has a size of 1 MB or larger. Logic die 810 may include a PE array 812 that includes a 2D array of PEs 820. Each PE 820 may include a MAC unit 822, a weight register (W-REG) 824 for storing weights, an input register (I-REG) 826 for storing input activations, and an output register (0-REG) 828 for storing intermediate results (e.g., PSUMs). The PE array may be connected to the global buffer on memory die 830 through high-bandwidth 3D interconnects 840. In 3D NN accelerator 800, logic die 810 may not include local buffers such as I-LB 720 or W-LB 750. Even though not shown in FIG. 8, 3D NN accelerator 800 may include some other peripheral circuits.

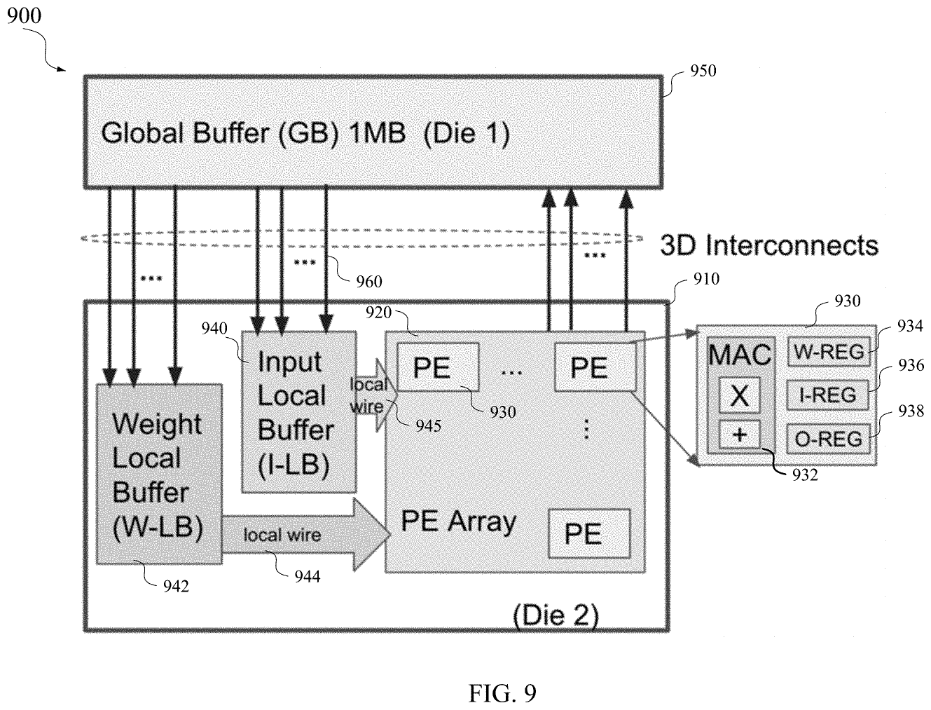

FIG. 9 includes a simplified block diagram of another example of a 3D NN accelerator 900 including a memory die 950 electrically connected to a logic die 910 with local memory through 3D interconnects 960. 3D NN accelerator 900 may also be referred to as “Baseline 3” design in the following description. In the illustrated example, memory die 950 may include a global buffer that has a size of 1 MB or larger. Logic die 910 may include a PE array 920 that includes a 2D array of PEs 930. Each PE 930 may include a MAC unit 932, a weight register (W-REG) 934 for storing weights, an input register (I-REG) 936 for storing input activations, and an output register (O-REG) 938 for storing intermediate results. Logic die 910 may also include local buffers such as input local buffer (I-LB) 940 and weight local buffer (W-LB) 942. PE array 920, I-LB 940, and W-LB 942 may be connected to the global buffer on memory die 950 through high-bandwidth 3D interconnects 960. I-LB 940 may be connected to PE array 920 through 2D interconnects 945, and W-LB 942 may be connected to PE array 920 through 2D interconnects 944. Both 2D interconnects 944 and 2D interconnects 945 may be local interconnects. Thus, 3D NN accelerator 900 may have an in-package memory hierarchy that includes the global buffer on memory die 950, input local buffer I-LB 940, weight local buffer W-LB 942, and in-PE registers, all of which may be connected to the logic circuits (e.g., MAC units 932) through high-speed and/or high bandwidth interconnects.

Emerging applications such as AR and VR application may need moderate performance in machine learning tasks but a more stringent power efficiency performance. Unlike CPU/GPU workloads, AR/VR neural networks may be compressed and quantized for running on devices with power and thermal constraints. To achieve low latency and high energy efficiency for always-accessible user experiences, AR/VR hardware needs to reduce data movement cost between different modules, and needs to have a small form factor due to area or size constraint of the wearable or portable devices, such as HMDs. 3D NN accelerators 800 and 900 described above may not take full advantage of the high bandwidth offered by 3D die-to-die stacking in advanced processing technology. For example, high bandwidth offered by simply splitting SRAMs and logic circuits in two dies, which may improve performance of conventional CPUs or GPUs, may not improve the energy efficiency in 3D stacked AR/VR DNN accelerators. In addition, different AR/VR DNN layers may need different configurations for optimal energy efficiency in terms of bandwidth requirement, data reuse opportunity, temporal mapping, and spatial mapping, due to, for example, different sizes of parameters (e.g., input data, weights, and output date) in different AR/VR DNN layers. Therefore, the overall energy efficiency of a DNN accelerator implementing the AR/VR DNN may be suboptimal when the DNN accelerator has a fixed architecture for different layers of the DNN. Furthermore, to fully utilize the 3D interconnect bandwidth, more computing units may be needed to process the data, and thus larger PE arrays may be needed. However, many AR/VR NNs have been pruned and quantized with limited parameter sizes for fitting on-device, larger PE arrays (e.g., 64×64 or larger) may not be needed and may result in low hardware utilization, which is neither energy nor area efficient. Therefore, conventional 3D die-stacking architectures that may work well for reducing memory access latency and energy in general-purpose CPUs and GPUs may not be directly applicable to AR/VR applications.

To evaluate the impact of the high bandwidths offered by 3D interconnects on the energy efficiency in 3D NN accelerators, a sensitivity study has been performed to show the minimum energy consumption and latency as a function of bandwidth for different AR NN layers of an AR/VR DNN. 2D NN accelerator 700 and 3D NN accelerators 800 and 900 described above were evaluated and the results are described below.

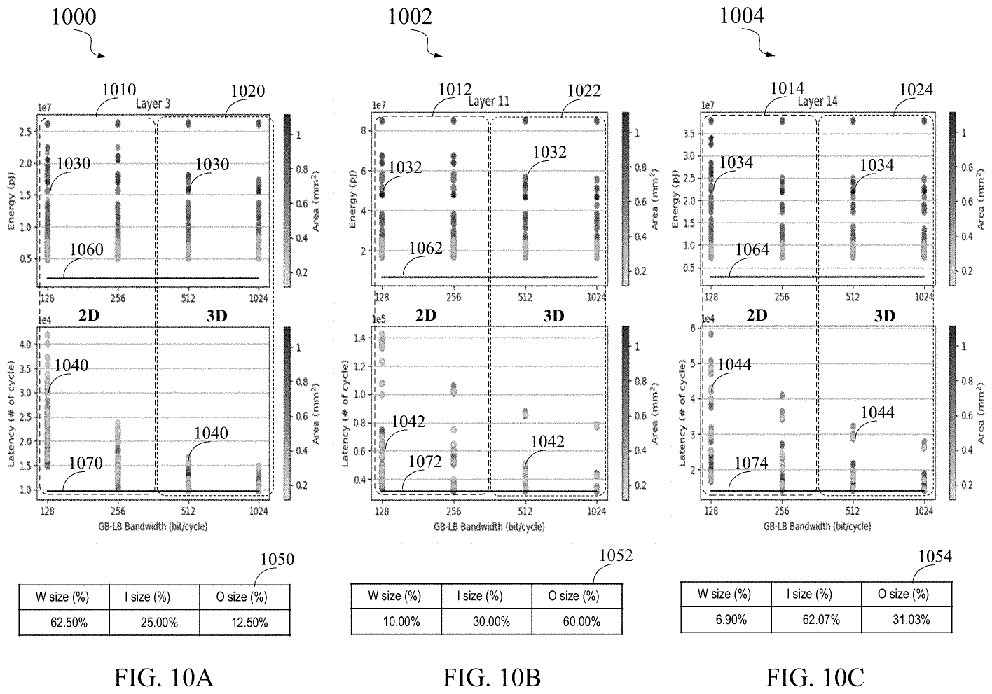

FIGS. 10A-10C illustrate energy consumption and latency of examples of NN accelerators with different data communication bandwidths for executing different AR NN layers of an edge inference NN. Each data point in FIGS. 10A-10C corresponds to a NN accelerator design with a unique combination of the input local buffer size, the weight local buffer size, the weight register size, the input register size, and the output register size. Data points for a same bandwidth correspond to design variations of a same 2D or 3D NN accelerator architecture with different memory size combinations, and thus may correspond to different silicon areas. In the examples shown in FIGS. 10A-10C, 1392 different memory size combinations are evaluated and plotted at each bandwidth, and each of the NN accelerator design may include a PE array with 32×32 PEs.

FIG. 10A includes a diagram 1000 showing energy consumption and latency of examples of NN accelerators with different data communication bandwidths for executing an AR NN layer (e.g., layer 3). In FIG. 10A, the horizontal axes correspond to the data communication bandwidth. Data points in box 1010 correspond to design variations of a same 2D NN accelerator architecture, such as 2D NN accelerator 700, which may have data communication bandwidth below about 512 bits per clock cycle, such as 256 bits/cycle or 128 bits/cycle. Data points in box 1020 correspond to design variations of a same 3D NN accelerator, such as 3D NN accelerator 900, which may have data communication bandwidths at or greater than about 512 bits per clock cycle, such as about 1024 bits/cycle. Each data point 1030 in FIG. 10A indicates the energy consumption and silicon area of a NN accelerator design with a unique memory size combination. A line 1060 shows the energy consumption of the MAC operations, which may be the minimum energy consumption of an accelerator with a certain number of PEs in the PE array, such as a PE array with 32×32 PEs. Each data point 1040 in FIG. 10A indicates the latency of a NN accelerator design with a unique memory size combination. A line 1070 shows the latency of the MAC operations, which may be the minimum latency of an accelerator with a certain number of PEs in the PE array.

A table 1050 in FIG. 10A show the relative sizes of the weights, input activations, and output data associated with (e.g., used or generated by) the AR NN layer (e.g., layer 3) of the edge inference NN. For example, the weights may be about 62.5% of the total data associated with the AR NN layer, the input activations may be about 25% of the total data associated with the AR NN layer, whereas the output data may be about 12.5% of the total data associated with the AR NN layer. Thus, the AR NN layer may need more local memory for storing weights and/or may need higher bandwidth for fetching weights from the global buffer or system memory (e.g., DRAM in another package).

FIG. 10B includes a diagram 1002 showing energy consumption and latency of examples of NN accelerators with different data communication bandwidths for executing an AR NN layer (e.g., layer 11) of the edge inference NN. In FIG. 10B, the horizontal axes correspond to the data communication bandwidth. Data points in box 1012 correspond to design variations of a same 2D NN accelerator architecture, such as 2D NN accelerator 700, which may have data communication bandwidth below about 512 bits per clock cycle. Data points in box 1022 correspond to design variations of a same 3D NN accelerator, such as 3D NN accelerator 900, which may have data communication bandwidth at or greater than about 512 bits per clock cycle. Each data point 1032 in FIG. 10B indicates the energy consumption and silicon area of a NN accelerator design with a unique memory size combination. A line 1062 shows the energy consumption of the MAC operations, which may be the minimum energy consumption of an accelerator with a certain number of PEs in the PE array, such as a PE array with 32×32 PEs. Each data point 1042 in FIG. 10B indicates the latency of a NN accelerator design with a unique memory size combination. A line 1072 shows the latency of the MAC operations, which may be the minimum latency of an accelerator with a certain number of PEs in the PE array.

A table 1052 in FIG. 10B show the relative sizes of the weights, input activations, and output data associated with the AR NN layer (e.g., layer 11) of the edge inference NN. For example, the weights may be about 10.0% of the total data associated with the AR NN layer, the input activations may be about 30% of the total data associated with the AR NN layer, whereas the output data may be about 60% of the total data associated with the AR NN layer. Thus, the AR NN layer may need more local memory for storing output data and/or may need higher bandwidth for sending output data to the global buffer or system memory (e.g., DRAM in another package).

FIG. 10C includes a diagram 1004 showing energy consumption and latency of examples of NN accelerators with different data communication bandwidths for executing an AR NN layer (e.g., layer 14). In FIG. 10C, data points in box 1014 correspond to design variations of a same 2D NN accelerator architecture, such as 2D NN accelerator 700, which may have data communication bandwidth below about 512 bits per clock cycle. Data points in box 1024 correspond to design variations of a same 3D NN accelerator, such as 3D NN accelerator 900, which may have data communication bandwidth at or greater than about 512 bits per clock cycle. Each data point 1034 in FIG. 10C indicates the energy consumption and silicon area of a NN accelerator design with a unique memory size combination. A line 1064 shows the energy consumption of the MAC operations, which may be the minimum energy consumption of an accelerator with a certain number of PEs in the PE array, such as a PE array with 32×32 PEs. Each data point 1044 in FIG. 10C indicates the latency of a NN accelerator design with a unique memory size combination. A line 1074 shows the latency of the MAC operations, which may be the minimum latency of an accelerator with a certain number of PEs in the PE array.

A table 1054 in FIG. 10C show the relative sizes of the weights, input activations, and output data associated with the AR NN layer (e.g., layer 14) of the edge inference NN. For example, the weights may be about 6.9% of the total data associated with the AR NN layer, the input activations may be about 62.07% of the total data associated with the AR NN layer, whereas the output data may be about 31.03% of the total data associated with the AR NN layer. Thus, the AR NN layer may need more local memory for storing input activations and/or may need higher bandwidth for fetching input activations form the global buffer or system memory (e.g., DRAM in another package).

FIGS. 10A-10C show that minimum energy consumption can be achieved at mediate bandwidths (e.g., about 256 bits/cycle), which may be provided by 2D interconnects in 2D NN accelerators. Thus, by optimizing the 2D NN accelerator design (e.g., selecting appropriate memory sizes), lower energy consumption can be achieved for most of the AR NN layers, without requiring the high bandwidth offered by 3D interconnects (e.g. >512 bits/cycle). In addition, FIGS. 10A-10C indicate that different AR NN layers may use different numbers of input channels, filters, batches, and thus different amounts of input data, filter data, and output data. Therefore, different AR NN layers may need different spatial mapping to unroll loops in the convolution operations onto the PE array, and may have different requirements on the memory sizes and/or bandwidths for the input activations, weights, and output data, in order to achieve better energy efficiency. As such, using an accelerator with a fixed configuration may not achieve desired energy efficiency for all AR NN layers. Customizing the memory configuration (e.g., memory size combination) of the 2D DNN accelerator design for respective AR NN layers may lower the energy consumption for most AR NN layers, even at lower data communication bandwidths (e.g., at or below 256 bits/cycle). The bandwidth improvement offered by 3D interconnects (e.g. >512 bits/cycle) may reduce the latency, but may not improve the energy efficiency of the 3D NN accelerator shown in FIGS. 8 and 9.

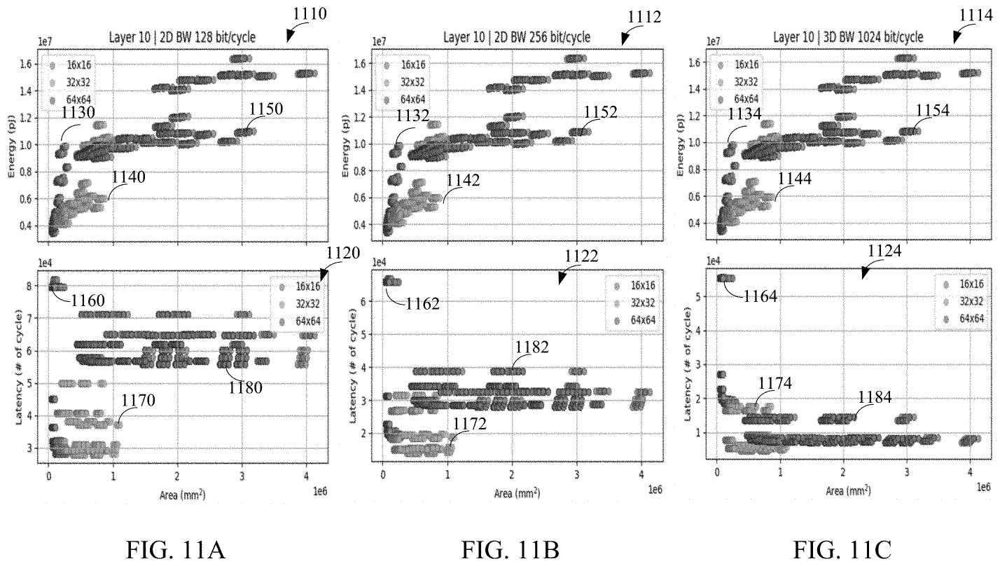

FIGS. 11A-11C illustrate energy consumption and latency of examples of NN accelerators with different data communication bandwidths and processing element (PE) array sizes for executing an AR NN layer (e.g., layer 10). Each data point in FIGS. 11A-11C corresponds to a NN accelerator design with a unique combination of the input local buffer size, the weight local buffer size, the weight register size, the input register size, the output register size, the PE array size, and the data communication bandwidth (achieved through 2D or 3D interconnects). Therefore, the data points may correspond to NN accelerators with different memory size combinations and/or different PE array sizes, and thus may also correspond to different silicon areas. In FIGS. 11A-11C, the horizontal axes correspond to silicon areas of the NN accelerators.

A diagram 1110 in FIG. 11A shows the energy consumption of examples of 2D NN accelerators with a data communication bandwidth about 128 bits/cycle. Data points 1130 in diagram 1110 correspond to 2D NN accelerators with a 16×16 PE array but different memory size combinations. Data points 1140 in diagram 1110 correspond to 2D NN accelerators with a 32×32 PE array but different memory size combinations. Data points 1150 in diagram 1110 correspond to 2D NN accelerators with a 64×64 PE array but different memory size combinations. A diagram 1120 in FIG. 11A shows the latency of examples of 2D NN accelerators with a data communication bandwidth about 128 bits/cycle. Data points 1160 in diagram 1120 correspond to 2D NN accelerators with a 16×16 PE array but different memory size combinations. Data points 1170 in diagram 1120 correspond to 2D NN accelerators with a 32×32 PE array but different memory size combinations. Data points 1180 in diagram 1120 correspond to 2D NN accelerators with a 64×64 PE array but different memory size combinations.

A diagram 1112 in FIG. 11B shows the energy consumption of examples of 2D NN accelerators with a data communication bandwidth about 256 bits/cycle. Data points 1132 in diagram 1112 correspond to 2D NN accelerators with a 16×16 PE array but different memory size combinations. Data points 1142 in diagram 1112 correspond to 2D NN accelerators with a 32×32 PE array but different memory size combinations. Data points 1152 in diagram 1112 correspond to 2D NN accelerators with a 64×64 PE array but different memory size combinations. A diagram 1122 in FIG. 11A shows the latency of examples of 2D NN accelerators with a data communication bandwidth about 256 bits/cycle. Data points 1162 in diagram 1122 correspond to 2D NN accelerators with a 16×16 PE array but different memory size combinations. Data points 1172 in diagram 1122 correspond to 2D NN accelerators with a 32×32 PE array but different memory size combinations. Data points 1182 in diagram 1122 correspond to 2D NN accelerators with a 64×64 PE array but different memory size combinations.

A diagram 1114 in FIG. 11C shows the energy consumption of examples of 3D NN accelerators with a data communication bandwidth about 1024 bits/cycle. Data points 1134 in diagram 1114 correspond to 3D NN accelerators with a 16×16 PE array but different memory size combinations. Data points 1144 in diagram 1114 correspond to 3D NN accelerators with a 32×32 PE array but different memory size combinations. Data points 1154 in diagram 1114 correspond to 3D NN accelerators with a 64×64 PE array but different memory size combinations. A diagram 1124 in FIG. 11A shows the latency of examples of 3D NN accelerators with a data communication bandwidth about 128 bits/cycle. Data points 1164 in diagram 1124 correspond to 3D NN accelerators with a 16×16 PE array but different memory size combinations. Data points 1174 in diagram 1124 correspond to 3D NN accelerators with a 32×32 PE array but different memory size combinations. Data points 1184 in diagram 1124 correspond to 3D NN accelerators with a 64×64 PE array but different memory size combinations.

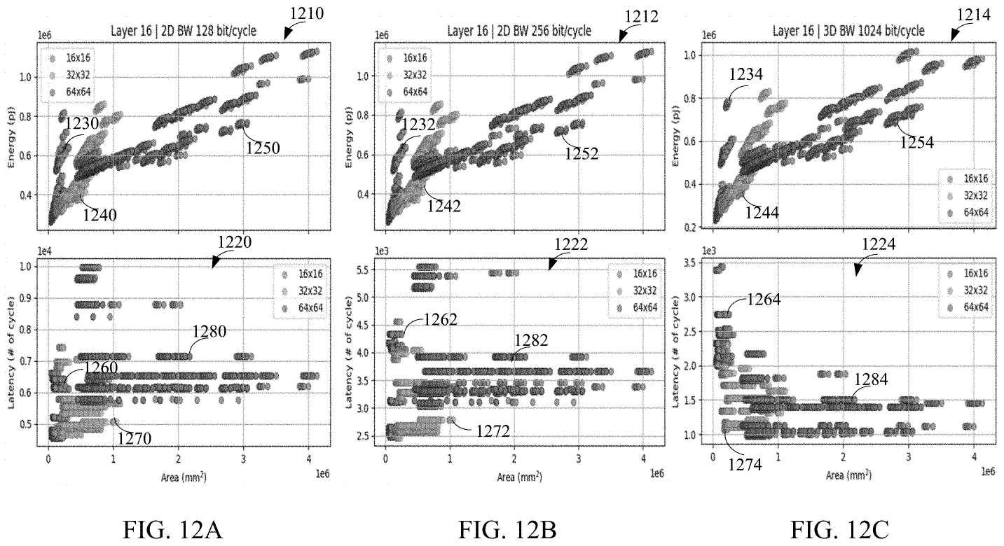

FIGS. 12A-12C illustrate energy consumption and latency of examples of NN accelerators with different data communication bandwidths and PE array sizes for executing an AR NN layer (e.g., layer 16). Each data point in FIGS. 12A-12C corresponds to a NN accelerator design with a unique combination of the input local buffer size, the weight local buffer size, the weight register size, the input register size, the output register size, the PE array size, and the data communication bandwidth (achieved through 2D or 3D interconnects). Therefore, the data points may correspond to NN accelerators with different memory size combinations and/or different PE array sizes, and thus may also correspond to different silicon areas. In FIGS. 12A-12C, the horizontal axes correspond to silicon areas of the NN accelerators.

A diagram 1210 in FIG. 12A shows the energy consumption of examples of 2D NN accelerators with a data communication bandwidth about 128 bits/cycle. Data points 1230 in diagram 1210 correspond to 2D NN accelerators with a 16×16 PE array but different memory size combinations. Data points 1240 in diagram 1210 correspond to 2D NN accelerators with a 32×32 PE array but different memory size combinations. Data points 1250 in diagram 1210 correspond to 2D NN accelerators with a 64×64 PE array but different memory size combinations. A diagram 1220 in FIG. 12A shows the latency of examples of 2D NN accelerators with a data communication bandwidth about 128 bits/cycle. Data points 1260 in diagram 1220 correspond to 2D NN accelerators with a 16×16 PE array but different memory size combinations. Data points 1270 in diagram 1220 correspond to 2D NN accelerators with a 32×32 PE array but different memory size combinations. Data points 1280 in diagram 1220 correspond to 2D NN accelerators with a 64×64 PE array but different memory size combinations.

A diagram 1212 in FIG. 12B shows the energy consumption of examples of 2D NN accelerators with a data communication bandwidth about 256 bits/cycle. Data points 1232 in diagram 1212 correspond to 2D NN accelerators with a 16×16 PE array but different memory size combinations. Data points 1242 in diagram 1212 correspond to 2D NN accelerators with a 32×32 PE array but different memory size combinations. Data points 1252 in diagram 1212 correspond to 2D NN accelerators with a 64×64 PE array but different memory size combinations. A diagram 1222 in FIG. 12A shows the latency of examples of 2D NN accelerators with a data communication bandwidth about 128 bits/cycle. Data points 1262 in diagram 1222 correspond to 2D NN accelerators with a 16×16 PE array but different memory size combinations. Data points 1272 in diagram 1222 correspond to 2D NN accelerators with a 32×32 PE array but different memory size combinations. Data points 1282 in diagram 1222 correspond to 2D NN accelerators with a 64×64 PE array but different memory size combinations.

A diagram 1214 in FIG. 12C shows the energy consumption of examples of 3D NN accelerators with a data communication bandwidth about 1024 bits/cycle. Data points 1234 in diagram 1214 correspond to 3D NN accelerators with a 16×16 PE array but different memory size combinations. Data points 1244 in diagram 1214 correspond to 3D NN accelerators with a 32×32 PE array but different memory size combinations. Data points 1254 in diagram 1214 correspond to 3D NN accelerators with a 64×64 PE array but different memory size combinations. A diagram 1224 in FIG. 12A shows the latency of examples of 3D NN accelerators with a data communication bandwidth about 128 bits/cycle. Data points 1264 in diagram 1224 correspond to 3D NN accelerators with a 16×16 PE array but different memory size combinations. Data points 1274 in diagram 1224 correspond to 3D NN accelerators with a 32×32 PE array but different memory size combinations. Data points 1284 in diagram 1224 correspond to 3D NN accelerators with a 64×64 PE array but different memory size combinations.

FIGS. 11A-12C show that the bandwidth improvement offered by 3D interconnects (e.g., 1024 bits/cycle) may reduce the latency, but may not reduce the energy consumption of the 3D NN accelerator for executing some NN layers. FIGS. 11A-12C also show that, for smaller parameter sizes (e.g. layer 10 and layer 16 of the AR NN), a low latency, a low energy consumption, and a small silicon area may be achieved using a PE array with about 32×32 PEs. Since many AR NNs or AR NN layers may have been pruned and quantized to have smaller parameter sizes in order to fit on mobile devices, high bandwidth 3D interconnects that may be needed to support convolutions using a large PE array (e.g., with 64×64 PEs) may not be needed for the AR NN layers with smaller parameter sizes. A larger PE array may use a larger silicon area and may result in low hardware utilization for implementing the AR NN layers with smaller parameter sizes, and may not provide energy efficient improvement for either 2D NN accelerator (e.g., with interconnect bandwidth about 128 or 256 bits/cycle) or 3D NN accelerator (e.g., with interconnect bandwidth about 512 or 1024 bits/cycle).

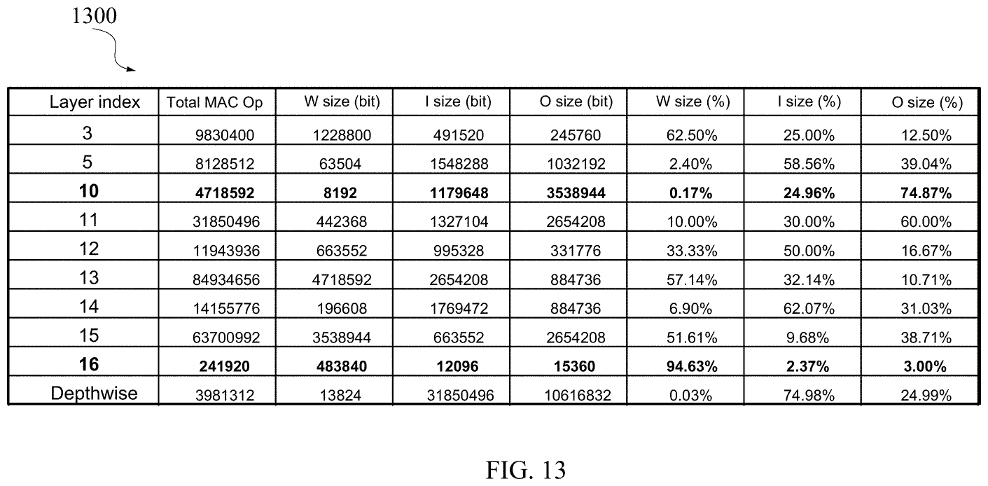

FIG. 13 includes a table 1300 illustrating various parameters of some NN layers of an example of an edge inference AR neural network according to certain embodiments. FIG. 13 shows the total number of MAC operations (total MAC Op), weight size (W size), input size (I size), and output size (O size) in each AR NN layer. FIG. 13 also shows the percentages of the weights (W size), input data (I size), and output data (O size) in the data used in each AR NN layer. FIG. 13 shows that different AR NN layers may have different respective total numbers (and percentages) of MAC operations, weight sizes, input sizes, and output sizes. Therefore, a DNN accelerator with a fixed configuration may not be able to achieve the best energy efficiency for all layers in the AR NN.

The evaluation results shown in FIGS. 10A-13 indicate that 3D die-stacking of an SRAM die and a logic die using high bandwidth 3D interconnects may not work well for NN accelerators used for at least some AR/VR applications, such as hand tracking. Other configurations of the NN accelerator may need to be changed to fully utilize the benefits provided by 3D ICs and improve the energy efficiency and latency of the NN accelerator for all layers of the AR NN.

According to certain embodiments, to fully utilize the high bandwidth offered by 3D die-stacking and further improve the energy efficiency for implementing on-device AR/VR NNs beyond what 2D designs may be able to offer, a bandwidth-aware, flexible-scheduling NN accelerator implemented by 3D stacking of a global buffer die and another die including configurable logic circuits and a configurable local buffer is disclosed herein. The NN accelerator can allocate hardware resources for implementing AR/VR NN layers based on properties of AR/VR NN layers, utilize the high bandwidth offered by 3D interconnects to reduce energy and latency, and support flexible spatial unrolling and bandwidth allocation according to properties of AR/VR NN layers. For example, based on the specific tensor operation (e.g., sizes of the tensors) of a NN layer, the NN accelerator disclosed herein may utilize the high bandwidth offered by 3D interconnects for transferring large and/or less frequently used (or reused) data (either weights or input activations) to reduce energy and latency. The NN accelerator may configure a local buffer that may have limited size and bandwidth to store small and/or more frequently used (or reused) data (either weights or input activations). The NN accelerator may also dynamically configure the connections of PEs in the PE array with other PEs, with the local buffer, and with the global buffer, to support flexible spatial unrolling of tensor operations that use tensors having various dimensions and sizes, such as various numbers of input channels, input batches, filters, and output channels.

The 3D NN accelerators disclosed herein can utilize the high 3D SRAM bandwidth (e.g., at or greater than 512 bits/cycle), and can dynamically alter the dataflow and scheduling during run-time based on the properties of each AR NN layer. The 3D NN accelerator can support different architectures by changing the operating modes (e.g., allocating different bandwidths and changing data types in the local buffer) to reduce energy consumption and latency, with minimal hardware overhead. Experimental results show that the 3D NN accelerator disclosed herein can significantly reduce the energy-delay product (EDP) in both the layer level and the application level, and thus can provide an overall energy efficiency improvement over the 2D NN accelerator design and existing 3D NN accelerator designs.

According to certain embodiments, the 3D DNN accelerator disclosed herein may include a global buffer on a first die, and a second die including a 3D bandwidth-aware, NN layer-aware controller, a configurable local buffer (C-LB) for storing weights or input activations, and a configurable PE array. The controller may include an array of arbiters for allocating bandwidths for data traffic between the global buffer and the C-LB and between the global buffer and the PE array. The controller may also include a set of NN layer configuration registers. Pre-determined configuration parameters for different AR/VR NN layers may be pre-loaded into the NN layer configuration registers. The controller may, based on the configuration parameters saved in the NN layer configuration registers (e.g., pre-determined modes for maximal layer-wise energy efficiency for respective AR/VR NN layers), configure the configurable local buffer to store either weight data or input data for the respective AR/VR NN layers. In some embodiments, the controller may, based on the configuration parameters saved in the NN layer configuration registers (e.g., pre-determined architectures and modes for maximal layer-wise energy efficiency for the respective AR/VR NN layers), control the arbiters to dynamically allocate data transfer bandwidth for data transfer between the global buffer and the PE array and the data transfer bandwidth for data transfer between the C-LB and the PE array. In some embodiments, the controller may generate and send control signals to the configurable PE array to configure the PE array for supporting flexible spatial unrolling of convolution operations that matches the allocated 3D bandwidth.

In some embodiments, the NN accelerator may include a configurable PE array with novel register partition to support flexible spatial mapping. In existing PE array designs, each PE may have a dedicated register for input data (I-REG), a dedicated register for weights (W-REGs), and a dedicated register for output data (O-REG). In the configurable PE array disclosed herein, the registers in each PE may not be assigned based on the different data types but may instead be assigned based on the different data sources, such as the LB or GB. For example, the PE disclosed herein may include a local buffer register (LB-REG) that receives data from the LB on the same die, and a global buffer register (GB-REG) that receives data from the GB on another die. The PE may also include an output register (O-REG) for storing intermediate results. The sizes of the LB-REG, GB-REG, and O-REG may be different. For example, the size of the GB-REG may be four times to eight times or more of the size of the LB-REG, while the size of the O-REG may be three times to eight times or more of the size of the GB-REG. The PE array may also include a set of multiplexers or arbiters for configuring the input and output connections of the PEs with other PEs, the local buffer, the global buffer, and other circuits (e.g., additional accumulators) in the PE array.

In some embodiments, the NN accelerator includes a flexible spatial mapping PE array that can be dynamically configured to support different mapping schemes at run-time, such as different configurations for different combinations of bandwidth allocation and LB assignment. For example, the different spatial mapping schemes may correspond to different allocated bandwidth for data communication between the LB and the PE array (LB-PE) and data communication between the GB and the PE array (GB-PE), and the LB data type (e.g., input data or weights). The controller may generate configuration signals to control the set of multiplexers or arbiters to alter the row, column, and/or output connections in the PE array to match the allocated bandwidth and support different spatial mappings for tensor operations with different numbers of input channels and corresponding filters, different numbers of output channels, and different batch sizes.

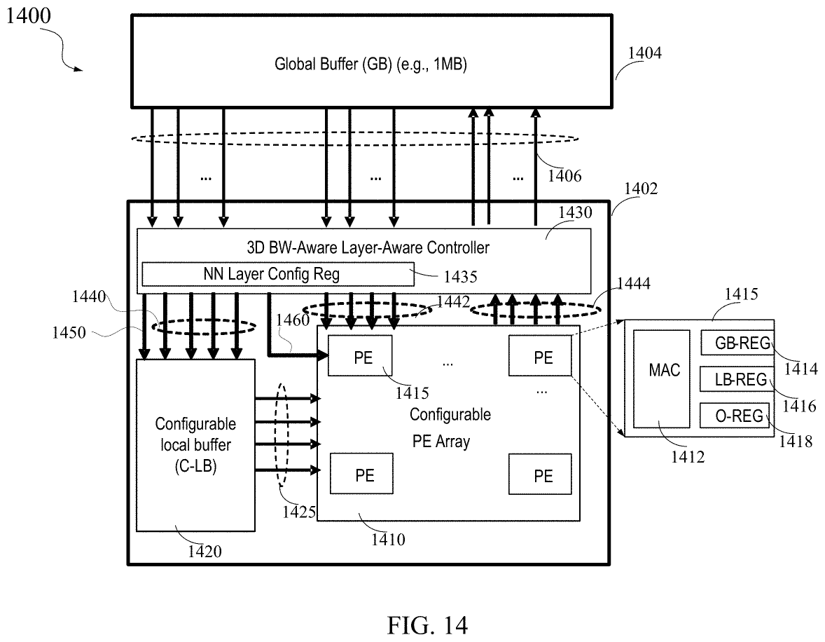

FIG. 14 is a simplified block diagram of an example of a bandwidth-aware, layer-aware 3D NN accelerator 1400 according to certain embodiments. 3D NN accelerator 1400 may include a first die 1402 and a second die 1404 connected by 3D interconnects 1406. Second die 1404 may include memory devices, such as SRAM blocks, that may be used as a global buffer. First die 1402 may include a configurable PE array 1410, a configurable local buffer 1420, and a 3D bandwidth-aware, layer-aware controller 1430. In the illustrated example, 2D interconnects 1440 may be used to send data (e.g., weights or input activations) from the global buffer to C-LB 1420 via controller 1430 and 3D interconnects 1406. 2D interconnects 1442 may be used to send data (e.g., weights and/or input activations) from the global buffer to PE array 1410 via controller 1430 and 3D interconnects 1406. 2D interconnects 1444 may be used to send data (e.g., output data) from PE array 1410 to the global buffer via controller 1430 and 3D interconnects 1406. 2D interconnects 1425 may be used to send data (e.g., weights or input activations) from C-LB 1420 to PE array 1410.

Controller 1430 may include NN layer configuration registers 1435 that may store pre-determined NN layer configuration parameters, such as spatial mapping preferences of respective NN layers. Controller 1430 may, based on the NN layer configuration parameters for each layer, dynamically allocate bandwidths for 2D interconnects 1440, 1442, and 1444, for example, using an array of arbiters. Controller 1430 may send control signals to C-LB 1420 through one or more signal lines 1450, to configure C-LB 1420 for storing either weights or input activations. The bandwidth of 2D interconnects 1425 may also be dynamically configured based on the control signals sent through one or more signal lines 1450. Controller 1430 may also send control signals to PE array 1410 through one or more signal lines 1460, to configure PE array 1410 to support different spatial mapping as described in detail below.

As illustrated, PE array 1410 may include a 2D array of PEs 1415. Each PE 1415 may include a MAC unit 1412, a register file for storing data from the global buffer (e.g., GB-REG 1414), a register file for storing data from C-LB 1420 (e.g., LB-REG 1416), and a register file for storing intermediate outputs (e.g., O-REG 1418). Compared with PE 740, 820, or 930 describe above, the registers in each PE 1415 are divided based the source of the data (e.g., the global buffer or the local buffer), rather than based on the data types (e.g., weights or input activations). PE array 1410 may also include a plurality of multiplexers (not shown in FIG. 14), where the control signals from the one or more signal lines 1460 may control the multiplexers to configure the input and output connections of PEs 1415 differently for different spatial mapping schemes.

FIG. 15 illustrates an example of a PE array 1510 for supporting flexible spatial mapping according to certain embodiments. FIG. 15 shows a die 1502 of an example of a NN accelerator 1500, which may be an example of 3D NN accelerator 1400. In the illustrated example, die 1502 may include PE array 1510, which may receive data 1504 from a global buffer (e.g., on a different die) through 3D interconnects 1506, and may also receive data 1520 from a local buffer through 2D interconnects 1525 on die 1502. PE array 1510 may include a 2D array of PEs 1515. In the example shown in FIG. 15, PE array 1510 may include 32×32 PEs 1515. As illustrated, each PE 1515 may not have dedicated registers for weights or input activations. Rather, each PE 1515 in NN accelerator 1500 may include a local buffer register (LB-REG) 1514 for receiving and storing data 1520 from the local buffer, and a global buffer register (GB-REG) 1516 for receiving and storing data 1504 from the global buffer. Each PE 1515 may also include an output register 1518 that may store intermediate results (e.g., partial sum) or final outputs. Some output registers 1518 may be connected to the global buffer so that the final outputs may be saved to the global buffer. The sizes of local buffer register 1514, global buffer register 1516, and output register 1518 may be different. For example, global buffer register 1516 may have larger capacity than local buffer register 1514, such as about 4 times to about 8 times larger than local buffer register 1514. Output register 1518 may be larger than global buffer register 1516, such as about 3 times to about 8 times larger than global buffer register 1516. A MAC unit 1512 in each PE 1515 may receive a weight and an input activation from local buffer register 1514 and global buffer register 1516 to perform a multiplication operation, add the product of the multiplication operation to the partial sum stored in output register 1518 (e.g., from the preceding PE), and save the updated partial sum back to output register 1518 and/or pass the updated partial sum to the next PE or the global buffer.

The 3D bandwidth-aware, layer-aware NN accelerator described above with respect to FIGS. 14 and 15 may be configured to perform tensor operations on tensors with various dimensions, such as different numbers of input channels, different numbers of filters and/or filter sets, different numbers of output channels, and different numbers of batches. The NN accelerator may also be configured to have either weights or input activations in the local buffer, and to allocate different bandwidths for data communication between the local buffer and the PE array and data communication between the global buffer and the PE array.

FIGS. 16A-16F illustrate 12 different configurations of an example of a bandwidth-aware, flexible-scheduling NN accelerator according to certain embodiments. The different configurations may include different spatial mappings, different data communication bandwidths, and different local buffer usage. In the illustrated examples, the configurable NN accelerator may include a global buffer (GB) with a size of about 1 MB, a local buffer, and a PE array with 32×32 PEs. The global buffer may be connected to the local buffer and the PE array through 3D interconnects that may achieve a bandwidth up to about 1024 bits/cycle (e.g., 512 bits/cycle or 1024 bits/cycle). The local buffer may be used to store either weights or input activations and may be connected to the PE array through 2D interconnects that may achieve a bandwidth up to about 512 bits/cycle (e.g., 128 bits/cycle, 256 bits/cycle, or 512 bits/cycle). Thus, there may be 3×2×2=12 different combinations of local buffer bandwidth, global buffer bandwidth, and local buffer data type. The PE array may be configured accordingly to support tensor operations on input tensors and weight tensors of different sizes. FIGS. 16A-16F shows some configuration parameters of the 12 different configurations.

In the following descriptions, K, C, and B are used to describe the dimensions of tensors used in a tensor operation after im2col operations, where K is the number of output channels (or number of filter sets), C is the product of the number of input channels (or number of filters in each filter set) and the X and Y dimensions of each filter (e.g., R×S), and B is the product of the batch size and the X and Y dimensions of each output channel (e.g., E×F). Thus, in a tensor operation W[K, C]×I[C, B]=O[K, B], the input tensor I may have dimensions of C×B, the weight tensor W may have dimensions of K×C, and the output tensor O may have dimensions of K×B. The value of B may affect the size of input tensor/and the size of output tensor O, the value of C may affect the size of input tensor I and the size of weight tensor W, whereas the value of K may affect the size of weight tensor Wand the size of output tensor O.

FIG. 16A shows two different configurations 1610 and 1612 of the configurable NN accelerator. Configurations 1610 and 1612 may have the same bandwidth allocation but different types of data (e.g., weights or input activations) in the local buffer to support different spatial mapping schemes (e.g., different K, C, and B values). In the two configurations shown in FIG. 16A, the bandwidth of data communication between the global buffer and the PE array may be 512 bits/cycle, whereas the bandwidth of data communication between the local buffer and the PE array may be 128 bits/cycle. Configuration 1610 (“Arch1_Mode1”) may be used to perform the above-described tensor operation with K=64, B=16, and C=1, where the size of the weight tensor W[K, C] (e.g., 64×1) may be larger than (e.g., about 4 times of) the size of the input tensor I[C, B] (e.g., 1×16). As such, the local buffer, which may move data to the PE array at a lower bandwidth (e.g., 128 bits/cycle), may be configured to store the smaller-sized input activations that may be reused by the PE array for the tensor operation, while the larger-sized weights may be moved from the global buffer to the PE array at the higher bandwidth (e.g., 512 bits/cycle). Configuration 1612 (“Arch1_Mode2”) may be used to perform the above-described tensor operation with K=16, B=64, and C=1, where the size of the input tensor I (e.g., 1×64) may be larger than (e.g., about 4 times of) the size of the weight tensor W (e.g., 16×1). As such, the local buffer, which may move data to the PE array at a lower bandwidth (e.g., 128 bits/cycle), may be configured to store the smaller-sized weights that may be reused by the PE array for the tensor operation, while larger-sized input activations may be moved from the global buffer to the PE array at the higher bandwidth (e.g., 512 bits/cycle).

FIG. 16B shows two different configurations 1620 and 1622 of the configurable NN accelerator. Configurations 1620 and 1622 may have the same bandwidth allocation but different types of data (e.g., weights or input activations) in the local buffer to support different spatial mapping schemes (different K, C, and B values). In the two configurations shown in FIG. 16B, the bandwidth of data communication between the global buffer and the PE array may be 512 bits/cycle, whereas the bandwidth of data communication between the local buffer and the PE array may be 256 bits/cycle. Configuration 1620 (“Arch2_Mode1”) may be used to perform the above-described tensor operation with K=32, B=16, and C=2, where the size of the weight tensor W (e.g., 32×2) may be larger than (e.g., about 2 times of) the size of the input tensor I (e.g., 2×16). As such, the local buffer, which may move data to the PE array at a lower bandwidth (e.g., 256 bits/cycle), may be configured to store smaller-sized input activations that may be reused by the PE array for the tensor operation, while the larger-sized weights may be moved from the global buffer to the PE array at the higher bandwidth (e.g., 512 bits/cycle). Configuration 1622 (“Arch2_Mode2”) may be used to perform the above-described tensor operation with K=16, B=32, and C=2, where the size of the input tensor I (e.g., 2×32) may be larger than (e.g., about 2 times of) the size of the weight tensor W (e.g., 16×2). As such, the local buffer, which may move data to the PE array at a lower bandwidth (e.g., 256 bits/cycle), may be configured to store weights that may be reused by the PE array for the tensor operation, while input activations may be moved from the global buffer to the PE array at the higher bandwidth (e.g., 512 bits/cycle).

FIG. 16C shows two different configurations 1630 and 1632 of the configurable NN accelerator. Configurations 1630 and 1632 may have the same bandwidth allocation but different types of data (e.g., weights or input activations) in the local buffer to support different spatial mapping schemes (different K, C, and B values). In the configurations shown in FIG. 16C, the bandwidth of data communication between the global buffer and the PE array may be 512 bits/cycle, and the bandwidth of data communication between the local buffer and the PE array may also be 512 bits/cycle. Configurations 1630 (“Arch3_Mode1”) and 1632 (“Arch3_Mode2”) may be used to perform the above-described tensor operation with K=16, B=16, and C=4, where the size of the weight tensor W (e.g., 16×4) may be about the same as the size of the input tensor I (e.g., 4×16). As such, the local buffer may be used to store either the input activations (e.g., as in configuration 1630) or the weights (e.g., as in configuration 1632).

FIG. 16D shows two different configurations 1640 and 1642 of the configurable NN accelerator. Configurations 1640 and 1642 may have the same bandwidth allocation but different types of data (e.g., weights or input activations) in the local buffer to support different spatial mapping schemes (e.g., different K, C, and B values). In the two configurations shown in FIG. 16D, the bandwidth of data communication between the global buffer and the PE array may be 1024 bits/cycle, whereas the bandwidth of data communication between the local buffer and the PE array may be 128 bits/cycle. Configuration 1640 (“Arch4_Mode1”) may be used to perform the above-described tensor operation with K=64, B=8, and C=2, where the size of the weight tensor W (e.g., 64×2) may be larger than (e.g., about 8 times of) the size of the input tensor I (e.g., 2×8). As such, the local buffer, which may move data to the PE array at a lower bandwidth (e.g., 128 bits/cycle), may be configured to store input activations that may be reused by the PE array for the tensor operation, while the larger-sized weights may be moved from the global buffer to the PE array at the higher bandwidth (e.g., 1024 bits/cycle). Configuration 1642 (“Arch4_Mode2”) may be used to perform the above-described tensor operation with K=8, B=64, and C=2, where the size of the input tensor I (e.g., 2×64) may be larger than (e.g., about 8 times of) the size of the weight tensor W (e.g., 8×2). As such, the local buffer, which may move data to the PE array at a lower bandwidth (e.g., 128 bits/cycle), may be configured to store the smaller-sized weights that may be reused by the PE array for the tensor operation, while input activations may be moved from the global buffer to the PE array at the higher bandwidth (e.g., 1024 bits/cycle).

FIG. 16E shows two different configurations 1650 and 1652 of the configurable NN accelerator. Configurations 1650 and 1652 may have the same bandwidth allocation but different types of data (e.g., weights or input activations) in the local buffer to support different spatial mapping schemes (e.g., different K, C, and B values). In the two configurations shown in FIG. 16E, the bandwidth of data communication between the global buffer and the PE array may be 1024 bits/cycle, whereas the bandwidth of data communication between the local buffer and the PE array may be 256 bits/cycle. Configuration 1650 (“Arch5_Mode1”) may be used to perform the above-described tensor operation with K=32, B=8, and C=4, where the size of the weight tensor W (e.g., 32×4) may be larger than (e.g., about 4 times of) the size of the input tensor I (e.g., 4×8). As such, the local buffer, which may move data to the PE array at a lower bandwidth (e.g., 256 bits/cycle), may be configured to store the smaller-sized input activations that may be reused by the PE array for the tensor operation, while the larger-sized weights may be moved from the global buffer to the PE array at the higher bandwidth (e.g., 1024 bits/cycle). Configuration 1652 (“Arch5_Mode2”) may be used to perform the above-described tensor operation with K=8, B=32, and C=4, where the size of the input tensor I (e.g., 4×32) may be larger than (e.g., about 4 times of) the size of the weight tensor W (e.g., 8×4). As such, the local buffer, which may move data to the PE array at a lower bandwidth (e.g., 256 bits/cycle), may be configured to store weights that may be reused by the PE array for the tensor operation, while input activations may be moved from the global buffer to the PE array at the higher bandwidth (e.g., 1024 bits/cycle).

FIG. 16F shows two different configurations 1660 and 1662 of the configurable NN accelerator. Configurations 1660 and 1662 may have the same bandwidth allocation but different types of data (e.g., weights or input activations) in the local buffer to support different spatial mapping schemes (e.g., different K, C, and B values). In the two configurations shown in FIG. 16F, the bandwidth of data communication between the global buffer and the PE array may be 1024 bits/cycle, whereas the bandwidth of data communication between the local buffer and the PE array may be 512 bits/cycle. Configuration 1660 (“Arch6_Mode1”) may be used to perform the above-described tensor operation with K=16, B=8, and C=8, where the size of the weight tensor W (e.g., 16×8) may be larger than (e.g., about 2 times of) the size of the input tensor I (e.g., 8×8). As such, the local buffer, which may move data to the PE array at a lower bandwidth (e.g., 512 bits/cycle), may be configured to store input activations that may be reused by the PE array for the tensor operation, while the larger-sized weights may be moved from the global buffer to the PE array at the higher bandwidth (e.g., 1024 bits/cycle). Configuration 1662 (“Arch6_Mode2”) may be used to perform the above-described tensor operation with K=8, B=16, and C=8, where the size of the input tensor I (e.g., 8×16) may be larger than (e.g., about 2 times of) the size of the weight tensor W (e.g., 8×8). As such, the local buffer, which may move data to the PE array at a lower bandwidth (e.g., 512 bits/cycle), may be configured to store weights that may be reused by the PE array for the tensor operation, while the larger-sized input activations may be moved from the global buffer to the PE array at the higher bandwidth (e.g., 1024 bits/cycle).

To support the different configurations of the 3D NN accelerator described above, the fixed-sized PE array (e.g., 32×32) may include a set of multiplexers (MUXes) or arbiters for configuring the input and output connections of the PEs with other PEs, the local buffer, the global buffer, and other circuits (e.g., additional accumulators) in the PE array. To configure the PE array to perform the different tensor operations in different configurations described above, for example, with respect to FIGS. 16A-16F, the controller may provide different control signals to MUXes in the PE array to control the data flow between PEs, between PEs and the local buffer, and between the PEs and global buffer, as described in more detail below.

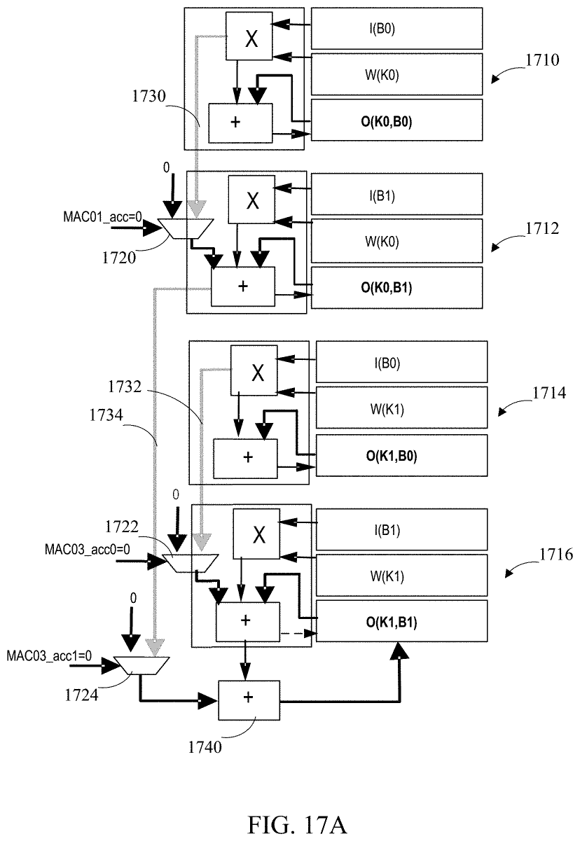

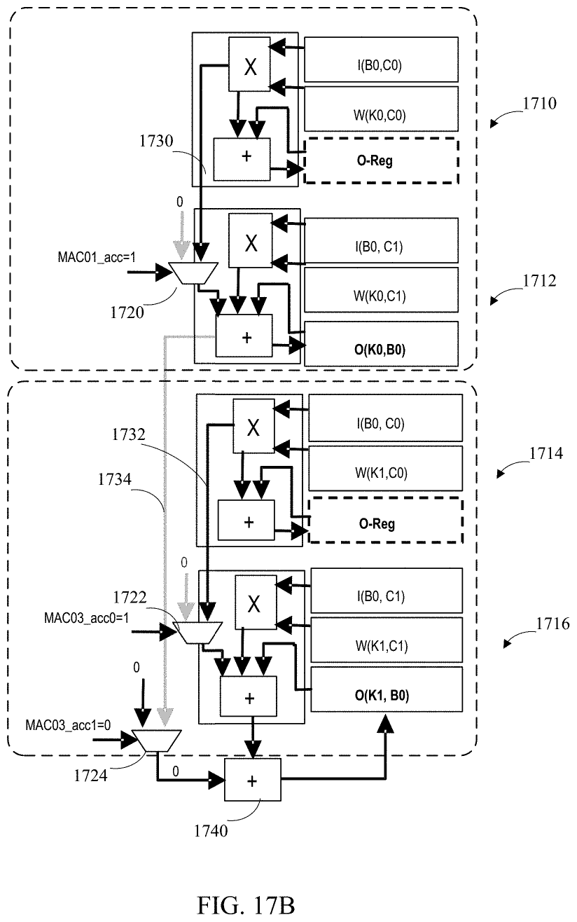

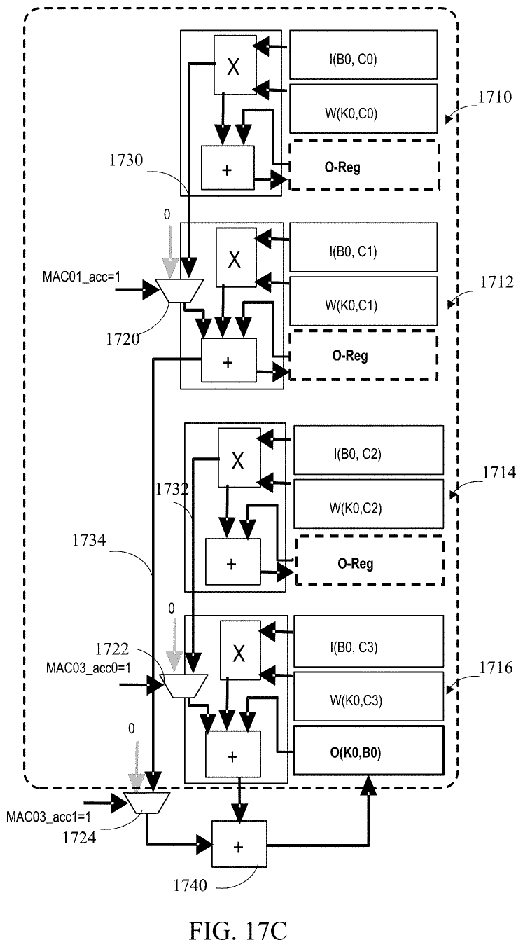

FIGS. 17A-17C illustrate examples of configurating the configurable PE array to support spatial mapping of 1, 2, and 4 input channels, respectively, according to certain embodiments. Four PEs 1710, 1712, 1714, and 1716 are shown in the examples to illustrate spatial mapping of 1, 2, and 4 channels. Other PEs in the configurable PE array may be configured in similar manners for spatial mapping of 1, 2, and 4 input channels. Each PE 1710, 1712, 1714, or 1716 includes a MAC unit and registers for storing input activations, weights, and outputs (e.g., weighted sums) of the MAC unit, where the input activations and weights may be read from either the global buffer or the local buffer according to the configuration of the NN accelerator (more specifically, the configuration of the local buffer) as descried above with respect to FIGS. 14 and 16A-16F.

In addition, the PE array may include three MUXes 1720, 1722, and 1724 and an accumulator 1740 for each group of four PEs in a column of the PE array. The three MUXes 1720, 1722, and 1724 may be controlled by control signals “MAC01_acc,” “MAC03_acc0,” and “MAC03_acc1,” respectively, to configure the PE array for spatial mapping of 1, 2, and 4 channels. The control signals may be generated by a controller, such as controller 1430, and may be used to control all similar groups of four PEs in the configurable PE array. As illustrated, the output of the multiplier of the MAC unit in PE 1710 may be connected to MUX 1720 through a signal line 1730, and the output of MUX 1720 may be connected to the accumulator of the MAC unit in PE 1712. Similarly, the output of the multiplier of the MAC unit in PE 1714 may be connected to MUX 1722 through a signal line 1732, and the output of MUX 1722 may be connected to the accumulator of the MAC unit in PE 1716. The output of the accumulator of the MAC unit in PE 1716 may or may not be directly saved to the output register in PE 1716, but may be sent to accumulator 1740. The output of the accumulator in the MAC unit of PE 1712 may also be connected to MUX 1724 through a signal line 1734. The output of MUX 1724 and the output of the accumulator in the MAC unit of PE 1716 may be summed at accumulator 1740 and the sum may be saved to the output register of PE 1716. In the examples shown in FIGS. 17A-17C, the output generation can be performed in one step, and the weighted sum accumulation may be done for up to 4 PEs in the same column.

FIG. 17A illustrates an example of configuring the PE array to support spatial mapping of tensor operations including one input channel according to certain embodiments. In the configuration shown in FIG. 17A, control signals “MAC01_acc,” “MAC03_acc0,” and “MAC03_acc1” may all be “0.” Therefore, the output of the multiplier of the MAC unit in PE 1710 may not be selected and passed on to the accumulator in the MAC unit of PE 1712 by MUX 1720, the output of the multiplier of the MAC unit in PE 1714 may not be selected and passed on to the accumulator in the MAC unit of PE 1716 by MUX 1722, and the output of the accumulator in the MAC unit of PE 1712 may not be selected and passed on to accumulator 1740 by MUX 1724. Therefore, each MAC unit in each respective PE may generate one output based on the input activation and the weight.

For example, PE 1710 may use the input activation of batch B0 and the weight of filter set K0 to generate an output element O(K0, B0) of output channel K0 for batch B0. PE 1712 may use the input activation of batch B1 and the weight of filter set K0 to generate an output element O(K0, B1) of output channel K0 for batch B1. PE 1714 may use the input activation of batch B0 and the weight of filter set K1 to generate an output element O(K1, B0) of output channel K1 for batch B0. PE 1716 may use the input activation of batch B1 and the weight of filter set K1 to generate an output element O(K1, B1) of output channel K1 for batch B1, where output element O(K1, B1) may be saved to the output register of PE 1716 through accumulator 1740.

FIG. 17B illustrates an example of configuring the PE array to support spatial mapping of tensor operations including two input channels according to certain embodiments. In the configuration shown in FIG. 17B, control signals “MAC01_acc” and “MAC03_acc0” may be set to “1” and control signal “MAC03_acc1” may be set to “0.” Therefore, the output of the multiplier in the MAC unit of PE 1710 may be selected and passed on to the accumulator in the MAC unit of PE 1712 by MUX 1720, the output of the multiplier in the MAC unit of PE 1714 may be selected and passed on to the accumulator in the MAC unit of PE 1716 by MUX 1722, whereas the output of the accumulator in the MAC unit of PE 1712 may not be selected and passed on to accumulator 1740 by MUX 1724. Therefore, PE 1710 and PE 1712 may be used to generate one output, and PE 1714 and PE 1716 may be used to generate another output.

For example, the multiplier in the MAC unit of PE 1710 may generate a first product by multiplying the input activation of input channel C0 of batch B0 with the weight of filter channel C0 of filter set K0, and the first product may be passed on to the accumulator in the MAC unit in PE 1712 by MUX 1720. The multiplier in the MAC unit of PE 1712 may generate a second product by multiplying the input activation of input channel C1 of batch B0 with the weight of filter channel C1 of filter set K0, and the accumulator in the MAC unit of PE 1712 may add the second product to the first product to generate an output element O(K0, B0) of output channel K0 for batch B0. Output element O(K0, B0) may be saved to the output register of PE 1712.

Similarly, the multiplier in the MAC unit of PE 1714 may generate a first product by multiplying the input activation of input channel C0 of batch B0 with the weight of filter channel C0 of filter set K1, and the first product may be passed on to the accumulator in the MAC unit of PE 1716 by MUX 1722. The multiplier in the MAC unit of PE 1716 may generate a second product by multiplying the input activation of input channel C1 of batch B0 with the weight of filter channel C1 of filter set K1, and the accumulator in the MAC unit of PE 1716 may add the second product to the first product to generate an output element O(K1, B0) of output channel K1 for batch B0. The output element O(K1, B0) may be saved to the output register of PE 1716 through accumulator 1740.

FIG. 17C illustrates an example of configuring the PE array to support spatial mapping of tensor operations including four input channels according to certain embodiments. In the configuration shown in FIG. 17C, control signals “MAC01_acc,” “MAC03_acc0,” and “MAC03_acc1” may all be set to “1.” Therefore, the output of the multiplier in the MAC unit of PE 1710 may be passed on to the accumulator in the MAC unit of PE 1712 by MUX 1720, the output of the multiplier in the MAC unit in PE 1714 may be passed on to the accumulator in the MAC unit of PE 1716 by MUX 1722, and the output of the accumulator in the MAC unit of PE 1712 may be passed on to accumulator 1740 by MUX 1724. Therefore, the multiplier in the MAC unit of PE 1710 may generate a first product by multiplying the input activation of input channel C0 of batch B0 with the weight of filter channel C0 of filter set K0, where the first product may be passed on to the accumulator in the MAC unit of PE 1712 by MUX 1720. The multiplier in the MAC unit of PE 1712 may generate a second product by multiplying the input activation of input channel C1 of batch B0 with the weight of filter channel C1 of filter set K0, and the accumulator in the MAC unit of PE 1712 may add the second product to the first product to generate a first partial sum. The first partial sum may be sent to accumulator 1740 through MUX 1724. Similarly, the multiplier in the MAC unit of PE 1714 may generate a third product by multiplying the input activation of input channel C2 of batch B0 with the weight of filter channel C2 of filter set K0, where the third product may be passed on to the accumulator in the MAC unit of PE 1716 by MUX 1722. The multiplier in the MAC unit of PE 1716 may generate a fourth product by multiplying the input activation of input channel C3 of batch B0 with the weight of filter channel C3 of filter set K0, and the accumulator in the MAC unit in PE 1716 may add the fourth product to the third product to generate a second partial sum. The second partial sum may also be sent to accumulator 1740. Accumulator 1740 may add the first partial sum to the second partial sum to generate an output element O(K0, B0) of output channel K0 for batch B0. The output element O(K0, B0) from accumulator 1740 may be saved to the output register of PE 1716. Thus, PEs 1710-1716 may be used to generate an output element of output channel K0 for batch B0 using the four input channels of batch B0.

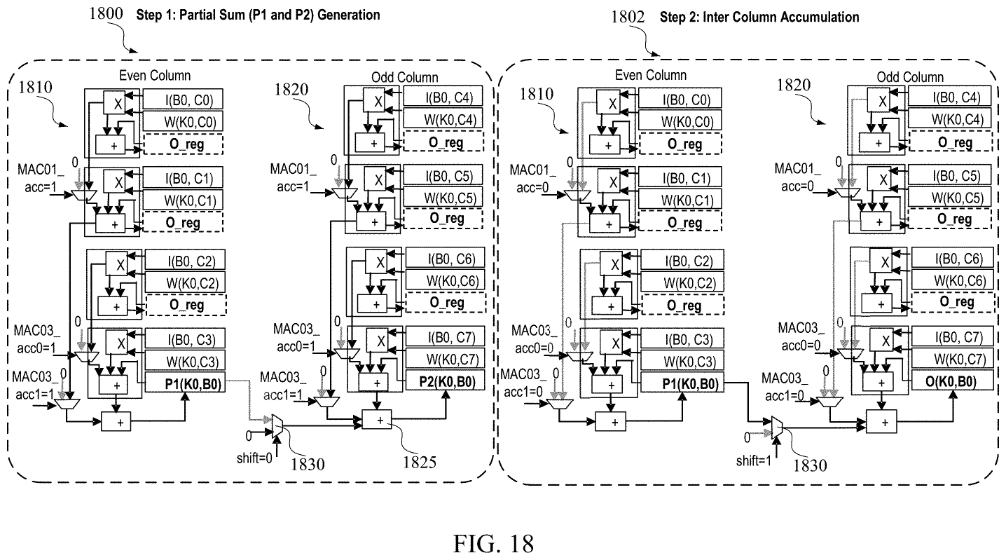

FIG. 18 illustrates an example of configuring a configurable PE array to support spatial mapping of tensor operations including 8 input channels in two steps according to certain embodiments. In FIG. 18, two PE groups 1810 and 1820 each including 4 PEs in a column as described above with FIGS. 17A-17C are shown to illustrate spatial mapping for 8 input channels. PE group 1810 and PE group 1820 may be in adjacent columns of the configurable PE array. For example, PE group 1810 may be in an even-number column (e.g., column 0, 2, . . . , or 30), and PE group 1820 may be in an odd-number column (e.g., column 1, 3, . . . , or 32). The output register of the bottom PE in PE group 1810 may be connected to a MUX 1830, and the output of MUX 1830 may be connected to an accumulator 1825 of PE group 1820, where the output of accumulator 1825 may be saved to the bottom PE in PE group 1820. MUX 1830 may be controlled by a fourth control signal “shift.”

In a first step 1800, control signals “MAC01_acc,” “MAC03_acc0,” and “MAC03_acc1” may be set to “1,” whereas control signal “shift” may be set to “0.” Therefore, PE group 1810 may operate as described above with respect to FIG. 17C to generate a first partial sum P1(K0, B0) using first 4 channels (e.g., C0, C1, C2, and C3) of input batch B0 and save first partial sum P1(K0, B0) to the output register of the bottom PE in PE group 1810. PE group 1820 may operate similarly to generate a second partial sum P2(K0, B0) using first 4 channels (e.g., C0, C1, C2, and C3) of input batch B0 and save second partial sum P2(K0, B0) to the output register of the bottom PE in PE group 1820. Because control signal “shift” is “0,” first partial sum P1(K0, B0) may not be passed by MUX 1830 to accumulator 1825.

In the second step 1802, control signals “MAC01_acc,” “MAC03_acc0,” and “MAC03_acc1” may be set to “0,” whereas control signal “shift” may be set to “1.” Therefore, first partial sum P1(K0, B0) may be passed by MUX 1830 to accumulator 1825, where accumulator 1825 may add first partial sum P1(1(0, B0) to second partial sum P2(K0, B0) to generate an output element O(K0, B0) of output channel K0 for batch B0 that includes 8 input channels. In this way, the configurable PE array may be configured to support spatial mapping of 8 input channels.

Even though not shown in FIGS. 17A-18, other similar PE groups in the configurable PE array may be configured by the four control signals “MAC01_acc,” “MAC03_acc0,” “MAC03_acc1,” and “shift” in manners similar to manners described above with respects to FIGS. 17A-18 to support spatial mapping of 1 to 8 input channels onto the configurable PE array.

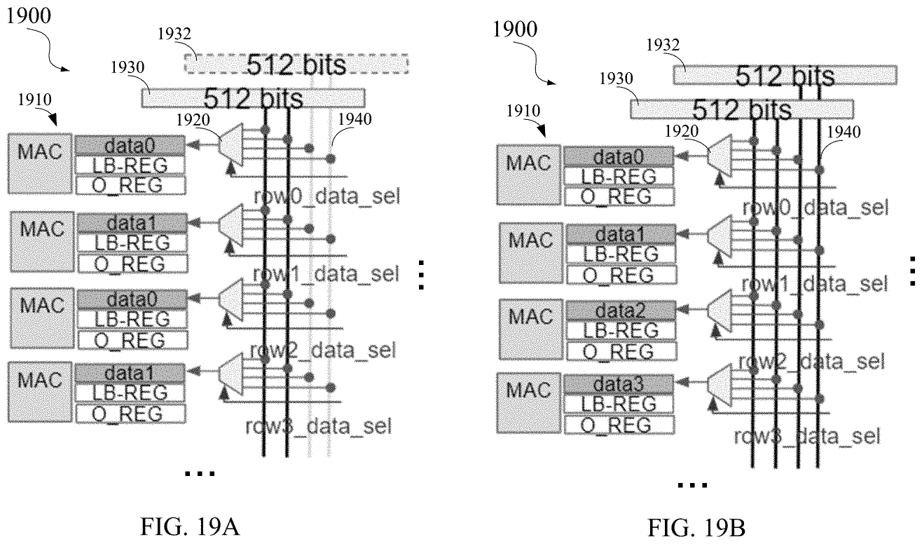

FIGS. 19A and 19B illustrate an example of a configurable column data casting design with full flexibility for supporting global buffer bandwidths of 512 and 1024 bits/cycle, respectively, according to certain embodiments. In the illustrated examples, a PE array 1900 may include 32 PE columns, where each PE column may include 32 PEs that are on 32 respective rows. Only four PEs in four rows of a PE column 1910 are shown in the illustrated examples. Each PE in PE column 1910 may include a MAC unit, a local buffer register (LB-REG) for storing data from the local buffer, a global buffer register (GB-REG) for storing data from the global buffer, and an output register, as described above. The global buffer register of each PE may be connected to GB data buses 1930 and 1932 through a MUX 1920 for communication with the global buffer. GB data bus 1930 and GB data bus 1932 may each have a bandwidth of 512 bits/cycle (i.e., 64 bytes/cycle) and may be shared by 32 PE columns. Therefore, MUXes 1920 of the PEs in a same PE column may receive up to 2 bytes from GB data bus 1930 and up to 2 bytes from GB data bus 1932 through a column bus 1940 in each clock cycle. Each MUX 1920 may include a 4-to-1 multiplexer where the inputs of MUX 1920 may receive up to 4 data elements (4 bytes) from GB data buses 1930 and 1932 through column bus 1940. Each MUX 1920 may be controlled by a row data selection control signal “row0_data_sel,” “row1_data_sel,” “row2_data_sel,” or “row3_data_sel” to store data from column bus 1940 into the global buffer register of the corresponding PE. Because each MUX 1920 has four input ports, each row data selection control signal may include two bits. Each row data selection control signal “row0_data_sel,” “row1_data_sel,” “row2_data_sel,” or “row3_data_sel” may be shared by all PE columns to control the data selection for PEs on a same row. In some embodiments, these four row data selection control signals may be reused for each group of four rows of PEs in the PE array, where each of the four row data selection control signals may be shared by MUXes 1920 for PEs on every fourth row of the PE array. In some embodiments, different row data selection control signals can be used for different rows of PEs to support more flexible column data casting. The examples shown in FIGS. 19A and 19B can provide configurable GB data connection with full flexibility for the column data spatial unrolling.

FIG. 19A illustrates an example of column data casting to support a global buffer bandwidth of 512 bits/cycle according to certain embodiments. In the illustrated example, data from the global buffer may be sent to PE array 1900 through GB data bus 1930 at 512 bits/cycle (i.e., 64 bytes/cycle), and no data may be on GB data bus 1932. MUXes 1920 of the PEs in PE column 1910 may receive 2 bytes (2 data elements) on two input ports from GB data bus 1930 through column bus 1940 in each clock cycle. The 2 data elements may be selected and stored into the global buffer registers of the PEs in PE column 1910 by MUXes 1920 based on the corresponding row data selection control signals asserted on MUXes 1920. In the example illustrated in FIG. 19A, in one clock cycle, a first data element “data0” may be saved to the GB-REGs of the PEs on the first and third rows, whereas a second data element “data1” may be saved to the GB-REGs of the PEs on the second and fourth rows. MUXes 1920 for PEs on other rows of PE column 1910 and in other PE columns may be controlled in similar manners to selectively store a data element from GB data bus 1930 into the GB-REG of each corresponding PE in each clock cycle.

FIG. 19B illustrates an example of column data casting to support a global buffer bandwidth of 1024 bits/cycle according to certain embodiments. In the illustrated example, data from the global buffer may be sent to PE array 1900 through GB data bus 1930 at 512 bits/cycle (i.e., 64 bytes/cycle) and through GB data bus 1932 at 512 bits/cycle (i.e., 64 bytes/cycle). Thus, MUXes 1920 of the PEs in PE column 1910 may receive 2 bytes (2 data elements) from GB data bus 1930 and 2 bytes (2 data elements) from GB data bus 1932 in each clock cycle. The 4 bytes (4 data elements) may be selected and stored into the global buffer registers of the PEs in PE column 1910 by MUXes 1920 based on the corresponding row data selection control signals asserted on MUXes 1920. In the example illustrated in FIG. 19B, in one clock cycle, a first data element “data0” may be saved to the GB-REG of the PE in the first row, a second data element “data1” may be saved to the GB-REG of the PE in the second row, a third data element “data2” may be saved to the GB-REG of the PE in the third row, whereas a fourth data element “data3” may be saved to the GB-REG of the PE in the fourth row. MUXes 1920 for PEs on other rows of PE column 1910 and in other PE columns may be controlled in similar manners to selectively store a data element from GB data bus 1930 into the GB-REG of each corresponding PE in each clock cycle.

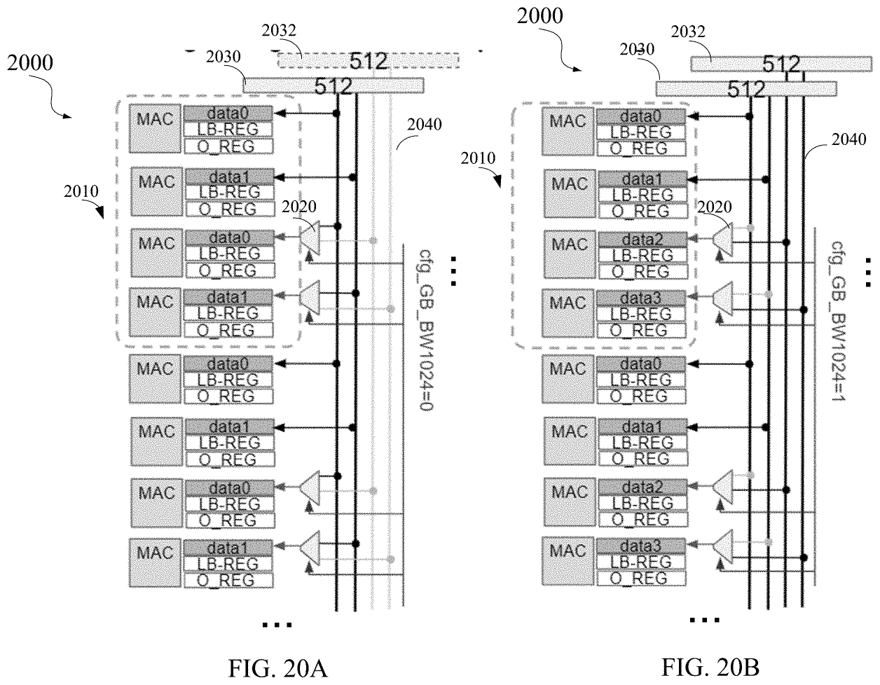

FIGS. 20A and 20B illustrate an examples of a light-weight configurable column data casting designs with low control overhead for supporting global buffer bandwidths of 512 and 1024 bits/cycle, respectively, according to certain embodiments. In the illustrated examples, a PE array 2000 may include 32 PE columns, where each PE column may include 32 PEs that are on 32 respective rows. Only eight PEs in eight rows of a PE column 2010 are shown in the illustrated examples. As described above, each PE in PE column 2010 may include a MAC unit, a local buffer register (LB-REG) for storing data from the local buffer, a global buffer register (GB-REG) for storing data from the global buffer, and an output register (O-REG). The global buffer register of each PE may be connected to GB data buses 2030 and 2032 through a column bus 2040 for communication with the global buffer. GB data bus 2030 and GB data bus 2032 may each have a bandwidth of 512 bits/cycle (i.e., 64 bytes/cycle) and may be shared by 32 PE columns. Therefore, the PEs in PE column 2010 may receive up to 2 bytes (2 data elements) from GB data bus 2030 and up to 2 bytes (2 data elements) from GB data bus 2032 in each clock cycle through column bus 2040. In contrast to the examples shown in FIGS. 19A and 19B, the examples shown in FIGS. 20A and 20B may have fixed data selection for the first row of PEs and the second row of PEs in each group of four rows of PEs. PEs in the third and fourth rows of PEs in each group of four rows of PEs may receive data from either GB data bus 2030 or GB data bus 2032 through column bus 2040 and 2-to-1 MUXes 2020. The 2-to-1 MUXes 2020 in all PE columns may be controlled by a same control signal “cfg_GB_BW1024.” The examples shown in FIGS. 20A and 20B may not provide configurable GB data connection with full flexibility for the column data spatial unrolling but may use fewer control signals and MUXes, and thus may have a low overhead.

FIG. 20A illustrates an example of configuring column data casting with low overhead to support a global buffer bandwidth of 512 bits/cycle according to certain embodiments. In the illustrated example, data from the global buffer may be sent to PE array 2000 through GB data bus 2030 at 512 bits/cycle (i.e., 64 bytes/cycle), and no data may be on GB data bus 2032. Thus, PEs in each PE column may receive a total of 2 bytes (2 data elements) from GB data bus 2030 through the corresponding column bus in each clock cycle. The first row of PEs in a group of four rows of PEs may each receive a data element (e.g., “data0” in PE column 2010) from GB data bus 2030 in each clock cycle. The second row of PEs in a group of four rows of PEs may each receive a data element (e.g., “data1” in PE column 2010) from GB data bus 2030 in each clock cycle. In the example shown in FIG. 20A, control signal “cfg_GB_BW1024” is set to “0.” Therefore, each MUX 2020 on the third row may select a data element (e.g., “data0” in PE column 2010) from GB data bus 2030 and save it to the global buffer register of the corresponding PE in each clock cycle. Similarly, each MUX 2020 on the fourth row may select a data element (e.g., “data1” in PE column 2010) from GB data bus 2030 and save it to the global buffer register of the corresponding PE in each clock cycle.

FIG. 20B illustrates an example of configuring column data casting with low overhead to support a global buffer bandwidth of 1024 bits/cycle according to certain embodiments. In the illustrated example, data from the global buffer may be sent to PE array 2000 through GB data bus 2030 at 512 bits/cycle (i.e., 64 bytes/cycle) and through GB data bus 2032 at 512 bits/cycle (i.e., 64 bytes/cycle). Thus, PEs in each PE column may receive a total of 4 bytes (4 data elements) from GB data buses 2030 and 2032 through the corresponding column bus in each clock cycle. The first row of PEs in a group of four rows of PEs may each receive a data element (e.g., “data0” in PE column 2010) from GB data bus 2030 in each clock cycle. The second row of PEs in a group of four rows of PEs may each receive a data element (e.g., “data1” in PE column 2010) from GB data bus 2030 in each clock cycle. In the example shown in FIG. 20B, control signal “cfg_GB_BW1024” is set to “1.” Therefore, each MUX 2020 on the third row may select a data element (e.g., “data2” in PE column 2010) from GB data bus 2032 and save it to the global buffer register of the corresponding PE in each clock cycle. Similarly, each MUX 2020 on the fourth row may select a data element (e.g., “data3” in PE column 2010) from GB data bus 2032 and save it to the global buffer register of the corresponding PE in each clock cycle.

Thus, in the examples shown in FIGS. 20A and 20B, only two two-to-1 MUXes may be needed for each group of four PEs, where all two-to-1 MUXes in PE array 2000 may be controlled by a same control signal (e.g., “cfg_GB_BW1024”). Therefore, the examples shown in FIGS. 20A and 20B may use only one control signals and fewer MUXes than the examples shown in FIGS. 19A and 19B, and thus may have a very low overhead.

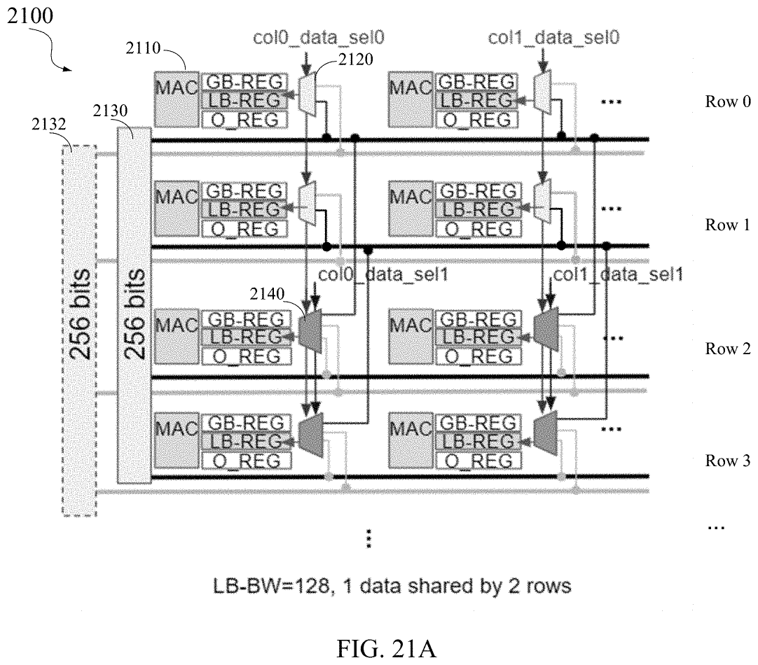

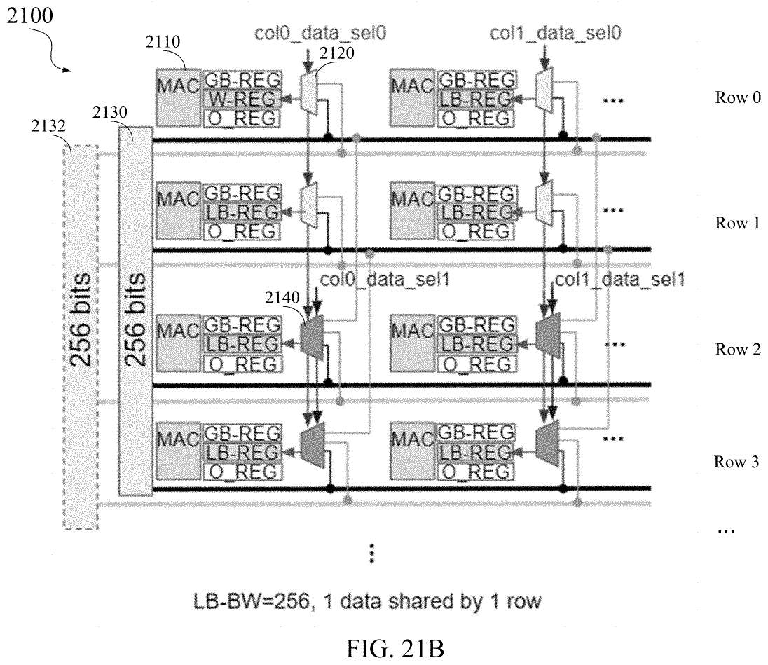

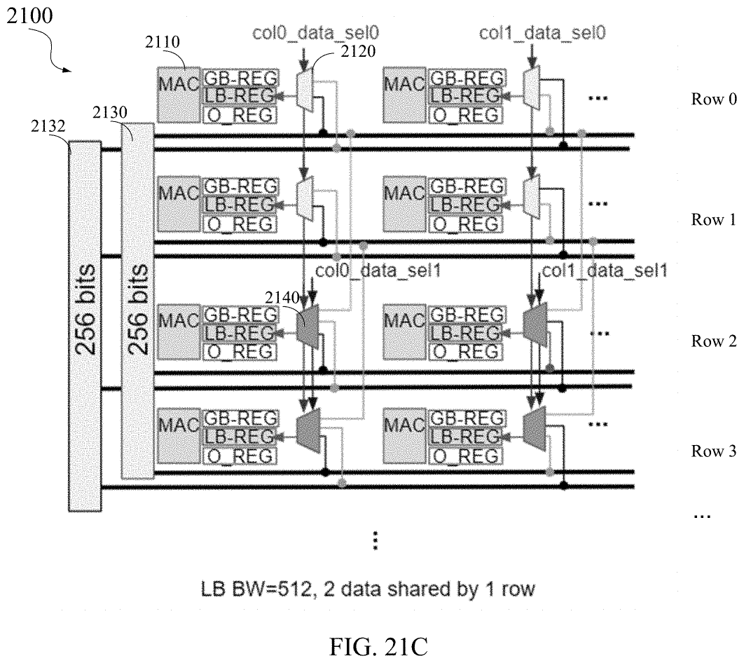

FIGS. 21A-21C illustrate an example of a configurable row data casting design with full flexibility for supporting local buffer bandwidths of 128, 256, and 512 bits/cycle, respectively, according to certain embodiments. In the illustrated example, a PE array 2100 may include 32 rows of PEs 2110, where each row may include 32 PEs in 32 respective columns. Each PE 2110 in PE array 2100 may include a MAC unit, a local buffer register (LB-REG) for storing data from the local buffer, a global buffer register (GB-REG) for storing data from the global buffer, and an output register (O-REG). The local buffer register of each PE 2110 may be connected to LB data buses 2130 and 2132 through a MUX for communication with the local buffer. LB data bus 2130 and LB data bus 2132 may each have a bandwidth of 256 bits/cycle (i.e., 32 bytes/cycle) that may be shared by 32 rows of PEs 2110.

Each MUX 2120 in the first two rows (rows 0 and 1) of a group of four rows of PE array 2100 may include a 2-to-1 multiplexer for receiving and storing a data element from a corresponding data line of LB data bus 2130 or a corresponding data line of LB data bus 2132 to the local buffer register. Each MUX 2140 in other two rows of the group of four rows of PE array 2100 may include a 3-to-1 multiplexer for receiving and storing a data element from one of two data lines of LB data bus 2130 or a data line of LB data bus 2132 to the local buffer register. For example, MUXes 2140 on a row 4N+2 (N>=0) may also be connected to a data line for row 4N in addition to the two data lines for row 4N+2, whereas MUXes 2140 on a row 4N+3 (N>=0) may also be connected to a data line for row 4N+1 in addition to the two data lines for row 4N+3. MUXes 2120 in the first two rows and an even number column may be controlled by a control signal “col0_data_se10,” whereas MUXes 2120 in the first two rows and an odd number column may be controlled by a control signal “col1_data_sel0.” MUXes 2140 in the other two rows of the group of four rows and even-number columns may be controlled by control signals “col0_data_sel0” and “col0_data_sel1,” whereas MUXes 2140 in the other two rows of the group of four rows and odd-number columns may be controlled by a control signal “col1_data_sel0” and “col1_data_sel1.” These four control signals may also be used to control MUXes for other PEs in PE array 2100. The example of configurable row data casting design shown in FIGS. 21A-21C can provide configurable LB data connections with full flexibility for row data spatial unrolling.

FIG. 21A illustrates an example of configuring row data casting to support a local buffer bandwidth of 128 bits/cycle. Since the local buffer bandwidth is 128 bits/cycle (16 bytes/cycle), data from the local buffer in each clock cycle may include 16 data elements (e.g., 16 bytes) on a half of the 32 data lines of local buffer data bus 2130. Therefore, each data element in a clock cycle may be shared by PEs on two rows. For example, the control signals may be set to control MUXes 2120 and 2140 as shown by the thicker lines in FIG. 21A, such that PEs on row 4N (e.g., row 0) and row 4N+2 (e.g., row 2) may share a data element on a data line of local buffer data bus 2130 for row 4N (e.g., row 0), whereas PEs on row 4N+1 (e.g., row 1) and row 4N+3 (e.g., row 3) may share a data element on a data line of local buffer data bus 2130 for row 4N+1 (e.g., row 1). PEs on a same row but in different columns may receive the same data from the local buffer through a same data line of local buffer data bus 2130.

FIG. 21B illustrates an example of configuring row data casting to support a local buffer bandwidth of 256 bits/cycle. Since the local buffer bandwidth is 256 bits/cycle (32 bytes/cycle), data from the local buffer in each clock cycle may include 32 data elements (e.g., 32 bytes) on 32 respective data lines of local buffer data bus 2130. Therefore, each data element in a clock cycle may be shared by PEs on one respective row. The control signals may be set to control MUXes 2120 and 2140 as shown by the thicker lines in FIG. 21B, such that PEs on each row may receive a same data element from a respective data line of local buffer data bus 2130 for the row.

FIG. 21C illustrates an example of configuring row data casting to support a local buffer bandwidth of 512 bits/cycle. Since the local buffer bandwidth is 512 bits/cycle (64 bytes/cycle), data from the local buffer in each clock cycle may include a total of 64 data elements (e.g., 64 bytes) from local buffer data bus 2130 and local buffer data bus 2132. Therefore, two data elements may be shared by PEs on a same row in each clock cycle, where one data element may be on a data line of local buffer data bus 2130 and the other data element may be on a data line of local buffer data bus 2132. The control signals may be set to control MUXes 2120 and 2140 as shown by the thicker lines in FIG. 21C. For example, PEs on a same row and in even-number columns may receive the same data from the local buffer through a data line of local buffer data bus 2130, and PEs on a same row and in odd-number columns may receive the same data from the local buffer through a data line of local buffer data bus 2132.

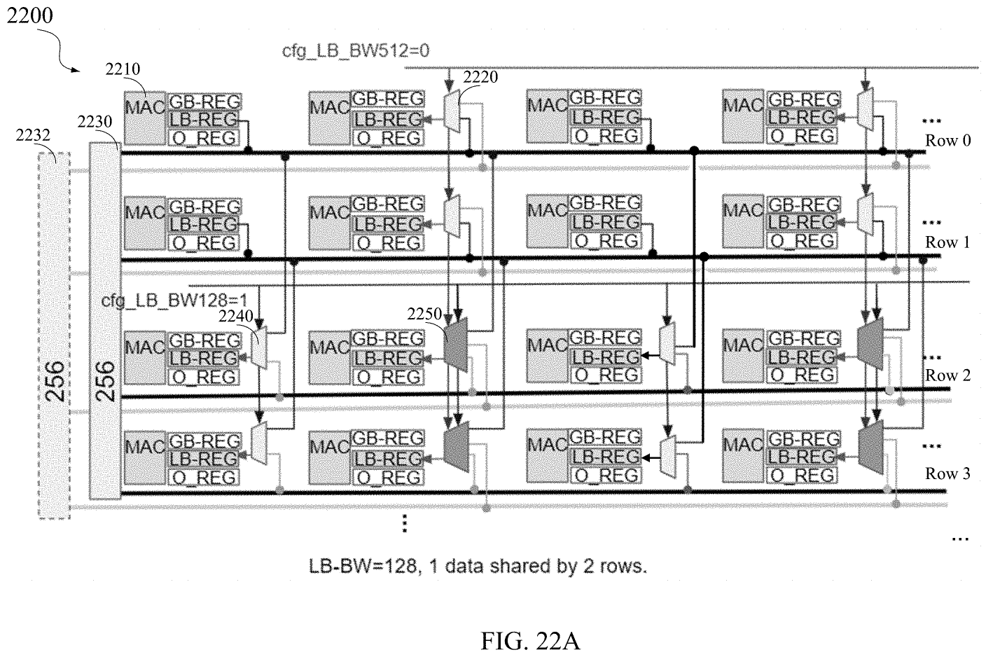

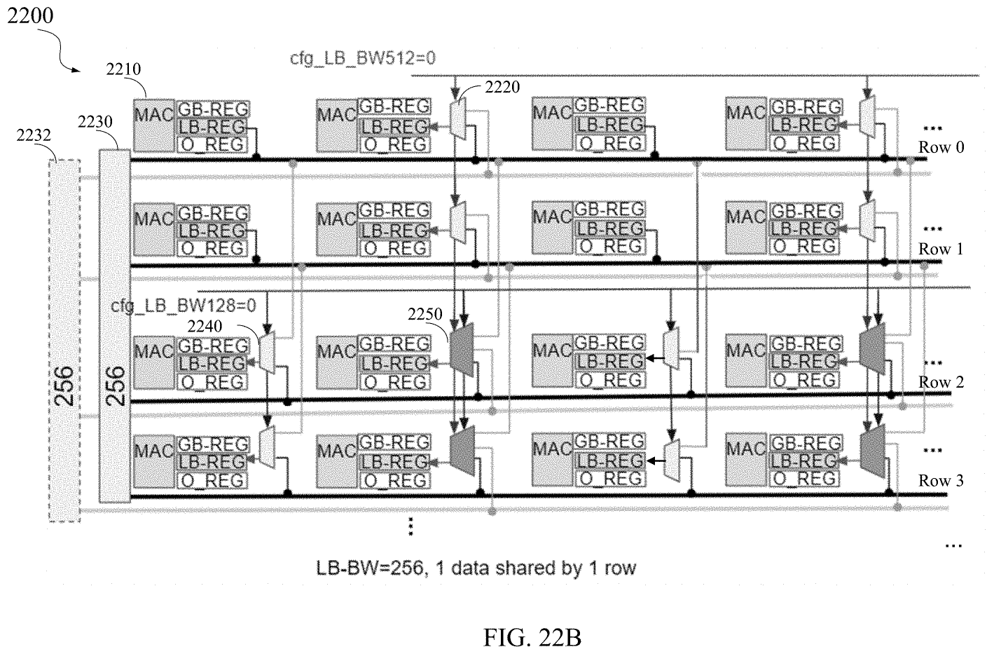

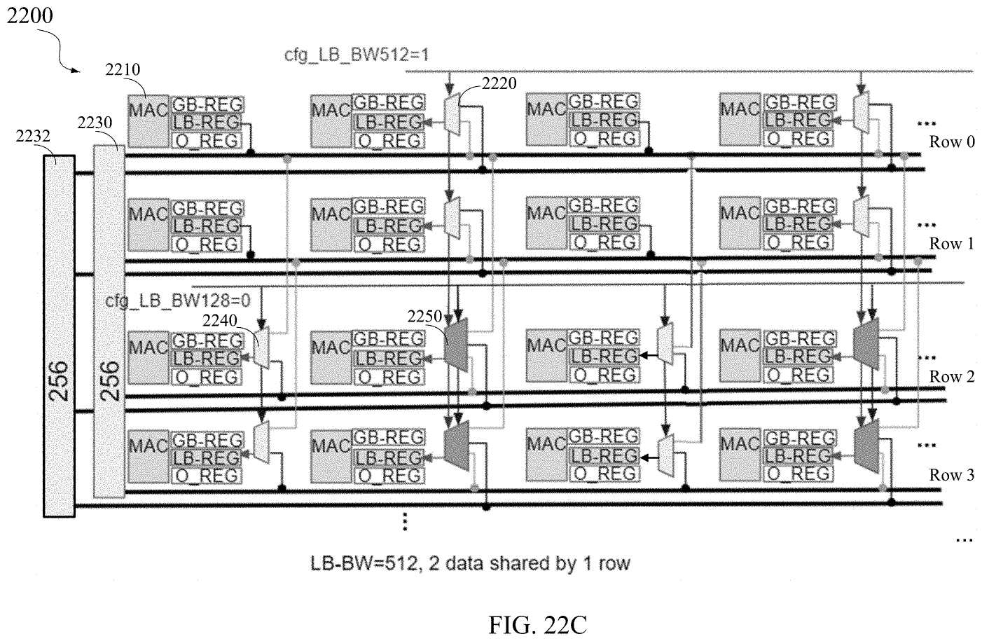

FIGS. 22A-22C illustrate an example of a light-weight configurable row data casting designs with low control overhead for supporting LB bandwidths of 128, 256, and 512 bits/cycle, respectively, according to certain embodiments. In the illustrated examples, a PE array 2200 may include 32 rows of PEs 2210, where each row may include 32 PEs in 32 respective columns. Each PE 2210 in PE array 2200 may include a MAC unit, a local buffer register (LB-REG) for storing data from the local buffer, a global buffer register (GB-REG) for storing data from the global buffer, and an output register (O-REG). The local buffer registers of some PEs 2210, such as PEs in rows 0 and 1 and in even-number columns, may be directly connected to data lines of LB data bus 2230 for communication with the local buffer. The local buffer registers of some PEs 2210 may be connected to LB data buses 2230 and 2232 through MUXes for communication with the local buffer. LB data bus 2230 and LB data bus 2232 may each have a bandwidth of 256 bits/cycle (i.e., 32 bytes/cycle) and may be shared by 32 rows of PEs 2210. The examples shown in FIGS. 22A-22C may not provide configurable LB data connection with full flexibility for the row data spatial unrolling, but may offer light-weight implementations with lower control and multiplexing overhead.

Only wo control signals “cfg_LB_BW512” and “cfg_LB_BW128” may be used to control the MUXes for row data casting. For example, the local buffer registers of PEs 2210 in rows 0 and 1 of each group of four rows and in odd-number columns may be connected to LB data buses 2230 and 2232 through 2-to-1 MUXes 2220 that are controlled by control signal “cfg_LB_BW512.” The local buffer registers of PEs 2210 on the other two rows of each group of four rows and in even-number columns may be connected to LB data bus 2230 through 2-to-1 MUXes 2240 that are controlled by control signal “cfg_LB_BW128.” The local buffer registers of PEs 2210 on the other two rows of each group of four rows and in odd-number columns may be connected to LB data buses 2230 and 2232 through 3-to-1 MUXes 2250 that are controlled by control signals “cfg_LB_BW512” and “cfg_LB_BW128.”

FIG. 22A illustrates an example of configuring row data casting with low overhead to support a local buffer bandwidth of 128 bits/cycle. Since the local buffer bandwidth is 128 bits/cycle (16 bytes/cycle), data from the local buffer in each clock cycle may include 16 data elements (e.g., 16 bytes) on a half of the 32 data lines of local buffer data bus 2230. Therefore, each data element in a clock cycle may be shared by PEs on two rows. For example, control signal “cfg_LB_BW512” may be set to “0” and control signal “cfg_LB_BW128” may be set to “1” to control the MUXes as shown by the thicker lines in FIG. 22A, such that PEs on row 4N (N>=0) (e.g., row 0) and row 4N+2 (e.g., row 2) may share a data element on a data line of local buffer data bus 2230 for row 4N (e.g., row 0), whereas PEs on row 4N+1 (e.g., row 1) and row 4N+3 (e.g., row 3) may share a data element on a data line of local buffer data bus 2230 for row 4N+1 (e.g., row 1). PEs on a same row but in different columns may receive the same data from the local buffer through a same data line of local buffer data bus 2230.

FIG. 22B illustrates an example of configuring row data casting with low overhead to support a local buffer bandwidth of 256 bits/cycle. Since the local buffer bandwidth is 256 bits/cycle (32 bytes/cycle), data from the local buffer in each clock cycle may include 32 data elements (e.g., 32 bytes) on 32 respective data lines of local buffer data bus 2230. Therefore, each data element in a clock cycle may be shared by PEs on one row. Control signal “cfg_LB_BW512” may be set to “0” and control signal “cfg_LB_BW128” may be set to “0” to control the MUXes as shown by the thicker lines in FIG. 22B, such that PEs on each row may share a data element on a data line of local buffer data bus 2230 for the row.

FIG. 22C illustrates an example of configuring row data casting with low overhead to support a local buffer bandwidth of 512 bits/cycle. Since the local buffer bandwidth is 512 bits/cycle (64 bytes/cycle), data from the local buffer in each clock cycle may include a total of 64 data elements (e.g., 64 bytes) from local buffer data bus 2230 and local buffer data bus 2232. Therefore, two data elements may be shared by PEs on a same row in each clock cycle, where one data element may be on a data line of local buffer data bus 2230 and the other data element may be on a data line of local buffer data bus 2232. Control signal “cfg_LB_BW512” may be set to “1” and control signal “cfg_LB_BW128” may be set to “0” to control the MUXes as shown by the thicker lines in FIG. 22C. For example, PEs on a same row and in even-number columns may receive the same data from the local buffer through a data line of local buffer data bus 2230, and PEs on a same row and in odd-number columns may receive the same data from the local buffer through a data line of local buffer data bus 2232.

Spatial unrolling for two AR NN layers of an example of an edge inference AR NN for hand tracking is described below to explain the operations of the NN accelerator disclosed herein. The temporal and spatial unrolling of the weights, input activations, and outputs onto the NN accelerator disclosed herein to achieve the best energy efficiency for each AR NN layer is described. In the results shown in below, “Baseline 1,” “Baseline 2,” and “Baseline 3” correspond to 2D NN accelerator 700 of FIG. 7, 3D NN accelerator 800 of FIGS. 8, and 3D NN accelerator 900 of FIG. 9, respectively.

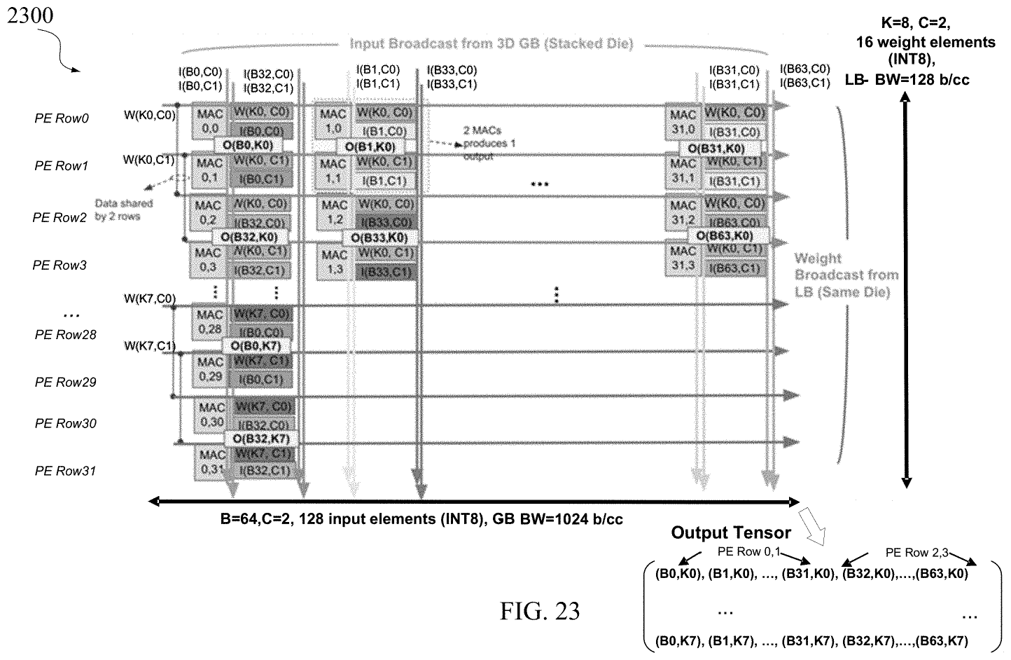

FIG. 23 illustrates an example of spatial unrolling according to a configuration of a 3D NN accelerator disclosed herein to implement a depth-wise convolution layer of an edge inference AR NN (e.g., depth-wise layer of FIG. 13). In the example of implementing the depth-vise convolution layer shown in FIG. 23, the 3D NN accelerator may be configured according to configuration 1642 of FIG. 16D, where the output channel number K is 8, the product of output channel dimensions and the batch size (B) is 64, the product of filter channel dimensions and the number of input (or filter) channel (C) is 2, the local buffer bandwidth is 128 bits/cycle, the global buffer bandwidth is 1024 bits/cycle, and the local buffer is configured to store weights. In FIG. 23, MAC_{x,y} represents the MAC unit of a PE in column x and row y of a PE array 2300 (e.g., a 32×32 PE array), I(Bi,Cj) represents an input element in the input tensor, W(Km,Cn) represents a weight element in the weight tensor, and O(Bk,K1) represents an output element in the output tensor.

PE array 2300 of the 3D NN accelerator may be configured to support spatial mapping for two input channels as shown in, for example, FIG. 17B, such that two MACs may produce one output element. For example, MAC_{0,0} and MAC_{0,1} may together produce O(B0,K0), MAC_{1,0} and MAC_{1,1} may together produce O(B1,K0), and so on. The column (global buffer) data casting in the illustrated example may be similar to the examples of column data casting shown in, for example, FIG. 19B and FIG. 20B. For example, the GB-REGs of the PEs in column 0 and rows 4N (e.g., rows 0, 4, . . . , and 28 for N=0, 1, . . . , and 7, respectively) may receive I(B0, C0), the GB-REGs of the PEs in column 0 and rows 4N+1 (e.g., rows 1, 5, . . . , and 29 for N=0, 1, . . . , and 7, respectively) may receive I(B0, C0, the GB-REGs of the PEs in column 0 and rows 4N+2 (e.g., rows 2, 6, . . . , and 30 for N=0, 1, . . . , and 7, respectively) may receive I(B32, C0), the GB-REGs of the PEs in column 0 and rows 4N+3 (e.g., rows 3, 7, . . . , and 31 for N=0, 1, . . . , and 7, respectively) may receive I(B32, C0, the GB-REGs of the PEs in column 1 and rows 4N may receive I(B1, C0), the GB-REGs of the PEs in column 1 and rows 4N+1 may receive I(B1, the GB-REGs of the PEs in column 1 and rows 4N+2 may receive I(B33, C0), the GB-REGs of the PEs in column 1 and rows 4N+3 may receive I(B33, C0, and so on. The row (local buffer) data casting may be similar to the examples of row data casting shown in, for example, FIG. 21A and FIG. 22A. For example, PEs in a row 4N (N>=0) and a row 4N+2 may share a same weight (e.g., W(K0, C0), W(K1, C0), . . . , and W(K7, C0) for N=0, 1, . . . , and 7, respectively), and PEs in a row 4N+1 (N>=0) and a row 4N+3 (N>=0) may share a same weight (e.g., W(K0, C1), W(K1, C1), . . . , and W(K7, C1) for N=0, 1, . . . , and 7, respectively).

Based on the mapping shown in FIG. 23, an output tensor of the tensor operation in the depth-wise layer may be:

$$( \begin{matrix}O ( B 0 , K 0 ) & O ( B 1 , K 0 ) & … & O ( B 31 , K 0 ) & O ( B 32 , K 0 ) & … & O ( B 63 , K 0 ) \\ & … & & … & & … & \\ O ( B 0 , K 7 ) & O ( B 1 , K 7 ) & & O ( B 31 , K 7 ) & O ( B 32 , K 7 ) & & O ( B 63 , K 7 )\end{matrix} ) .$$

Each row of the output tensor may be generated by PEs on a group of 4 rows of PEs, where the first 32 output elements of each row of the output tensor (e.g., O(B0,K0), O(B1,K0), . . . , and O(B31,K0)) may be generated by PEs in the first two rows of the group of 4 rows of PEs, and the next 32 output elements of each row of the output tensor (e.g., O(B32,K0), O(B33,K0), . . . , and O(B63,K0)) may be generated by PEs in the other two rows of the group of 4 rows of PEs.

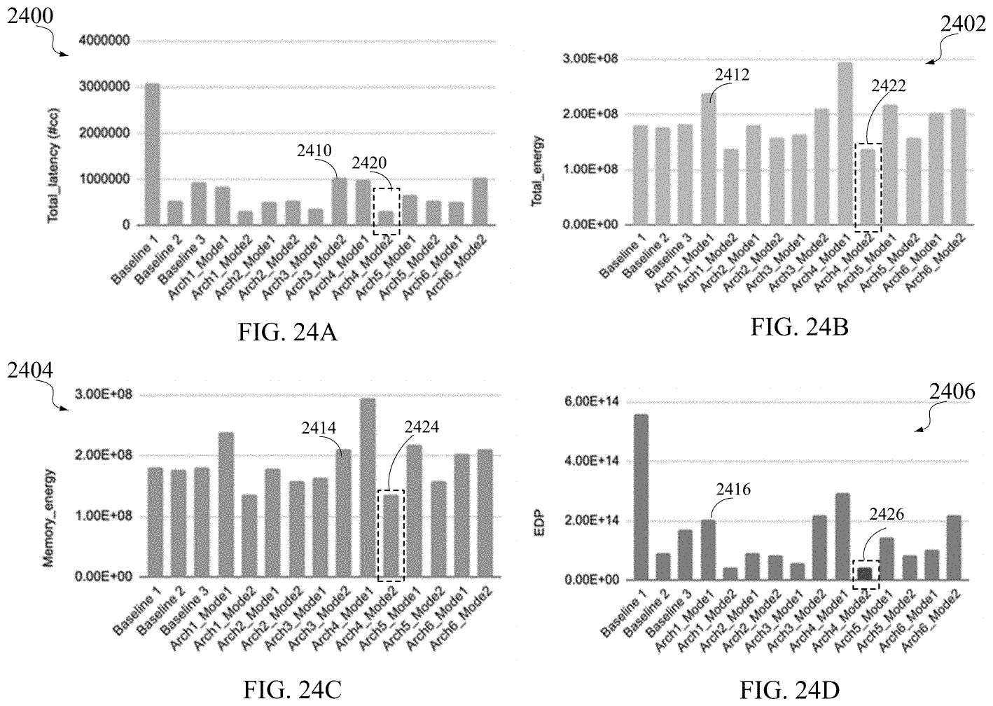

FIGS. 24A-24D illustrate latency and energy efficiency comparisons of the baseline architectures and various configurations of a 3D NN accelerator according to certain embodiments disclosed herein for implementing the depth-wise convolution layer of the edge inference AR NN shown in FIG. 13. The different configurations of the 3D NN accelerator according to certain embodiments disclosed herein (e.g., with respect to FIGS. 14-22C) include the 12 configurations shown in FIGS. 16A-16F.

FIG. 24A includes a chart 2400 showing the total latency (in number of clock cycles) for executing the depth-wise convolution layer of the AR NN by the baseline NN accelerators and the 3D configurable NN accelerators disclosed herein under different configurations. Each bar 2410 corresponds to the latency of one NN accelerator/accelerator configuration. FIG. 24A shows that the spatial unrolling according to configuration 1642 (“Arch4_Mode2”) of the 3D NN accelerator disclosed herein as shown in FIG. 23 may achieve the lowest latency (as indicated by a bar 2420) for implementing the depth-wise convolution layer of the AR NN.

FIG. 24B includes a chart 2402 showing the total energy consumption for executing the depth-wise convolution layer of the AR NN by the baseline NN accelerators and the 3D configurable NN accelerators disclosed herein under different configurations. Each bar 2412 corresponds to the energy consumption of one NN accelerator/accelerator configuration. FIG. 24B shows that the spatial unrolling according to configuration 1642 (“Arch4_Mode2”) of the 3D NN accelerator disclosed herein as shown in FIG. 23 may achieve the lowest energy consumption (as indicated by a bar 2422) for implementing the depth-wise convolution layer of the AR NN.

FIG. 24C includes a chart 2404 showing the memory energy consumption for executing the depth-wise convolution layer of the AR NN by the baseline NN accelerators and the 3D configurable NN accelerators disclosed herein under different configurations. Each bar 2414 corresponds to the memory energy consumption of one NN accelerator/accelerator configuration. FIG. 24C shows that the spatial unrolling according to configuration 1642 (“Arch4_Mode2”) of the 3D NN accelerator disclosed herein as shown in FIG. 23 may achieve the lowest memory energy consumption (as indicated by a bar 2424) for implementing the depth-wise convolution layer of the AR NN.

FIG. 24D includes a chart 2406 showing the energy delay product for executing the depth-wise convolution layer of the AR NN by the baseline NN accelerators and the 3D configurable NN accelerators disclosed herein under different configurations. Each bar 2416 corresponds to the energy delay product of one NN accelerator/accelerator configuration. FIG. 24D shows that the spatial unrolling according to configuration 1642 (“Arch4_Mode2”) of the 3D NN accelerator disclosed herein as shown in FIG. 23 may achieve the lowest energy delay product (as indicated by a bar 2426) for implementing the depth-wise convolution layer of the AR NN.

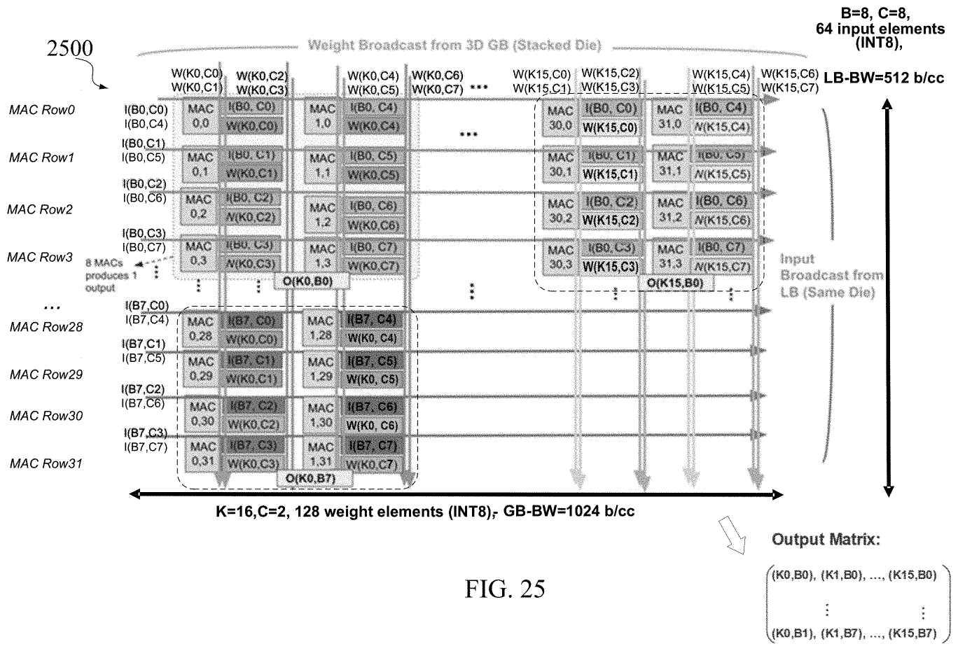

FIG. 25 illustrates an example of spatial unrolling according to a configuration of a 3D NN accelerator disclosed herein to implement a convolution layer of an AR NN (e.g., layer 16 of FIG. 13). In the illustrated example in FIG. 25, the 3D NN accelerator may be configured according to configuration 1660 (“Arch6_Mode1”) of FIG. 16F, where the output channel number K is 8, the product of output channel dimensions and the batch size (B) is 16, the product of filter channel dimensions and the number of input (or filter) channel (C) is 8, the local buffer bandwidth is 512 bits/cycle, the global buffer bandwidth is 1024 bits/cycle, and the local buffer is configured to store input data. In FIG. 25, MAC_{x,y} represents the MAC unit of a PE in column x and row y of a PE array 2500 (e.g., a 32×32 PE array), I(Bi,Cj) represents an input element in the input tensor, W(Km,Cn) represents a weight element in the weight tensor, and O(Bk,K1) represents an output element in the output tensor.

PE array 2500 of the 3D NN accelerator may be configured to support spatial mapping for eight input channels as shown in, for example, FIG. 18, such that 8 MACs of 8 PEs may produce one output element in two steps. For example, MAC_{0,0}, MAC_{0,1}, MAC_{0,2}, MAC_{0,3}, MAC_{1,0}, MAC_{1,1}, MAC_{1,2}, and MAC_{1,3} may together produce O(K0,B0) in two steps as show in FIG. 18. The column (global buffer) data casting may be similar to the examples of column data casting shown in, for example, FIG. 19B and FIG. 20B. For example, the GB-REGs of the PEs in column 0 and rows 4N (e.g., rows 0, 4, . . . , and 28 for N=0, 1, . . . , and 7, respectively) may receive W(K0, C0), the GB-REGs of the PEs in column 0 and rows 4N+1 (e.g., rows 1, 5, . . . , and 29 for N=0, 1, . . . , and 7, respectively) may receive W(K0, C1), the GB-REGs of the PEs in column 0 and rows 4N+2 (e.g., rows 2, 6, . . . , and 30 for N=0, 1, . . . , and 7, respectively) may receive W(K0, C2), the GB-REGs of the PEs in column 0 and rows 4N+3 (e.g., rows 3, 7, . . . , and 31 for N=0, 1, . . . , and 7, respectively) may receive W(K0, C3), the GB-REGs of the PEs in column 1 and rows 4N may receive W(K0, C4), the GB-REGs of the PEs in column 1 and rows 4N+1 may receive W(K0, C5), the GB-REGs of the PEs in column 1 and rows 4N+2 may receive W(K0, C6), the GB-REGs of the PEs in column 1 and rows 4N+3 may receive W(K0, C7), . . . , the GB-REGs of the PEs in column 30 and rows 4N may receive W(K15, C0), the GB-REGs of the PEs in column 30 and rows 4N+1 may receive W(K15, C1), the GB-REGs of the PEs in column 30 and rows 4N+2 may receive W(K15, C2), the GB-REGs of the PEs in column 30 and rows 4N+3 may receive W(K15, C3), the GB-REGs of the PEs in column 31 and rows 4N may receive W(K15, C4), the GB-REGs of the PEs in column 31 and rows 4N+1 may receive W(K15, C5), the GB-REGs of the PEs in column 31 and rows 4N+2 may receive W(K15, C6), and the GB-REGs of the PEs in column 31 and rows 4N+3 may receive W(K15, C7).

The row (local buffer) data casting may be similar to the example of row data casting shown in, for example, FIG. 21C and FIG. 22C, where PEs in a same row may receive two data elements in each clock cycle from the local buffer data buses. For example, PEs in a row 4N (N>=0) and even-number columns may share the same input data (e.g., I(B0, C0), I(B1, C0), . . . , and I(B7, C0) for N=0, 1, . . . , and 7, respectively), PEs in a row 4N+1 (N>=0) and even-number columns may share the same input data (e.g., I(B0, C1), I(B1, C1), . . . , and I(B7, C1) for N=0, 1, . . . , and 7, respectively), PEs in a row 4N+2 (N>=0) and even-number columns may share the same input data (e.g., I(B0, C2), I(B1, C2), . . . , and I(B7, C2) for N=0, 1, . . . , and 7, respectively), PEs in a row 4N+3 (N>=0) and even-number columns may share the same input data (e.g., I(B0, C3), I(B1, C3), . . . , and I(B7, C3) for N=0, 1, . . . , and 7, respectively), PEs in a row 4N and odd-number columns may share the same input data (e.g., I(B0, C4), I(B1, C4), . . . , and I(B7, C4), for N=0, 1, . . . , and 7, respectively), PEs in a row 4N+1 (N>=0) and odd-number columns may share the same input data (e.g., I(B0, C5), I(B1, C5), . . . , and I(B7, C5) for N=0, 1, . . . , and 7, respectively), PEs in a row 4N+2 (N>=0) and odd-number columns may share the same input data (e.g., I(B0, C6), I(B1, C6), . . . , and I(B7, C6) for N=0, 1, . . . , and 7, respectively), and PEs in a row 4N+3 (N>=0) and odd-number columns may share the same input data (e.g., I(B0, C7), I(B1, C7), . . . , and I(B7, C7) for N=0, 1, . . . , and 7, respectively).

Based on the mapping shown in FIG. 25, the output tensor (e.g., an output matrix) of the tensor operation on convolution layer 16 may be:

$$( \begin{matrix}O ( K 0 , B 0 ) & O ( K 1 , B 0 ) & … & O ( K 15 , B 0 ) \\ & … & & … \\ O ( K 0 , B 7 ) & O ( K 1 , B 7 ) & & O ( K 15 , B 7 )\end{matrix} ) .$$

Each row of the output matrix may be generated by a group of 4 rows of PEs.

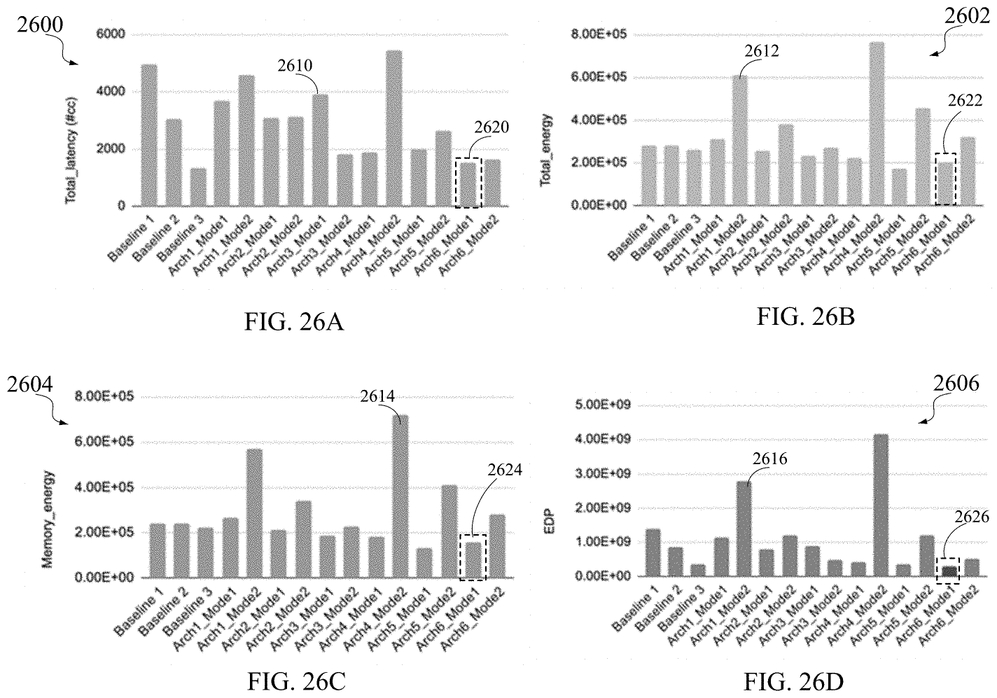

FIGS. 26A-26D illustrate latency and energy efficiency comparisons of the baseline architectures and various configurations of a 3D NN accelerator according to certain embodiments disclosed herein for implementing convolution layer 16 of the AR NN as shown in FIG. 13. The different configurations of the 3D NN accelerator according to certain embodiments disclosed herein (e.g., in FIGS. 14-22C) include the 12 configurations shown in FIGS. 16A-16F.

FIG. 26A includes a chart 2600 showing the total latency (in number of clock cycles) for executing convolution layer 16 of the AR NN by baseline NN accelerators and the 3D configurable NN accelerators disclosed herein under different configurations. Each bar 2610 corresponds to the latency of one NN accelerator/accelerator configuration. FIG. 26A shows that the spatial unrolling according to configuration 1660 (“Arch6_Mode1”) of the 3D NN accelerator disclosed herein as shown in FIG. 25 may achieve a low latency (as indicated by a bar 2620) for implementing convolution layer 16 of the AR NN.

FIG. 26B includes a chart 2602 showing the total energy consumption for executing convolution layer 16 of the AR NN by baseline NN accelerators and the 3D configurable NN accelerators disclosed herein under different configurations. Each bar 2612 corresponds to the energy consumption of one NN accelerator/accelerator configuration. FIG. 26B shows that the spatial unrolling according to configuration 1660 (“Arch6_Mode1”) of the 3D NN accelerator disclosed herein as shown in FIG. 25 may achieve a low energy consumption (as indicated by a bar 2622) for implementing convolution layer 16 of the AR NN.

FIG. 26C includes a chart 2604 showing the memory energy consumption for executing convolution layer 16 of the AR NN by baseline NN accelerators and the 3D configurable NN accelerators disclosed herein under different configurations. Each bar 2614 corresponds to the memory energy consumption of one NN accelerator/accelerator configuration. FIG. 26C shows that the spatial unrolling according to configuration 1660 (“Arch6_Mode1”) of the 3D NN accelerator disclosed herein as shown in FIG. 25 may achieve a low memory energy consumption (as indicated by a bar 2624) for implementing convolution layer 16 of the AR NN.

FIG. 26D includes a chart 2606 showing the energy delay product for executing convolution layer 16 of the AR NN by baseline NN accelerators and the 3D configurable NN accelerators disclosed herein under different configurations. Each bar 2616 corresponds to the energy delay product of one NN accelerator/accelerator configuration. FIG. 26D shows that the spatial unrolling according to configuration 1660 (“Arch6_Mode1”) of the 3D NN accelerator disclosed herein as shown in FIG. 25 may achieve the lowest energy delay product (as indicated by a bar 2626) for implementing convolution layer 16 of the AR NN.

FIGS. 23-26D show that, to achieve the best energy efficiency for performing an entire inference using a deep NN model, the NN accelerator needs to provide flexible spatial mapping and dynamically allocated bandwidth based on the specific property of each AR NN layer, which may not be achieved by the conventional fixed 2D or 3D architectures.

To evaluate the energy efficiency improvement, the 3D NN accelerator architecture disclosed herein was benchmarked with the 3 baseline designs that use existing 2D architecture (as shown in FIG. 7) and existing 3D-die stacking (as shown in FIGS. 8-9). In the experiments, the local buffer size is 64 KB, the LB-REG size is 1 B, the GB-REG size is 8 B, the O-REG size is 24 B, and the global buffer size is 1 MB. All representative AR NN layers shown in FIG. 13 were evaluated.

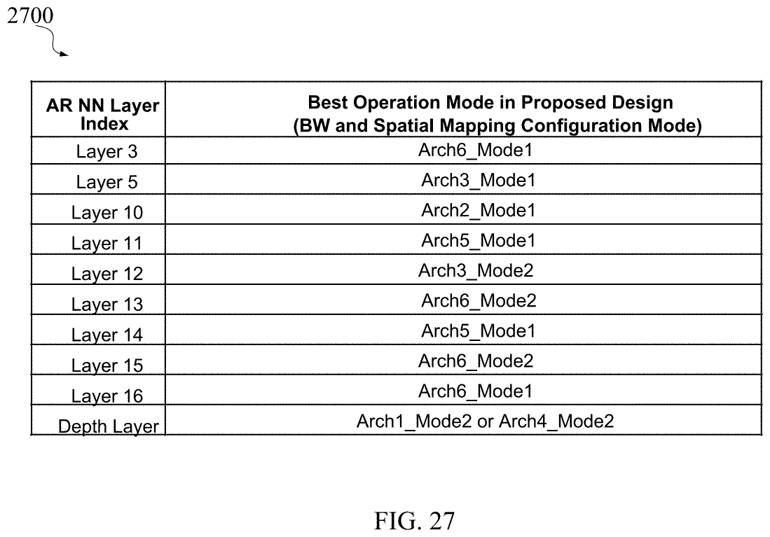

FIG. 27 is a table 2700 including experiment results showing the most energy-efficient (e.g., with the lowest energy delay product) operation modes of a bandwidth-aware, flexible-scheduling 3D NN accelerator according to certain embodiments for implementing different NN layers of the AR NN. FIG. 27 shows that, due to the diversity of the AR NN layers, the preferred global buffer data transfer bandwidth and local buffer data transfer bandwidth, and the spatial mapping can be very different for different AR NN layers, as indicated by the different most energy-efficient operation modes for different AR NN layers. Existing 2D or 3D NN accelerator architectures would not be able to implement the different configurations dynamically for different AR NN layers.

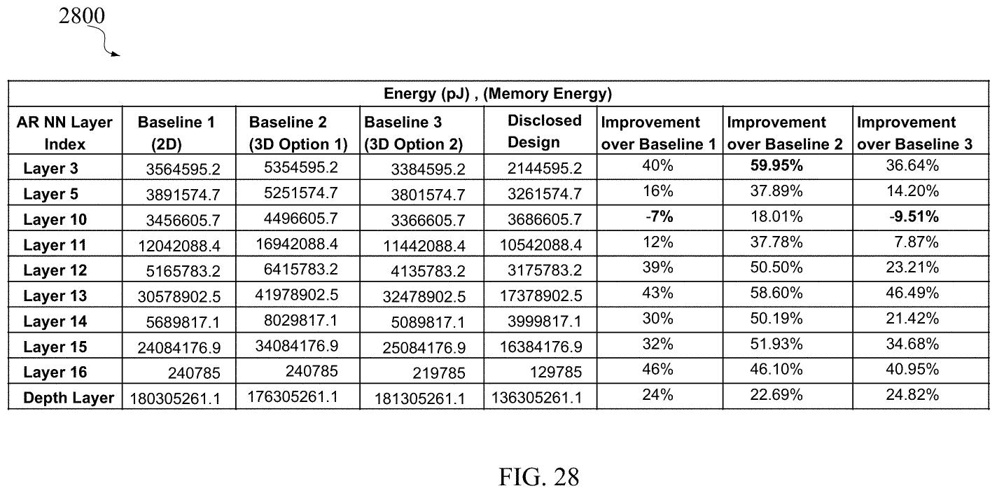

FIG. 28 is a table 2800 including experiment results showing memory energy reduction by the bandwidth-aware, flexible-scheduling 3D NN accelerator disclosed herein according to certain embodiments over baseline NN accelerator architectures for implementing different NN layers of the AR NN. FIG. 28 shows that the configurable 3D NN accelerator design disclosed herein can achieve up to about 60% of memory energy consumption reduction and can achieve significant energy saving for most of the NN layers.

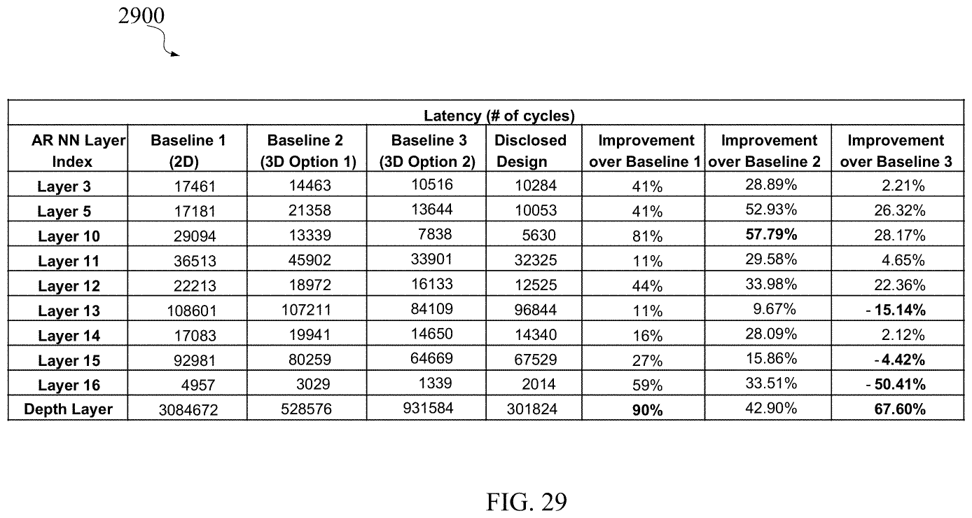

FIG. 29 is a table 2900 including experiment results showing data communication latency reduction by a bandwidth-aware, flexible-scheduling 3D NN accelerator disclosed herein according to certain embodiments over baseline NN accelerator architectures for implementing different NN layers of the AR NN. FIG. 29 shows that the configurable 3D NN accelerator design disclosed herein can achieve up to 90% of latency reduction.

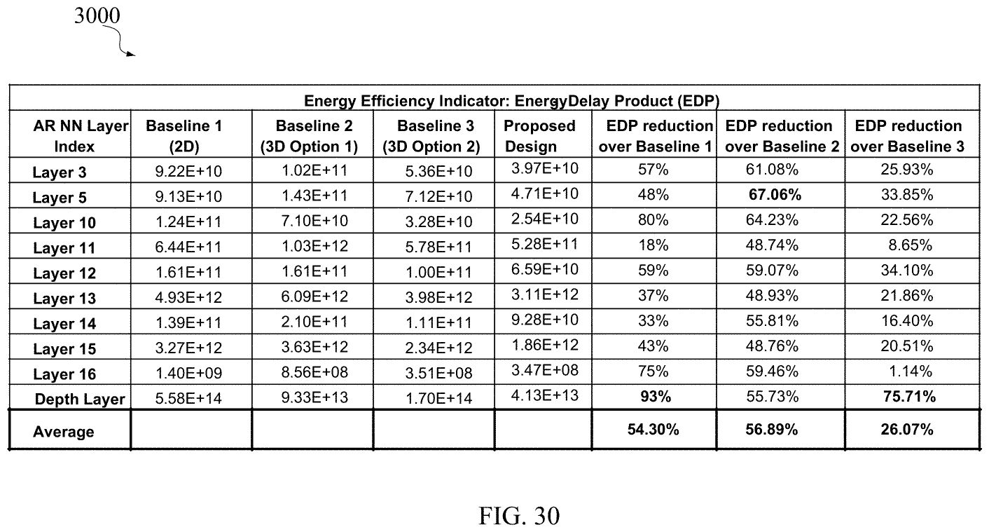

FIG. 30 is a table 3000 including experiment results showing energy delay product improvement of a bandwidth-aware, flexible-scheduling 3D NN accelerator according to certain embodiments over baseline NN accelerator architectures for implementing different NN layers of the AR NN. FIG. 30 shows that, compared with the 2D baseline design “Baseline 1” (as shown in FIG. 7), an average of about 54% and up to about 93% in EDP reduction can be achieved, which indicates an average of about 2.19 times and up to about 13.05 times energy efficiency improvement. Compared with the 3D baseline designs “Baseline 2” and “Baseline 3” (as shown in FIGS. 8 and 9), an average reduction of the energy delay product of about 57% (up to about 67%) and about 26% (up to about 76%), respectively, can be achieved, indicating an average energy efficiency improvement of about 2.32 times (up to about 3.04 times) and about 1.35 times (up to about 4.12 times), respectively.

It is noted that, in some circumstances, the best energy efficiency mode may yield higher energy (e.g., Layer 10, as shown in FIG. 28) or higher latency (e.g. Layer 13, Layer 15, and Layer 16, as shown in FIG. 29), but the overall energy delay product may be reduced. Due to the flexibility and reconfigurability of the 3D NN accelerator disclosed herein, these layers may be implemented by the 3D NN accelerator in other modes or configurations to achieve lower latency or lower energy consumption, based on the preference of the specific application.

Therefore, as described above, the 3D NN accelerator disclosed herein includes a configurable PE array, a configurable local buffer, and configurable data buses, and thus can be dynamically configured to better utilize the high bandwidth (e.g., >512 bits per cycle) offered by 3D interconnects and the reconfigurability for energy efficient, low latency NN operations (e.g., convolutions) on individual NN layers of a deep NN (e.g., an edge inference NN for object tracking in AR/VR applications). The 3D NN accelerator can, based on properties (e.g., dimensions of the tensors) of the NN layers, dynamically configure hardware resources, such as local memory, processing element (PE) array, and data bus bandwidth, to more efficiently implement the NN layers. For example, based on the tensor operation performed by a NN layer, the NN accelerator disclosed herein can utilize the high bandwidth offered by 3D interconnects for transferring large and/or less frequently reused data (either weights or input activations) to reduce energy and latency, can configure a local buffer that may have limited size and bandwidth to store small and/or more frequently reused data (either weights or input activations), and can dynamically configure the connections between PEs in the PE array and other PEs, connections between PEs and the local buffer data bus, and connections between PEs and the global buffer data bus, to support flexible spatial unrolling of tensor operations that may use tensors of different dimensions. Due to globally shared control signals, the overhead for support different bandwidth allocation and spatial mapping modes for different NN layers is negligible compared with the overall cost of PE array and memory.

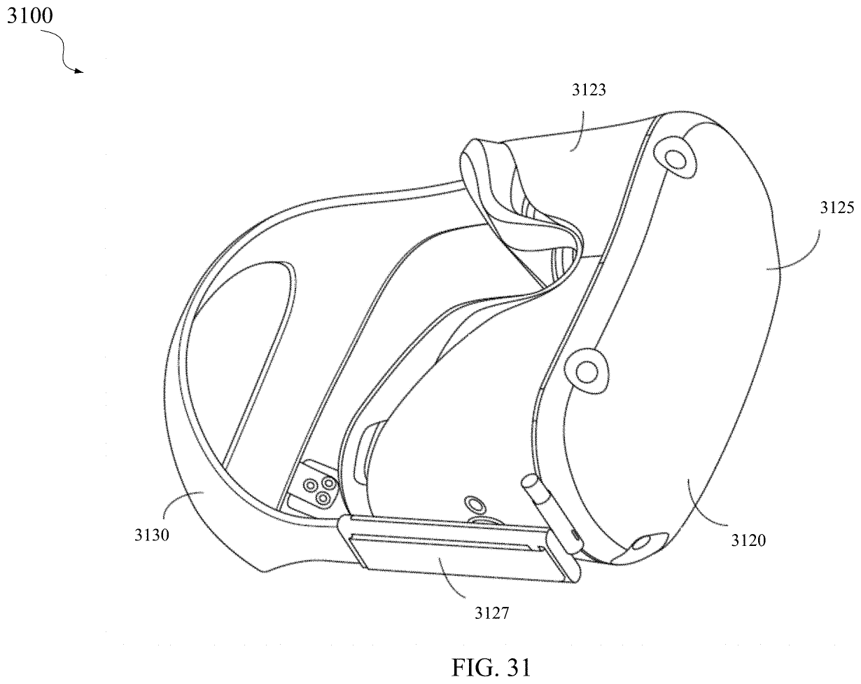

FIG. 31 is a perspective view of an example of a near-eye display in the form of an HMD device 3100 for implementing some of the examples disclosed herein. HMD device 3100 may be a part of, e.g., a VR system, an AR system, a mixed reality (MR) system, or any combination thereof. HMD device 3100 may include a body 3120 and a head strap 3130. FIG. 31 shows a bottom side 3123, a front side 3125, and a left side 3127 of body 3120 in the perspective view. Head strap 3130 may have an adjustable or extendible length. There may be a sufficient space between body 3120 and head strap 3130 of HMD device 3100 for allowing a user to mount HMD device 3100 onto the user's head. In various embodiments, HMD device 3100 may include additional, fewer, or different components. For example, in some embodiments, HMD device 3100 may include eyeglass temples and temple tips as shown in, for example, FIG. 16 below, rather than head strap 3130.

HMD device 3100 may present to a user media including virtual and/or augmented views of a physical, real-world environment with computer-generated elements. Examples of the media presented by HMD device 3100 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 31) enclosed in body 3120 of HMD device 3100. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 3100 may include two eye box regions.

In some implementations, HMD device 3100 may include various sensors (not shown), such as depth sensors, motion sensors, position sensors, and eye tracking sensors. Some of these sensors may use a structured light pattern for sensing. In some implementations, HMD device 3100 may include an input/output interface for communicating with a console. In some implementations, HMD device 3100 may include a virtual reality engine (not shown) that can execute applications within HMD device 3100 and receive depth information, position information, acceleration information, velocity information, predicted future positions, or any combination thereof of HMD device 3100 from the various sensors. In some implementations, the information received by the virtual reality engine may be used for producing a signal (e.g., display instructions) to the one or more display assemblies. In some implementations, HMD device 3100 may include locators (not shown, such as locators 126) located in fixed positions on body 3120 relative to one another and relative to a reference point. Each of the locators may emit light that is detectable by an external imaging device.

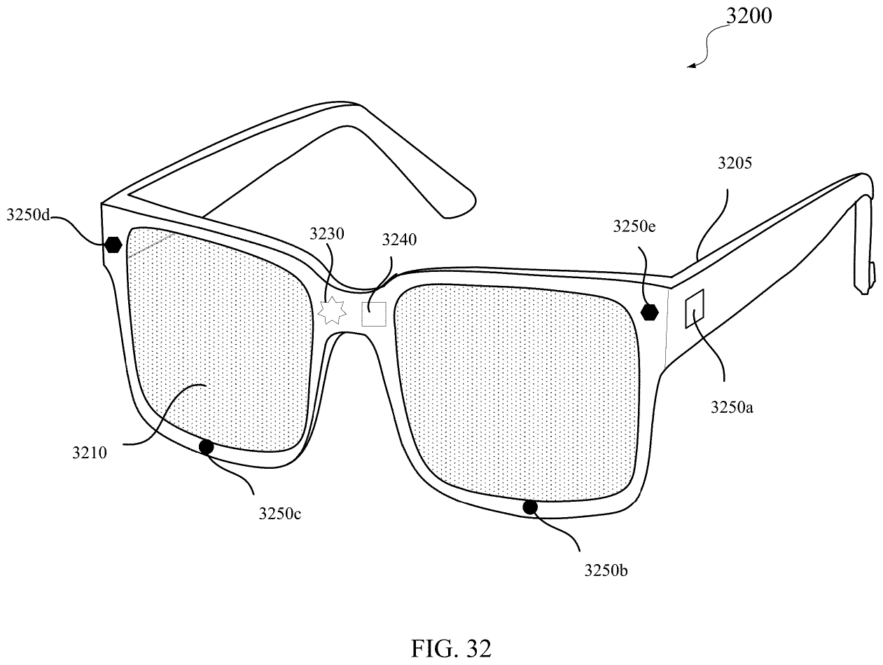

FIG. 32 is a perspective view of an example of a near-eye display 3200 in the form of a pair of glasses for implementing some of the examples disclosed herein. Near-eye display 3200 may be a specific implementation of near-eye display 120 of FIG. 1, and may be configured to operate as a virtual reality display, an augmented reality display, and/or a mixed reality display. Near-eye display 3200 may include a frame 3205 and a display 3210. Display 3210 may be configured to present content to a user. In some embodiments, display 3210 may include display electronics and/or display optics. For example, as described above with respect to near-eye display 120 of FIG. 1, display 3210 may include an LCD display panel, an LED display panel, or an optical display panel (e.g., a waveguide display assembly).

Near-eye display 3200 may further include various sensors 3250a, 3250b, 3250c, 3250d, and 3250e on or within frame 3205. In some embodiments, sensors 3250a-3250e may include one or more depth sensors, motion sensors, position sensors, inertial sensors, or ambient light sensors. In some embodiments, sensors 3250a-3250e may include one or more image sensors configured to generate image data representing different fields of views in different directions. In some embodiments, sensors 3250a-3250e may be used as input devices to control or influence the displayed content of near-eye display 3200, and/or to provide an interactive VR/AR/MR experience to a user of near-eye display 3200. In some embodiments, sensors 3250a-3250e may also be used for stereoscopic imaging.

In some embodiments, near-eye display 3200 may further include one or more illuminators 3230 to project light into the physical environment. The projected light may be associated with different frequency bands (e.g., visible light, infra-red light, ultra-violet light, etc.), and may serve various purposes. For example, illuminator(s) 3230 may project light in a dark environment (or in an environment with low intensity of infra-red light, ultra-violet light, etc.) to assist sensors 3250a-3250e in capturing images of different objects within the dark environment. In some embodiments, illuminator(s) 3230 may be used to project certain light patterns onto the objects within the environment. In some embodiments, illuminator(s) 3230 may be used as locators, such as locators 126 described above with respect to FIG. 1.

In some embodiments, near-eye display 3200 may also include a high-resolution camera 3240. Camera 3240 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 3210 for AR or MR applications.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

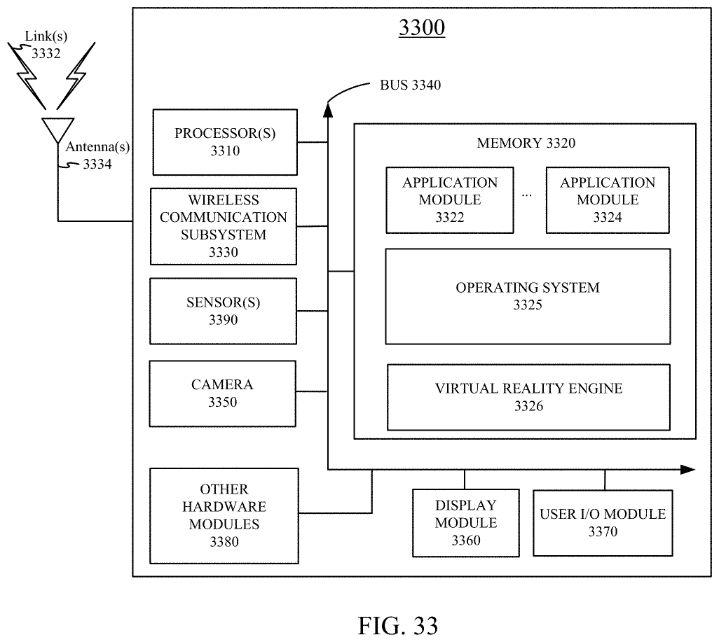

FIG. 33 is a simplified block diagram of an electronic system 3300 of an example of a near-eye display (e.g., HMD device) for implementing some of the examples disclosed herein. Electronic system 3300 may be used as the electronic system of an HMD device or other near-eye displays described above. In this example, electronic system 3300 may include one or more processor(s) 3310 and a memory 3320. Processor(s) 3310 may be configured to execute instructions for performing operations at a number of components, and can be, for example, a general-purpose processor or microprocessor suitable for implementation within a portable electronic device. Processor(s) 3310 may be communicatively coupled with a plurality of components within electronic system 3300. To realize this communicative coupling, processor(s) 3310 may communicate with the other illustrated components across a bus 3340. Bus 3340 may be any subsystem adapted to transfer data within electronic system 3300. Bus 3340 may include a plurality of computer buses and additional circuitry to transfer data.

Memory 3320 may be coupled to processor(s) 3310. In some embodiments, memory 3320 may offer both short-term and long-term storage and may be divided into several units. Memory 3320 may be volatile, such as static random access memory (SRAM) and/or dynamic random access memory (DRAM) and/or non-volatile, such as read-only memory (ROM), flash memory, and the like. Furthermore, memory 3320 may include removable storage devices, such as secure digital (SD) cards. Memory 3320 may provide storage of computer-readable instructions, data structures, program modules, and other data for electronic system 3300. In some embodiments, memory 3320 may be distributed into different hardware modules. A set of instructions and/or code might be stored on memory 3320. The instructions might take the form of executable code that may be executable by electronic system 3300, and/or might take the form of source and/or installable code, which, upon compilation and/or installation on electronic system 3300 (e.g., using any of a variety of generally available compilers, installation programs, compression/decompression utilities, etc.), may take the form of executable code.

In some embodiments, memory 3320 may store a plurality of application modules 3322 through 3324, which may include any number of applications. Examples of applications may include gaming applications, conferencing applications, video playback applications, or other suitable applications. The applications may include a depth sensing function or eye tracking function. Application modules 3322-3324 may include particular instructions to be executed by processor(s) 3310. In some embodiments, certain applications or parts of application modules 3322-3324 may be executable by other hardware modules 3380. In certain embodiments, memory 3320 may additionally include secure memory, which may include additional security controls to prevent copying or other unauthorized access to secure information.

In some embodiments, memory 3320 may include an operating system 3325 loaded therein. Operating system 3325 may be operable to initiate the execution of the instructions provided by application modules 3322-3324 and/or manage other hardware modules 3380 as well as interfaces with a wireless communication subsystem 3330 which may include one or more wireless transceivers. Operating system 3325 may be adapted to perform other operations across the components of electronic system 3300 including threading, resource management, data storage control and other similar functionality.

Wireless communication subsystem 3330 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 3300 may include one or more antennas 3334 for wireless communication as part of wireless communication subsystem 3330 or as a separate component coupled to any portion of the system. Depending on desired functionality, wireless communication subsystem 3330 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11× network. A WPAN may be, for example, a Bluetooth network, an IEEE 802.15×, or some other types of network. The techniques described herein may also be used for any combination of WWAN, WLAN, and/or WPAN. Wireless communications subsystem 3330 may permit data to be exchanged with a network, other computer systems, and/or any other devices described herein. Wireless communication subsystem 3330 may include a means for transmitting or receiving data, such as identifiers of HMD devices, position data, a geographic map, a heat map, photos, or videos, using antenna(s) 3334 and wireless link(s) 3332. Wireless communication subsystem 3330, processor(s) 3310, and memory 3320 may together comprise at least a part of one or more of a means for performing some functions disclosed herein.

Embodiments of electronic system 3300 may also include one or more sensors 3390. Sensor(s) 3390 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 3390 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or any combination thereof. The position sensors may be located external to the IMU, internal to the IMU, or any combination thereof. At least some sensors may use a structured light pattern for sensing.

Electronic system 3300 may include a display module 3360. Display module 3360 may be a near-eye display, and may graphically present information, such as images, videos, and various instructions, from electronic system 3300 to a user. Such information may be derived from one or more application modules 3322-3324, virtual reality engine 3326, one or more other hardware modules 3380, a combination thereof, or any other suitable means for resolving graphical content for the user (e.g., by operating system 3325). Display module 3360 may use LCD technology, LED technology (including, for example, OLED, ILED, μ-LED, AMOLED, TOLED, etc.), light emitting polymer display (LPD) technology, or some other display technology.

Electronic system 3300 may include a user input/output module 3370. User input/output module 3370 may allow a user to send action requests to electronic system 3300. An action request may be a request to perform a particular action. For example, an action request may be to start or end an application or to perform a particular action within the application. User input/output module 3370 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 3300. In some embodiments, user input/output module 3370 may provide haptic feedback to the user in accordance with instructions received from electronic system 3300. For example, the haptic feedback may be provided when an action request is received or has been performed.

Electronic system 3300 may include a camera 3350 that may be used to take photos or videos of a user, for example, for tracking the user's eye position. Camera 3350 may also be used to take photos or videos of the environment, for example, for VR, AR, or MR applications. Camera 3350 may include, for example, a complementary metal-oxide-semiconductor (CMOS) image sensor with a few millions or tens of millions of pixels. In some implementations, camera 3350 may include two or more cameras that may be used to capture 3D images.

In some embodiments, electronic system 3300 may include a plurality of other hardware modules 3380. Each of other hardware modules 3380 may be a physical module within electronic system 3300. While each of other hardware modules 3380 may be permanently configured as a structure, some of other hardware modules 3380 may be temporarily configured to perform specific functions or temporarily activated. Examples of other hardware modules 3380 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 3380 may be implemented in software.

In some embodiments, memory 3320 of electronic system 3300 may also store a virtual reality engine 3326. Virtual reality engine 3326 may execute applications within electronic system 3300 and receive position information, acceleration information, velocity information, predicted future positions, or any combination thereof of the HMD device from the various sensors. In some embodiments, the information received by virtual reality engine 3326 may be used for producing a signal (e.g., display instructions) to display module 3360. For example, if the received information indicates that the user has looked to the left, virtual reality engine 3326 may generate content for the HMD device that mirrors the user's movement in a virtual environment. Additionally, virtual reality engine 3326 may perform an action within an application in response to an action request received from user input/output module 3370 and provide feedback to the user. The provided feedback may be visual, audible, or haptic feedback. In some implementations, processor(s) 3310 may include one or more graphic processing units (GPUs) that may execute virtual reality engine 3326.

In various implementations, the above-described hardware and modules may be implemented on a single device or on multiple devices that can communicate with one another using wired or wireless connections. For example, in some implementations, some components or modules, such as GPUs, virtual reality engine 3326, and applications (e.g., tracking application), may be implemented on a console separate from the head-mounted display device. In some implementations, one console may be connected to or support more than one HMD.

In alternative configurations, different and/or additional components may be included in electronic system 3300. Similarly, functionality of one or more of the components can be distributed among the components in a manner different from the manner described above. For example, in some embodiments, electronic system 3300 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or any combination of A, B, and/or C, such as AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A neural network accelerator comprising:
a first memory device;
a controller connected to the first memory device through a high-bandwidth interconnect;
a configurable processing element (PE) array connected to the first memory device through a first data bus and including a two-dimensional (2D) array of PEs; and
a local memory connected to the controller and connected, through a second data bus, to the configurable PE array,
wherein the controller is configured to, during execution of a neural network (NN), dynamically configure the neural network accelerator for executing each NN layer of a plurality of NN layers of the neural network by:
selecting either weights of a weight tensor or input data of an input tensor of a tensor operation of the NN layer to store into the local memory; and
configuring input and output connections of PEs in the 2D array of PEs for performing the tensor operation.

2. The neural network accelerator of claim 1, wherein:
the controller includes a set of configuration registers configured to store respective configuration parameters for each NN layer of the plurality of NN layers; and
the controller is configured to dynamically configure the neural network accelerator for executing each NN layer of the plurality of NN layers based on the respective configuration parameters.

3. The neural network accelerator of claim 1, wherein:
the controller is further configured to dynamically control a first bandwidth of the first data bus, a second bandwidth of the second data bus, or both, for performing the tensor operation; and
the controller is configured to configure the input and output connections of the PEs in the 2D array of PEs based on the first bandwidth, the second bandwidth, or both.

4. The neural network accelerator of claim 3, wherein the controller includes an array of bus arbiters configured to control the first bandwidth of the first data bus.

5. The neural network accelerator of claim 3, wherein the controller is configured to control the second bandwidth of the second data bus by sending a local memory control signal to the local memory.

6. The neural network accelerator of claim 1, wherein:
each PE of the 2D array of PEs includes a multiply-accumulate (MAC) unit, a first register configured to receive data from the first memory device, a second register configured to receive data from the local memory, a third register coupled to MAC unit and configured to store an output of the MAC unit; and
the configurable PE array includes a plurality of multiplexers, wherein each multiplexer of the plurality of multiplexers is configured to:
connect an output of a PE to an input of another PE in the 2D array of PEs;
connect the first register of a PE in the 2D array of PEs to the first data bus; or
connect the second register of a PE in the 2D array of PEs to the second data bus.

7. The neural network accelerator of claim 6, wherein:
the controller is configured to configure the input and output connections of the PEs in the 2D array of PEs by controlling the plurality of multiplexers using a set of control signals; and
at least two multiplexers of the plurality of multiplexers are controlled by a same control signal of the set of control signals.

8. The neural network accelerator of claim 6, wherein the plurality of multiplexers includes:
a first set of multiplexers configured to connect PEs in the 2D array of PEs;
a second set of multiplexers configured to connect first registers of PEs in the 2D array of PEs to the first data bus; and
a third set of multiplexers configured to connect second registers of PEs in the 2D array of PEs to the second data bus.

9. The neural network accelerator of claim 6, wherein:
the first memory device includes a static random access memory (SRAM) device and is larger than the local memory; and
the first register is larger than the second register and is smaller than the third register.

10. The neural network accelerator of claim 1, wherein:
the first memory device is on a first die;
the controller, the configurable PE array, and the local memory are on a second die;
the high-bandwidth interconnect includes three-dimensional (3D) interconnects; and
the first die and the second die are arranged in a die stack and are connected by the 3D interconnects.

11. The neural network accelerator of claim 10, wherein the 3D interconnects include through-silicon-vias (TSVs), micro-bumps, or both.

12. The neural network accelerator of claim 1, wherein the first data bus is characterized by a configurable bandwidth equal to or greater than 512 bits per clock cycle.

13. The neural network accelerator of claim 1, wherein:
the input tensor includes input data for one or more input channels and a plurality of batches; and
the weight tensor includes weights for generating a plurality of output channels from the input tensor.

14. An integrated circuit device comprising:
a configurable processing element (PE) array including:
a two-dimensional (2D) array of PEs; and
a plurality of multiplexers connected to PEs in the 2D array of PEs;
a controller connected to the configurable PE array through a first data bus, the controller configured to control the plurality of multiplexers; and
a local memory connected to the controller and connected, through a second data bus, to the configurable PE array,
wherein each PE of the 2D array of PEs includes:
a multiply-accumulate (MAC) unit;
a first register connected to the first data bus directly or through a multiplexer of the plurality of multiplexer and configured to store data from the first data bus;
a second register connected to the second data bus directly or through a multiplexer of the plurality of multiplexer and configured to store data from the local memory; and
a third registers coupled to MAC unit and configured to store an output of the MAC unit.

15. The integrated circuit device of claim 14, wherein the MAC unit of a first PE in a first column of the 2D array of PEs is connected, through a multiplexer of the plurality of multiplexers, to the MAC unit of an adjacent second PE in the first column of the 2D array of PEs.

16. The integrated circuit device of claim 14, wherein:
the configurable PE array includes a plurality of accumulators outside of PEs of the 2D array of PEs; and
each accumulator of the plurality of accumulators is connected to at least two PEs in a same column of the 2D array of PEs directly or through a multiplexer of the plurality of multiplexers.

17. The integrated circuit device of claim 16, wherein a first PE in a first column of the 2D array of PEs is connected to a second PE in an adjacent column of the 2D array of PEs through a multiplexer of the plurality of multiplexers and an accumulator of the plurality of accumulators.

18. The integrated circuit device of claim 14, wherein:
the controller includes a set of configuration registers configured to store respective configuration parameters for each neural network (NN) layer of a plurality of NN layers of a neural network; and
the controller is configured to, during execution of the neural network by the integrated circuit device and based on the respective configuration parameters for each NN layer of the plurality of NN layers, control the plurality of multiplexers to dynamically configure the configurable PE array for executing each NN layer of the plurality of NN layers.

19. The integrated circuit device of claim 18, wherein the controller is configured to, based on the respective configuration parameters for each NN layer of the plurality of NN layers:
dynamically control a first bandwidth of the first data bus, a second bandwidth of the second data bus, or both, for executing the NN layer of the plurality of NN layers; and
select either weights of a weight tensor or input data of an input tensor of a tensor operation of the NN layer to store into the local memory.

20. The integrated circuit device of claim 14, wherein:
the controller, the configurable PE array, and the local memory are on a first die; and
the integrated circuit device further comprises a second die bonded to the first die and electrically connected to the first die through three-dimensional (3D) interconnects, wherein the second die includes a memory device that has a larger capacity than the local memory and is configured to store tensors used by a neural network.
